(19) United States
(12) Patent Application Publication
(10) Pub. No.: US 2014/0091264 A1
(43) Pub. Date: Apr. 3, 2014

(54) ORGANIC ELECTRONIC DEVICE

(71) Applicants: Junyou Pan, Frankfurt am Main (DE); Niels Schulte, Kelkheim (DE)

(72) Inventors: Junyou Pan, Frankfurt am Main (DE); Niels Schulte, Kelkheim (DE)

(73) Assignee: Merck Patent GmbH, Darmstadt (DE)

(21) Appl. No.: 14/118,685

(22) PCT Filed: May 16, 2012
(86) PCT No.: PCT/EP2012/002118

§ 371 Date: Nov. 19, 2013

(30) Foreign Application Priority Data
May 27, 2011 (DE) 10 2011 102 586.7

(51) Int. Cl. H01L 51/00

(52) U.S. Cl. CPC H01L 51/0067; H01L 51/0072; H01L 51/0071
USPC 252/519.21; 540/472; 540/469; 252/500

(57) ABSTRACT

The present invention relates to organic electronic devices, in particular organic electroluminescent devices, which comprise organic cyclophanes, in particular as matrix materials for fluorescent or phosphorescent emitter compounds or as charge-transport materials, in particular electron-transport materials, and to diverse organic cyclophanes themselves.

The present invention relates to organic electronic devices, in particular organic electroluminescent devices, which comprise organic cyclophanes, in particular as matrix materials for fluorescent or phosphorescent emitter compounds or as charge-transport materials, in particular electron-transport materials, and to diverse organic cyclophanes themselves.

The structure of organic electroluminescent devices (OLEDs, in which organic semiconductors are employed as functional materials is described, for example, in U.S. Pat. No. 4,539,507, U.S. Pat. No. 5,151,629, EP 0676461 and WO 98/27136. The emitting materials employed here are increasingly organometallic complexes which exhibit phosphorescence instead of fluorescence (M. A. Baldo et al., Appl. Phys. Lett. 1999, 75, 4-6). For quantum-mechanical reasons, an up to four-fold energy and power efficiency is possible using organometallic compounds as phosphorescence emitters. In general, however, there is still a need for improvement in the case of OLEDs, in particular also in the case of OLEDs which exhibit triplet emission (phosphorescence), for example with respect to efficiency, operating voltage and in particular lifetime. This applies, in particular, to OLEDs which emit in the relatively short-wave region, for example green.

The properties of phosphorescent OLEDs are determined not only by the triplet emitters (or quintet emitters) employed. In particular, the other materials used, such as matrix materials, hole-blocking materials, electron-transport materials, hole-transport materials and electron- or exciton-blocking materials, are also of particular importance here. Improvements in these materials can thus also result in significant improvements in the OLED properties. There is also still a need for improvement in these materials for fluorescent OLEDs.

In accordance with the prior art, carbazole derivatives, for example bis-(carbazolyl)biphenyl, are frequently used as matrix materials. There is still a need for improvement here, in particular with respect to the lifetime and the glass-transition temperature of the materials.

Furthermore, ketones (WO 2004/093207), phosphine oxides and sulfones (WO 2005/003253) are used as matrix materials for phosphorescent emitters. In particular with ketones, low operating voltages and long lifetimes are achieved. Furthermore, triazine derivatives are used as matrix materials for phosphorescent emitters (for example in accordance with WO 2007/063754 or WO 2008/056746). However, there is still a need for improvement on use of these matrix materials just as in the case of other matrix materials, in particular with respect to the efficiency and lifetime of the device.

There is thus, in particular, still a need for improvement in the case of matrix materials for phosphorescent emitters which simultaneously result in high efficiencies, long lifetimes and low operating voltages.

The object of the present invention is the provision of compounds which are suitable for use in a fluorescent or phosphorescent OLED, in particular a phosphorescent OLED, for example as matrix material or as hole-transport/electron-blocking material or exciton-blocking material or as electron-transport or hole-blocking material. In particular, the object of the present invention is to provide matrix materials and electron-transport materials which are also suitable for green- and blue-phosphorescent OLEDs. A further object of the present invention is to provide matrix materials for phosphorescent emitters.

Surprisingly, it has been found that organic cyclophanes are highly suitable as matrix materials for phosphorescent emitter compounds and also as charge-transport materials and in this use result in OLEDs which simultaneously have high efficiencies and low operating voltages.

The present invention provides an organic electroluminescent device which comprises, in at least one layer, a cyclophane compound of the following formula (1):

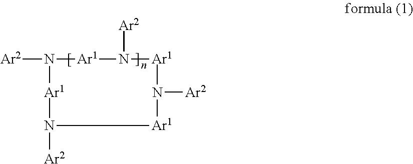

where the symbols and indices used have the following meanings:
n is an integer in the range from 0 to 8; preferably from 0 to 6, very preferably from 0 to 4, very particularly preferably equal to 3, 1 or 0, and especially preferably equal to 0;
Ar¹ is on each occurrence, identically or differently, a substituted or unsubstituted divalent monocyclic or polycyclic aromatic or heteroaromatic ring system;
Ar² is on each occurrence, identically or differently, a substituted or unsubstituted monovalent monocyclic or polycyclic aromatic or heteroaromatic ring system;
   characterised in that either (1) at least one representative of the Ar¹ or Ar² represents a heteroaromatic ring system, or (2) at least one representative of the Ar² represents an aromatic ring system containing a keto group.

An organic electroluminescent device is taken to mean a device which comprises at least two electrodes (anode and cathode) and a least one emitting layer which is arranged between the anode and the cathode, where at least one layer between the anode and the cathode comprises at least one compound of the formula (1) and preferably an organic or organometallic compound as phosphorescent emitter compound. The organic electroluminescent device according to the invention need not necessarily comprise only layers built up from organic or organometallic materials. Thus, it is also possible for one or more layers to comprise inorganic materials or to be built up entirely from inorganic materials.

The term “electroluminescence” encompasses an optical phenomenon and electrical phenomenon in which a material emits light as reaction to the application of an electric field. In the context of this invention, the following organic electroluminescent devices are preferred:
1) “Organic light emitting diode” (OLED) as described by R. Friend et al., in Nature 397, 121-128 (1999);
2) “Organic light emitting electrochemical cell” (OLEC) as described by Pei et al., in Science, (1995) Vol269 p1086;
3) “Organic light emitting field effect transistor” as described by Fabio in Cicoira and Clara Santato, in Adv. Funct. Mater. 2007, 17, 3421-3434, where “source” and “drain” are equivalent to anode and cathode.
4) “Organic light emitting electrochemical transistor” as described by C. Yumusak and N. S. Sariciftci, in Appl. Phys. Lett. 97, 033302 (2010), where “source” and “drain” are equivalent to anode and cathode.

In accordance with the invention, the organic electronic device is preferably an organic electroluminescent device, in particular an OLED or OLEC.

A mono- or polycyclic aromatic ring system in the sense of this invention is preferably taken to mean an aromatic ring system having 6 to 60 carbon atoms, preferably 6 to 30, particularly preferably 6 to 10 carbon atoms. An aromatic ring system in the sense of the present invention is intended to be taken to mean a system which does not necessarily contain only aromatic groups, but instead in which, in addition, a plurality of aromatic may be interrupted by a short non-aromatic unit (<10% of the atoms other than H, preferably <5% of the atoms other than H), such as, for example, sp³-hybridised C, O, N, etc, or a —C(O)— group. These aromatic ring systems may be monocyclic or polycyclic, i.e. they may contain one ring (for example phenyl) or two or more rings, which may also be condensed (for example naphthyl) or covalently linked (for example biphenyl), or contain a combination of condensed and linked rings.

Preferred aromatic ring systems are, for example, phenyl, biphenyl, tri-phenyl, naphthyl, anthracyl, binaphthyl, phenanthryl, dihydrophenanthryl, pyrene, dihydropyrene, chrysene, perylene, tetracene, pentacene, benzopyrene, fluorene and indene.

A mono- or polycyclic heteroaromatic ring system in the sense of this invention is preferably taken to mean a heteroaromatic ring system having 5 to 60 ring atoms, preferably 5 to 30, particularly preferably 5 to 14 ring atoms. The heteroaromatic ring system contains at least one heteroatom selected from N, O and S (remaining atoms are carbon). A heteroaromatic ring system is additionally intended to be taken to mean a system which does not necessarily contain only aromatic or heteroaromatic groups, but instead in which, in addition, a plurality of aromatic or heteroaromatic groups may be interrupted by a short non-aromatic unit (<10% of the atoms other than H, preferably <5% of the atoms other than H), such as, for example, sp³-hybridised C, O, N, etc, or a —C(O)— group. These heteroaromatic ring systems may be monocyclic or polycyclic, i.e. they may contain one ring (for example pyridyl) or two or more rings, which may also be condensed or covalently linked, or contain a combination of condensed and linked rings.

Preferred heteroaromatic ring systems are, for example, 5-membered rings, such as pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings, such as pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or condensed groups, such as indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, aza-carbazole, benzocarboline, phenanthridine, phenanthroline, thieno[2,3b]-thiophene, thieno[3,2b]thiophene, dithienothiophene, isobenzothiophene, dibenzothiophene, benzothiadiazothiophene or combinations of these groups. Particular preference is given to imidazole, benzimidazole and pyridine.

If the monocyclic or polycyclic aromatic or heteroaromatic ring system is a divalent system, as in the case of Ar₁, the two bonds to the nitrogen atoms in the compound of the formula (1) preferably take place to one aromatic ring. It is furthermore preferred for the two bonds to the nitrogen atoms in the formula (1) to take place via positions of the one aromatic ring in such a way that they are both in the meta-position to one another. In other words, the linking to the nitrogen atoms in the compound of the formula (1) takes place in positions 1 and 3 of one aromatic ring.

If the monocyclic or polycyclic aromatic or heteroaromatic ring system is a monovalent radical, as in the case of Ar₂, the bond preferably takes place via an aromatic atom of the ring system.

The ring systems Ar¹ and Ar² may be in unsubstituted or substituted form. If they are in substituted form, they can contain one or more radicals R¹. R¹ is selected on each occurrence, identically or differently, from the group consisting of the following: H, D, F, CI, Br, I, CHO, N(Ar)₂, C(═O)Ar, P(═O)(Ar)₂, S(═O)Ar, S(═O)₂Ar, CR²═CR²Ar, CN, NO₂, Si(R²)₃, B(OR²)₂, B(R²)₂, B(N(R²)₂)₂, OSO₂R², an alkyl, alkoxy or thioalkoxy group, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by F, CI, Br, I, CN or NO₂, or an aromatic or heteroaromatic ring system, which may in each case be substituted by one or more radicals R², or an aryloxy or heteroaryloxy group, which may be substituted by one or more radicals R², or a combination of these systems; two or more adjacent substituents R¹ here may also form a mono- or polycyclic, aliphatic, aromatic or heteroaromatic ring system with one another; where Ar is on each occurrence, identically or differently, a mono- or polycyclic aromatic or heteroaromatic ring system, which may be substituted by one or more radicals R²; two radicals Ar here which are bonded to the same nitrogen, phosphorus or boron atom may also be linked to one another by a single bond or a bridge selected from B(R²), C(R²)₂, Si(R²)₂, C═O, C═NR², C═C(R²)₂, O, S, S═O, SO₂, N(R²), P(R²) and P(═O)R²; and where R² is on each occurrence, identically or differently, H, D or an aliphatic, aromatic and/or heteroaromatic hydrocarbon radical, in which, in addition, H atoms may be replaced by F; two or more adjacent substituents R² here may also form a mono- or polycyclic, aliphatic or aromatic ring system with one another;

For the purposes of the present invention, an alkyl group is taken to mean linear, branched or cyclic alkyl groups. The linear alkyl groups preferably have 1 to 6, 1 to 10 or 1 to 40 carbon atoms. The branched or cyclic alkyl groups preferably have 3 to 6, 3 to 10 or 3 to 40 carbon atoms. Preference is given in all three cases to alkyl groups having 1 to 6 carbon atoms, particularly preferably 1 to 3 carbon atoms. One or more hydrogen atoms on these alkyl groups may preferably also be replaced by a fluorine atom. In addition, one or more of the CH₂ groups of these units may be replaced by NR(R here is a radical selected from the group consisting of H and C₁₋₆-alkyl). If one or more of the CH₂ groups is replaced by NR, it is particularly preferred for only one of these groups to be replaced. The alkyl groups may also be alkenyl or alkynyl groups, i.e. groups containing one or more double or triple bonds. Examples of such compounds include the following: methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, n-heptyl, cycloheptyl, n-octyl, cyclooctyl, 2-ethylhexyl, trifluoromethyl, pentafluoroethyl and 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl.

An alkoxy group or thioalkoxy group is taken to mean an alkyl group as defined above which is bonded via an O or S atom.

Preferred alkoxy groups are methoxy, trifluoromethoxy, ethoxy, n-propoxy, i-propoxy, n-butoxy, i-butoxy, s-butoxy, t-butoxy or 2-methylbutoxy. Aliphatic hydrocarbon radicals according to the invention are preferably linear or branched or cyclic alkyl groups, alkenyl groups or alkynyl groups, preferably having 1 to 20 or 3 to 20 carbon atoms respectively, in which one or more carbon atoms may replaced by O, N or S. In addition, one or more hydrogen atoms may be replaced by fluorine. Examples of the aliphatic hydrocarbons having 1 to 20 carbon atoms include the following: methyl, ethyl, n-propyl, isopropyl, n-butyl, isobutyl, sec-butyl (1-methylpropyl), tert-butyl, isopentyl, n-pentyl, tert-pentyl (1,1-dimethylpropyl), 1,2-dimethylpropyl, 2,2-dimethylpropyl (neopentyl), 1-ethylpropyl, 2-methylbutyl, n-hexyl, isohexyl, 1,2-dimethylbutyl, 1-ethyl-1-methylpropyl, 1-ethyl-2-methylpropyl, 1,1,2-trimethylpropyl, 1,2,2-trimethylpropyl, 1-ethylbutyl, 1-methylbutyl, 1,1-dimethylbutyl, 2,2-dimethylbutyl, 1,3-dimethylbutyl, 2,3-dimethyl-butyl, 3,3-dimethylbutyl, 2-ethylbutyl, 1-methylpentyl, 2-methylpentyl, 3-methylpentyl, cyclopentyl, cyclohexyl, cycloheptyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl and octynyl.

An aromatic or heteroaromatic hydrocarbon radical can be mono- or polycyclic and preferably contains 5 to 20, more preferably 5 to 10, most preferably 5 or 6 aromatic ring atoms. If the unit is an aromatic unit, it preferably contains 6 to 20, very preferably 6 to 10, very particularly preferably 6, carbon atoms as ring atoms. If the unit is a heteroaromatic unit, it contains 5 to 20, preferably 5 to 10, very preferably 5, aromatic ring atoms, of which at least one is a heteroatom. The heteroatoms are preferably selected from N, O and/or S. An aromatic or heteroaromatic unit here is taken to mean either a single aromatic ring, i.e. benzene, or a single heteroaromatic ring, for example pyridine, pyrimidine, thiophene, etc., or a condensed aryl or heteroaryl group, for example naphthalene, anthracene, phenanthrene, quinoline, isoquinoline, benzothiophene, benzofuran and indole etc.

Examples according to the invention of the aromatic or heteroaromatic hydrocarbon radical are accordingly: benzene, naphthalene, anthracene, phenanthrene, pyrene, chrysene, benzanthracene, perylene, naphthacene, pentacene, benzopyrene, furan, benzofuran, isobenzofuran, dibenzofuran, thiophene, benzothiophene, isobenzothiophene, dibenzothiophene, pyrrole, indole, isoindole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

An aryloxy or heteroaryloxy group is taken to mean an aromatic or heteroaromatic hydrocarbon radical as defined above which is bonded via an oxygen atom.

An aliphatic ring system is taken to mean a mono- or polycyclic ring system, preferably comprising 4 to 30 CH₂ units (in the case of polycyclic also CH units), preferably 5 to 20 CH₂ units, particularly preferably 5 ring atoms, which may contain up to three, preferably up to 2, preferably 2, heteroatoms selected from N, O, S, preferably N. Examples which are preferred in accordance with the invention are 1,2-diazocyclopentane or preferably 1,3-diazocyclopentane.

The organic electronic devices according to the invention can be used for various applications, for example for single-coloured or multicoloured dis-plays, for lighting applications or for medical or cosmetic applications, for example in phototherapy.

The preferred organic electronic device comprises cathode, anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers and/or charge-generation layers. Interlayers, which have, for example, an exciton-blocking function, may likewise be introduced between two emitting layers. However, it should be pointed out that each of these layers does not necessarily have to be present.

The organic electronic device here may comprise one emitting layer, or it may comprise a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to systems having three emitting layers, where the three layers exhibit blue, green and orange or red emission (for the basic structure see, for example, WO 2005/011013). It is possible here for all emitting layers to be fluorescent layers or for all emitting layers to be phosphorescent layers or for one or more emitting layer(s) to be (a) fluorescent layer(s) and one or more other layer(s) to be (a) phosphorescent layer(s).

The organic electronic device according to the invention here may comprise different layers in which a compound of the formula (1) is employed in at least one layer, depending on the application and area of use.

Preference is given in this invention to an organic electronic device which comprises a compound of the formula (1) as matrix material for fluorescent or phosphorescent emitters, in particular for phosphorescent emitters, in an emitting layer and/or as hole-blocking material in a hole-blocking layer and/or as electron-transport material in an electron-transport layer or as exciton-blocking material in exciton-blocking layer and/or as hole-transport material in a hole-transport layer, depending on the application and area of use.

In a further embodiment of the invention, the organic electronic device according to the invention is particularly preferably one in which the compound of the formula (1) is employed as matrix material for a fluorescent or phosphorescent compound, in particular for a phosphorescent compound, in an emitting layer. The organic electronic device here may comprise one emitting layer, or it may comprise a plurality of emitting layers, where at least one emitting layer comprises at least one compound of the formula (1) as matrix material.

The suitable and preferred embodiment for compounds as matrix material is explained as follows.

The compounds of the formulae (1) which are suitable as matrix material are characterised in that at least one representative of the Ar¹ and/or Ar² in formula (1) represents a heteroaromatic ring system.

The organic electronic device according to the invention preferably comprises a compound of the formula (1) as matrix material in an emitting layer in which a least one representative of the Ar¹ contains a divalent group of one of the following formulae (2) to (8):

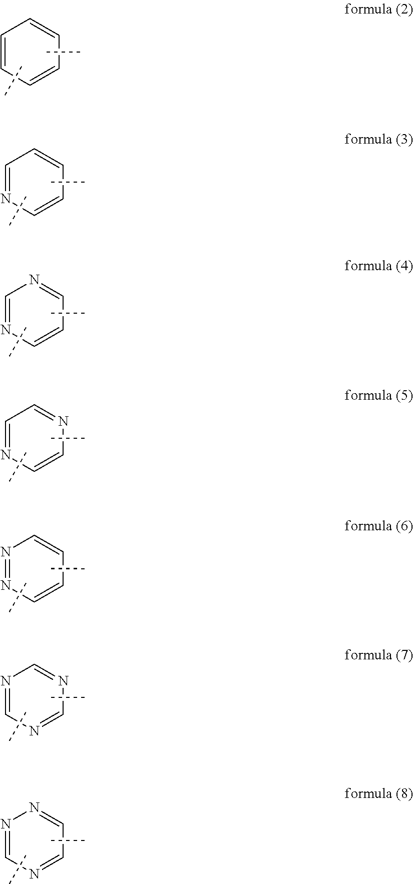

where the dashed lines represent the bonds to the ring nitrogen atoms of the compound of the formula (1). They are preferably in the meta-position to one another, i.e. in positions 1 and 3 of the aromatic ring.

In particular if all Ar² are aromatic ring system without heteroatoms, at least one representative of the Ar¹ is preferably a group of one of the formulae (3) to (8).

It is furthermore preferred for the compound of the formula (1) to be a compound of the following formula (9):

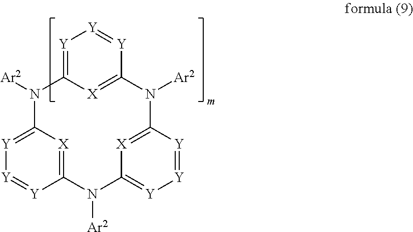

where X and Y are equal to CR¹ or N, and m is an integer from 1 to 6, preferably 1, 2 or 4, with the proviso that at least one representative of the X or Y is equal to N, and one representative of the Ar² represents a heteroaromatic, or an aromatic ring system, and R¹ has the same meaning as defined above.

Examples of particularly preferred compounds of the formula (9) are the compounds of the formulae (10) to (99) shown below.

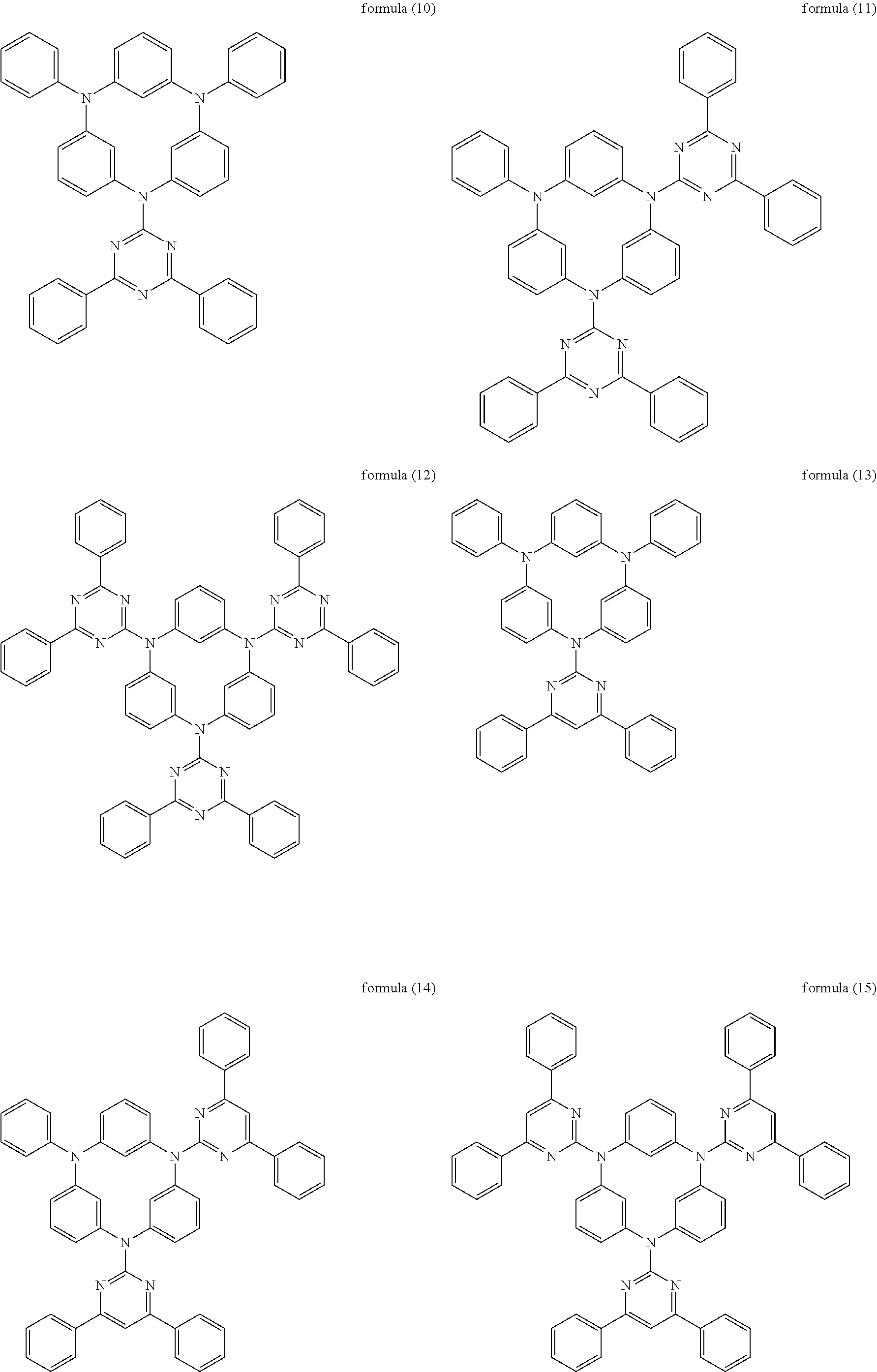

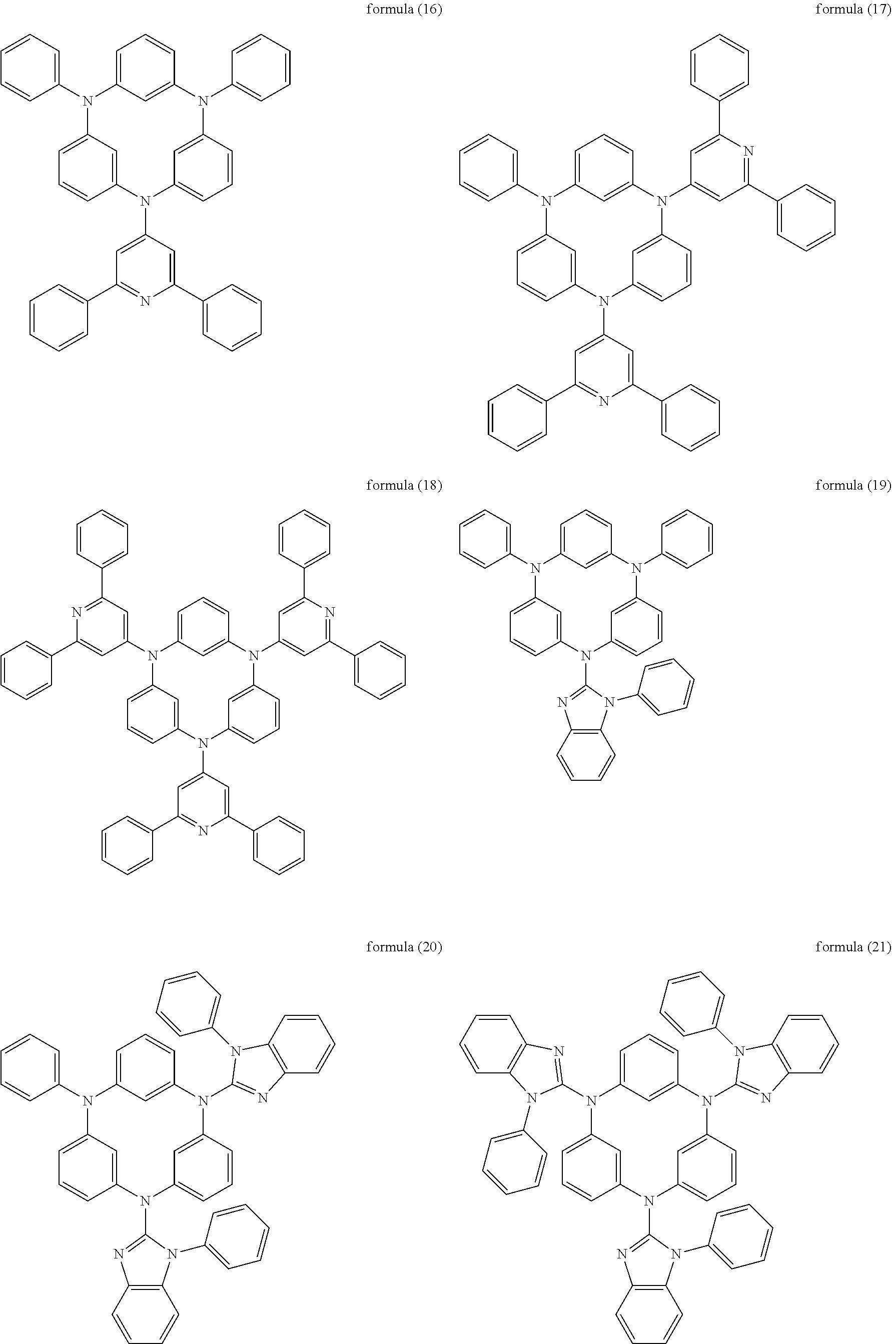

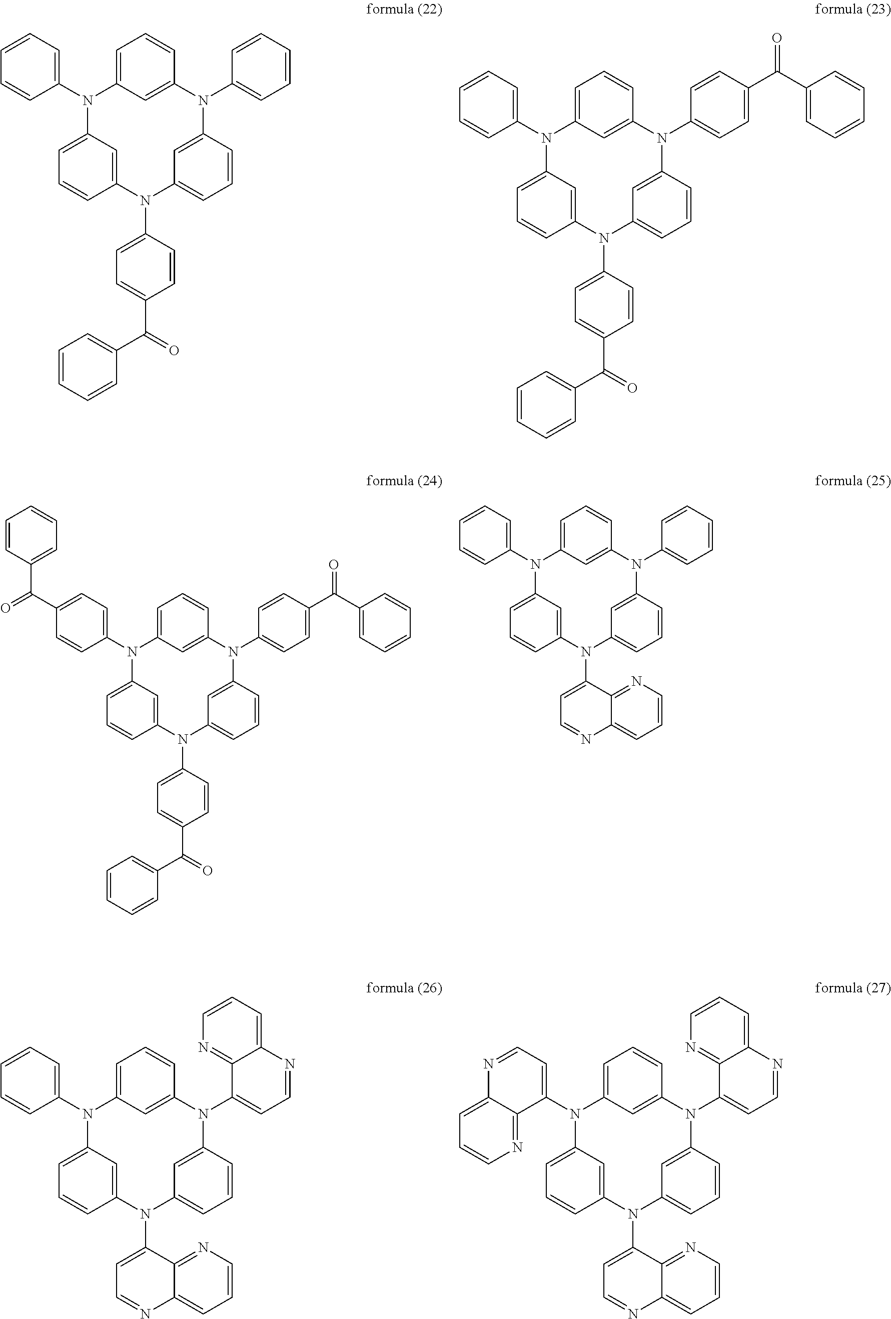

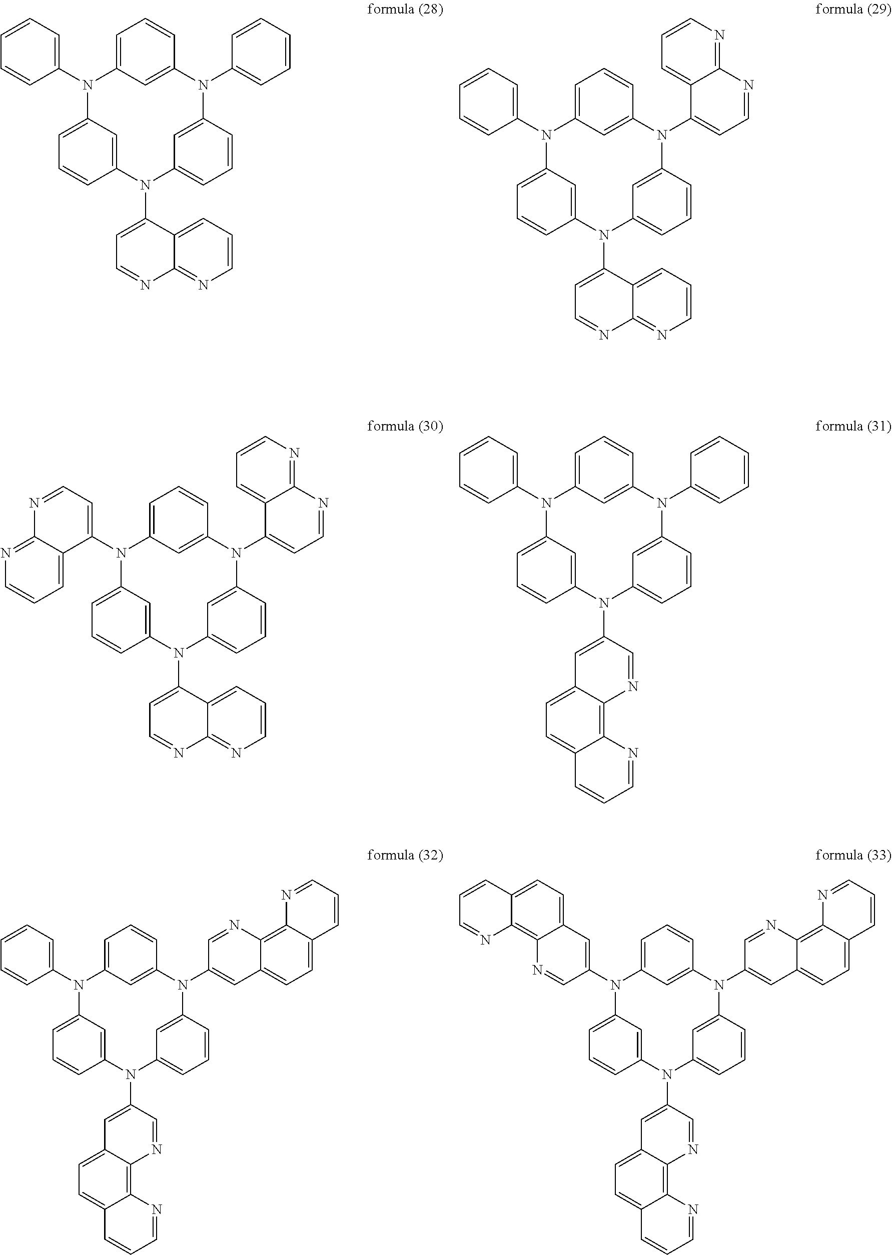

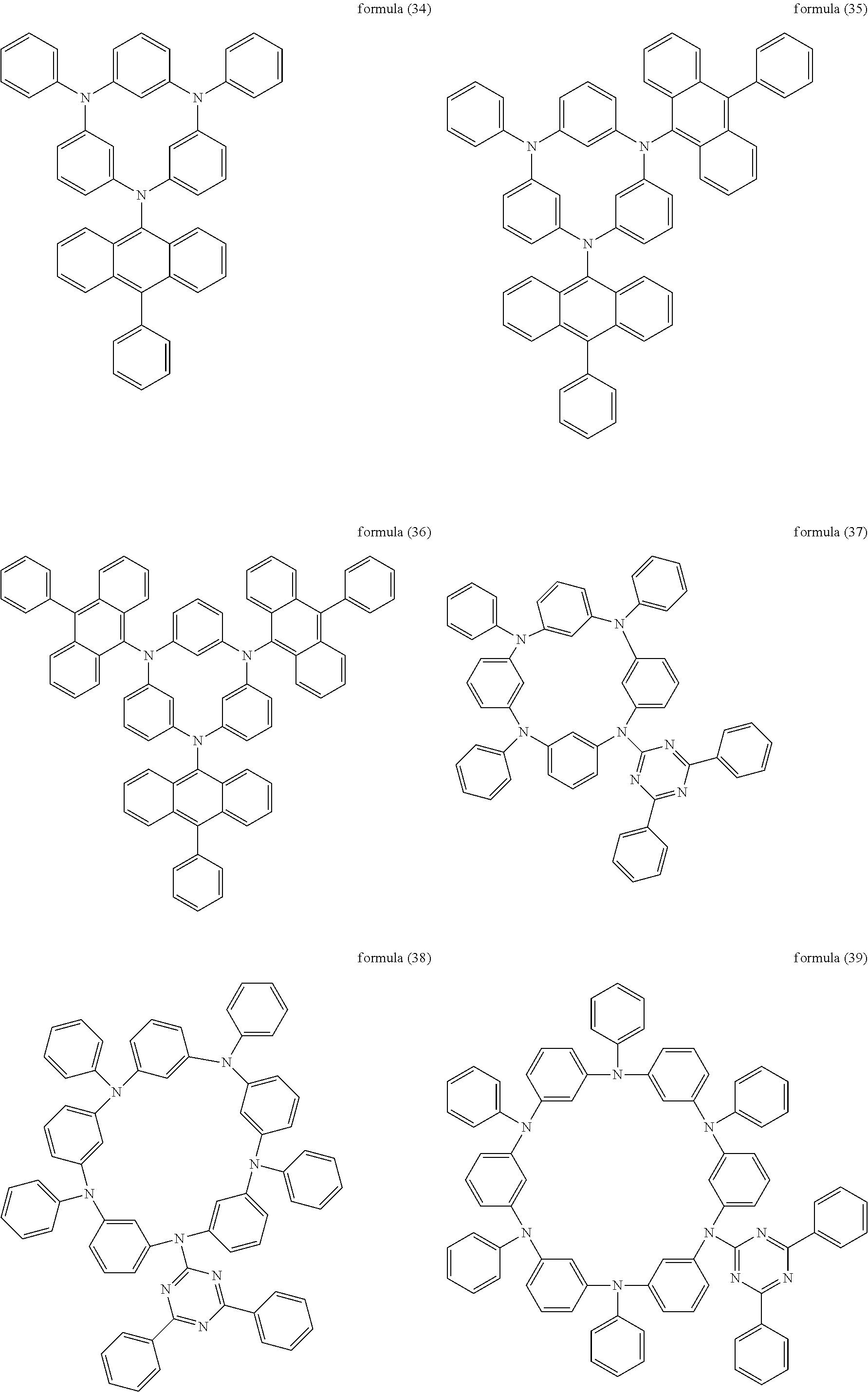

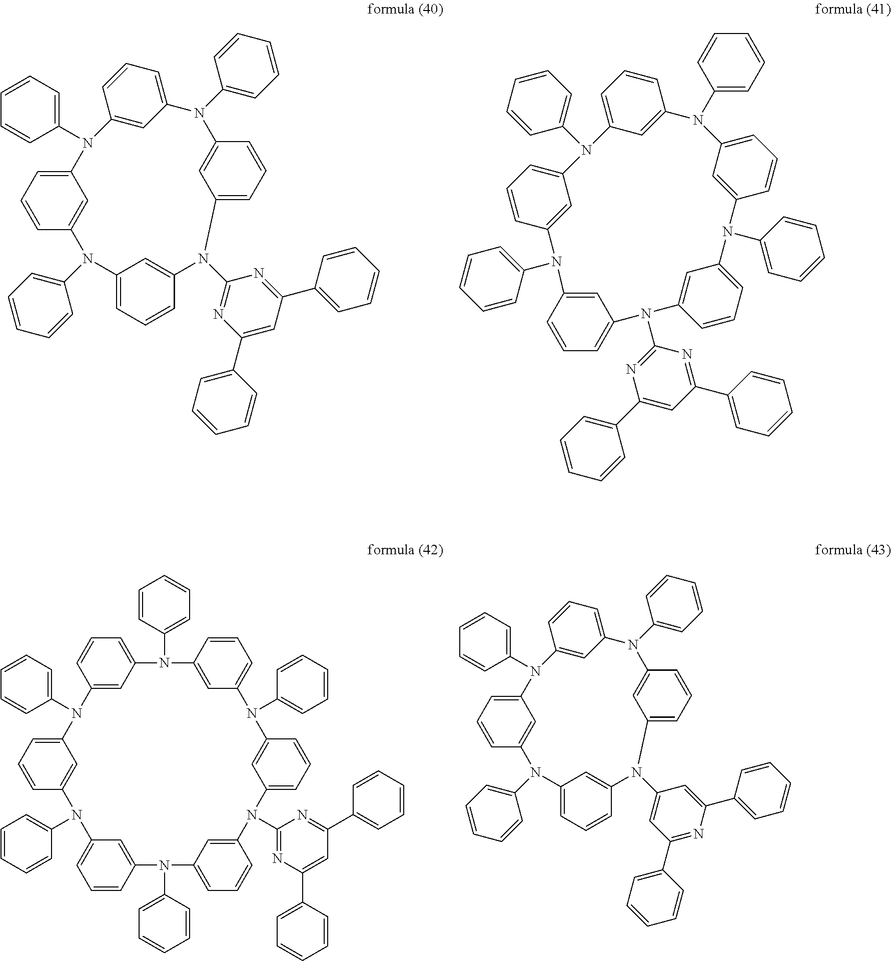

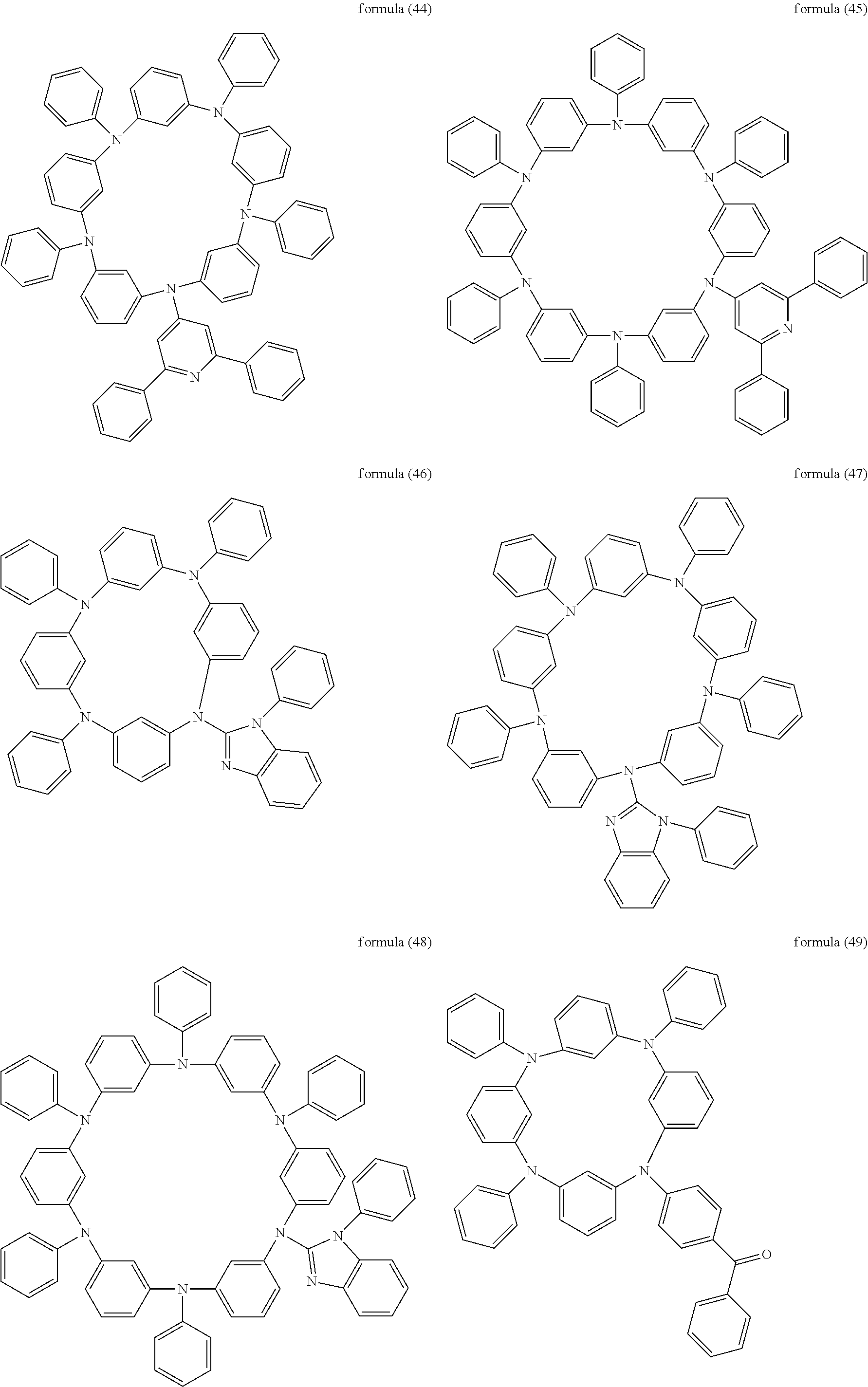

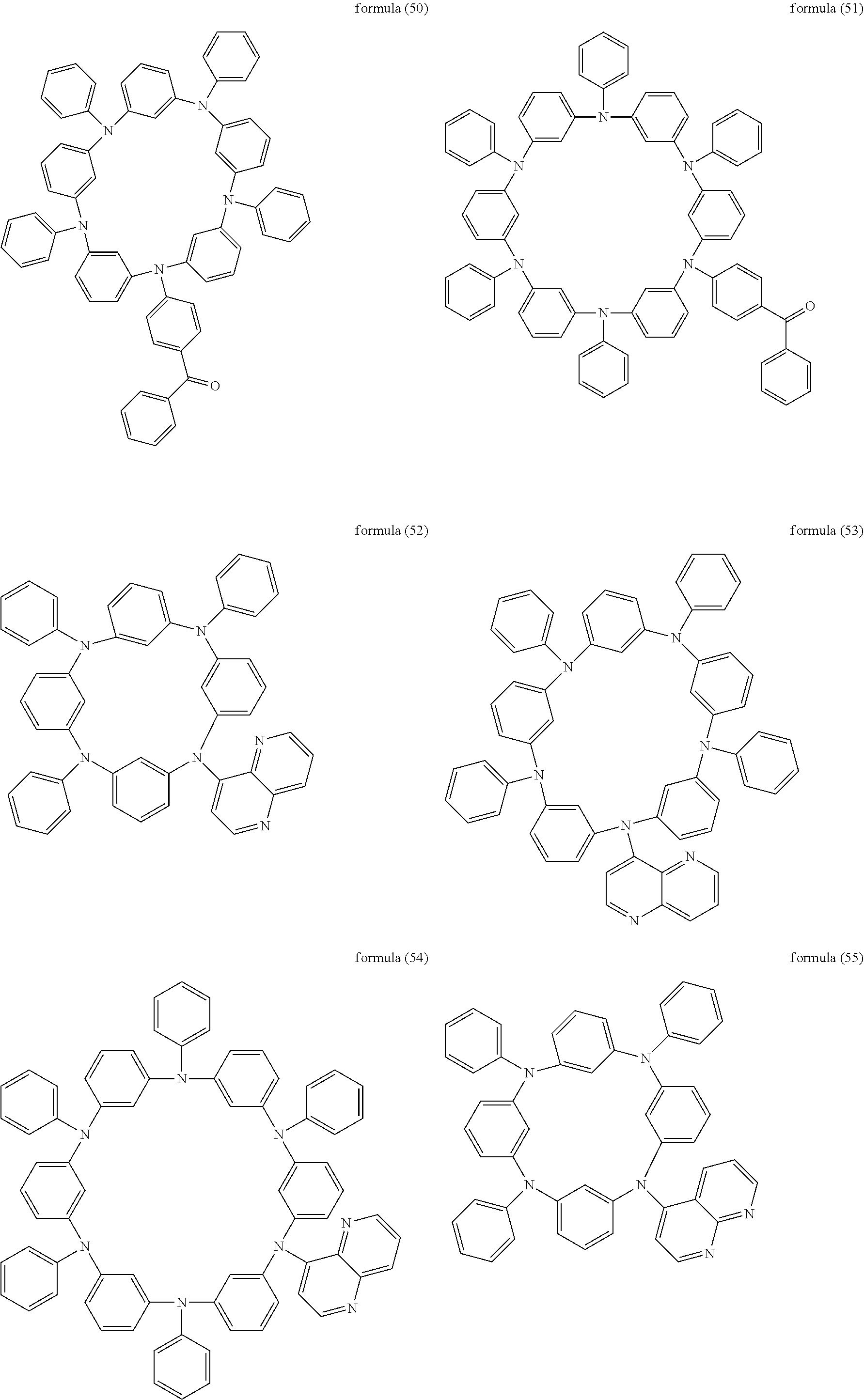

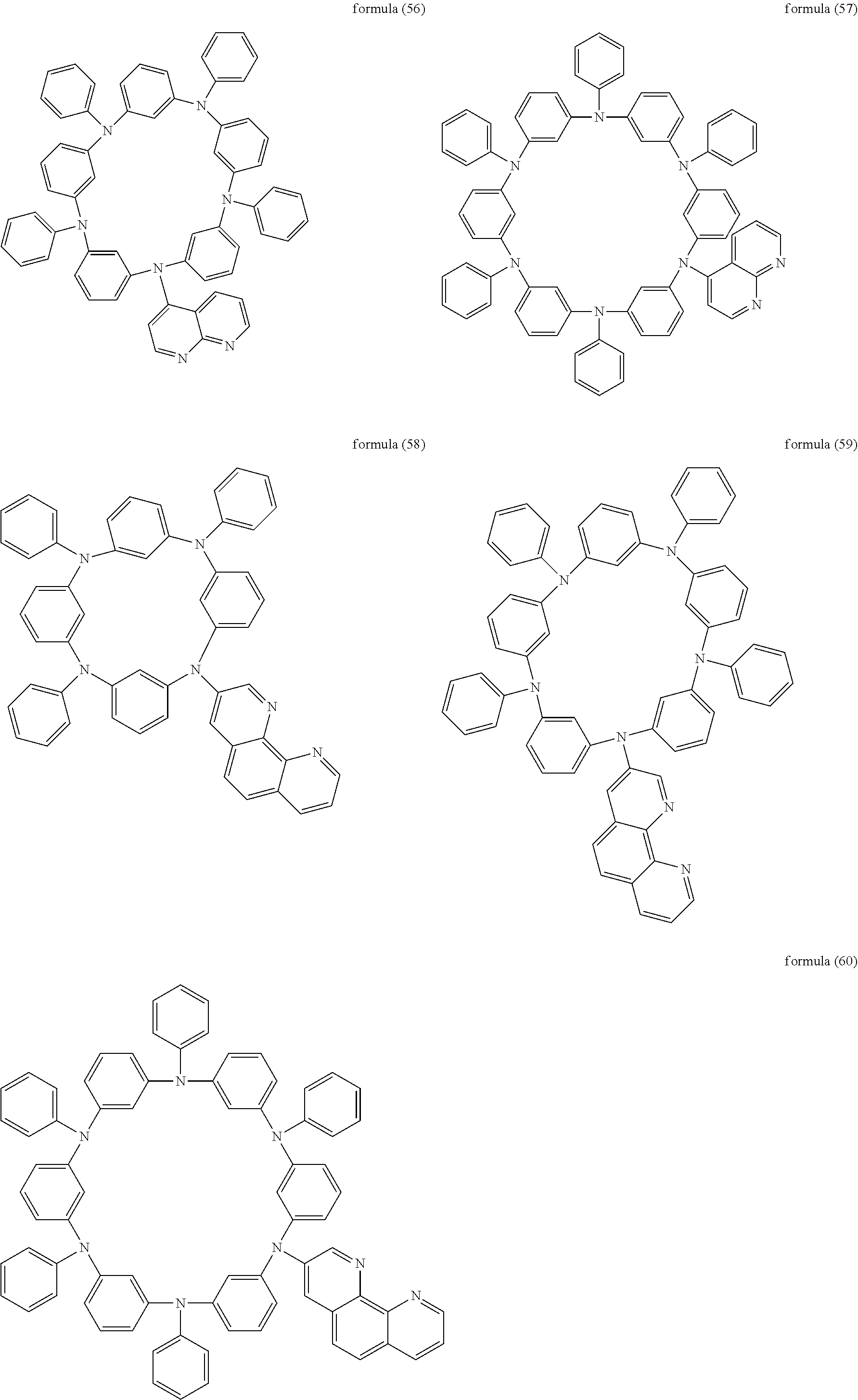

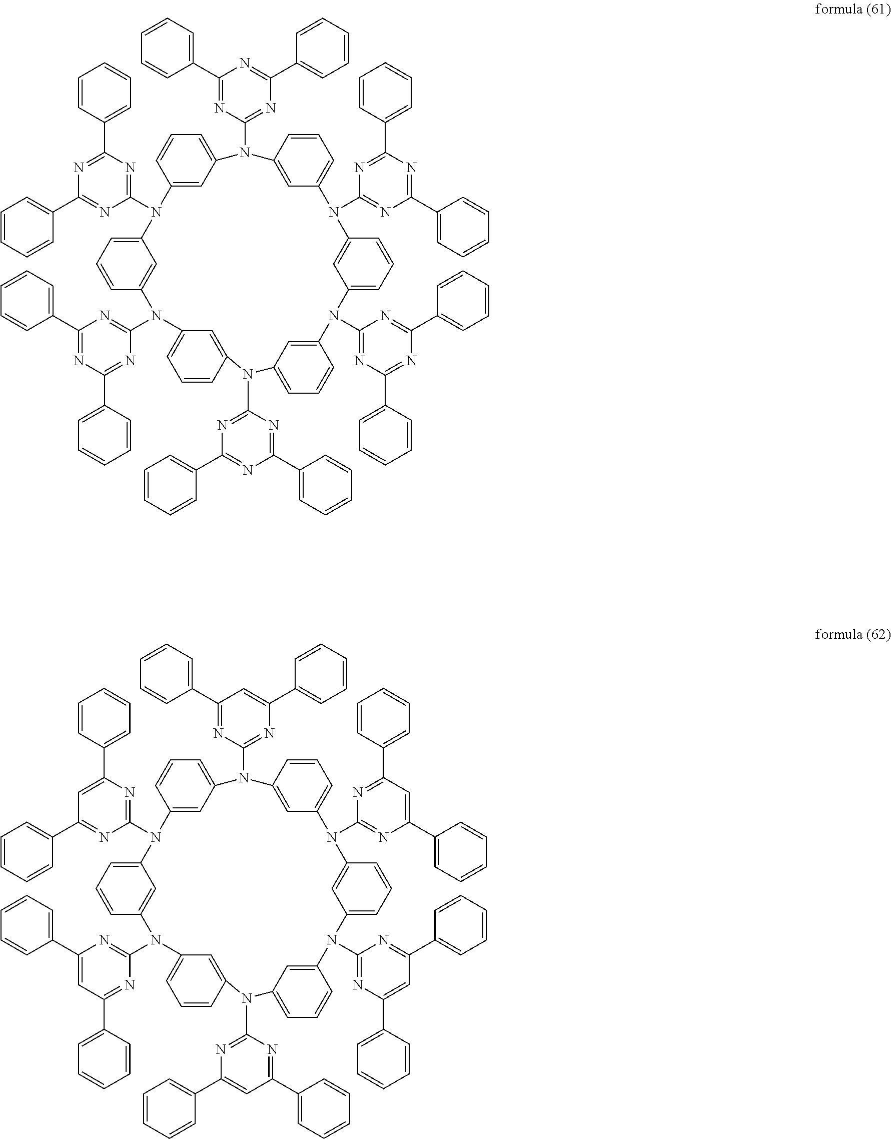

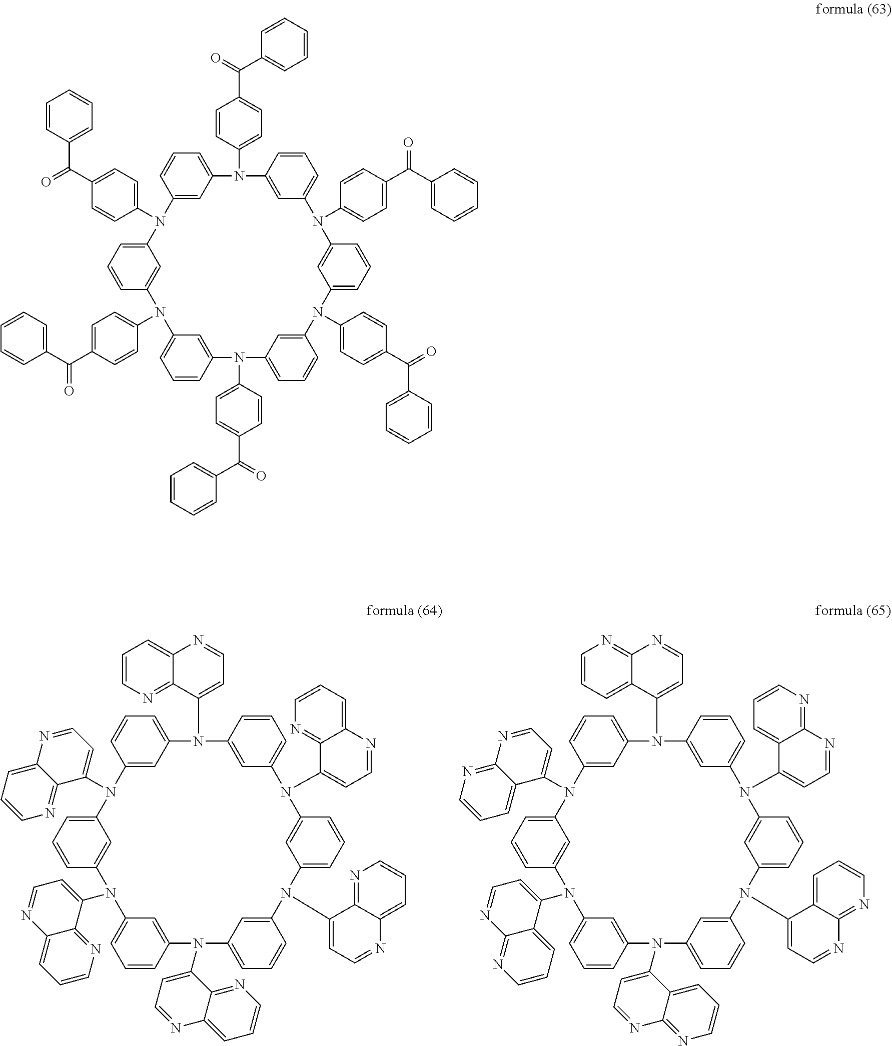

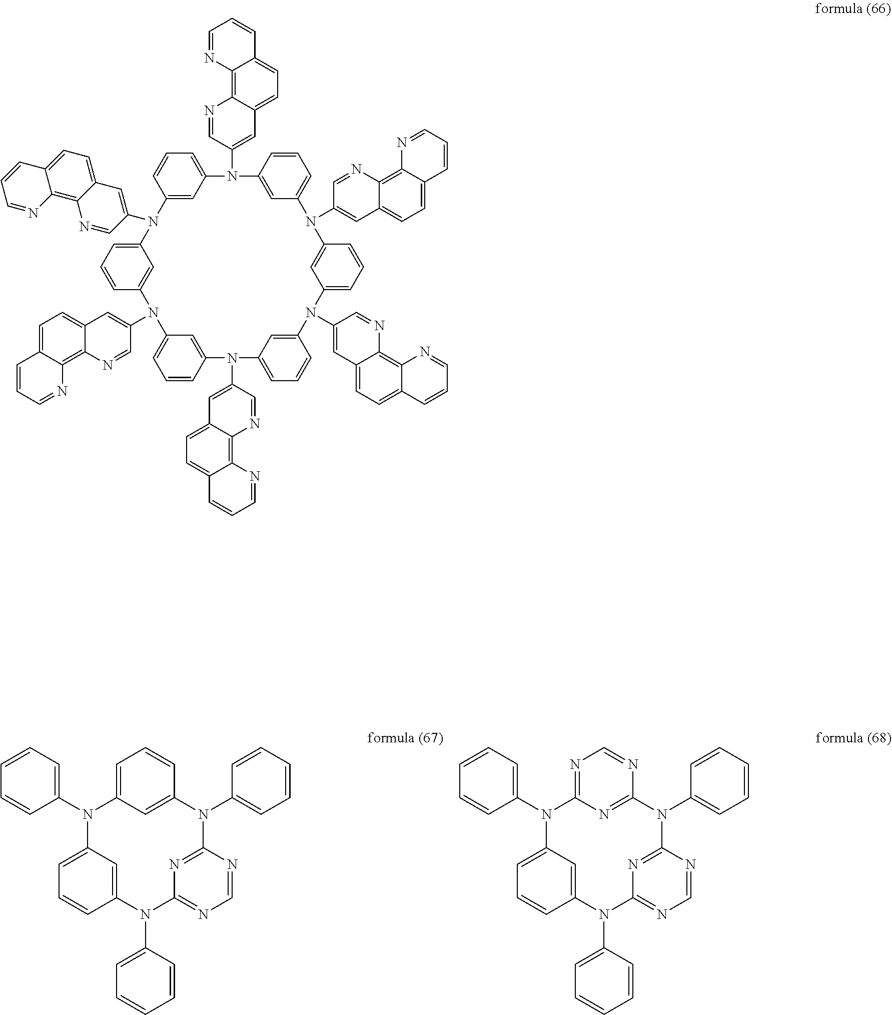 [SMILES: c1cnc2c(c1)ccc1cc(-n3c4cccc(c4)n(-c4cnc5c(ccc6cccnc65)c4)c4cccc(c4)n(-c4cnc5c(ccc6cccnc65)c4)c4cccc(c4)n(-c4cnc5c(ccc6cccnc65)c4)c4cccc(c4)n(-c4cnc5c(ccc6cccnc65)c4)c4cccc(c4)n(-c4cnc5c(ccc6cccnc65)c4)c4cccc3c4)cnc12 ; c1ccc(N2c3cccc(c3)N(c3ccccc3)c3ncnc(n3)N(c3ccccc3)c3cccc2c3)cc1 ; c1ccc(N2c3cccc(c3)N(c3ccccc3)c3ncnc(n3)N(c3ccccc3)c3ncnc2n3)cc1]

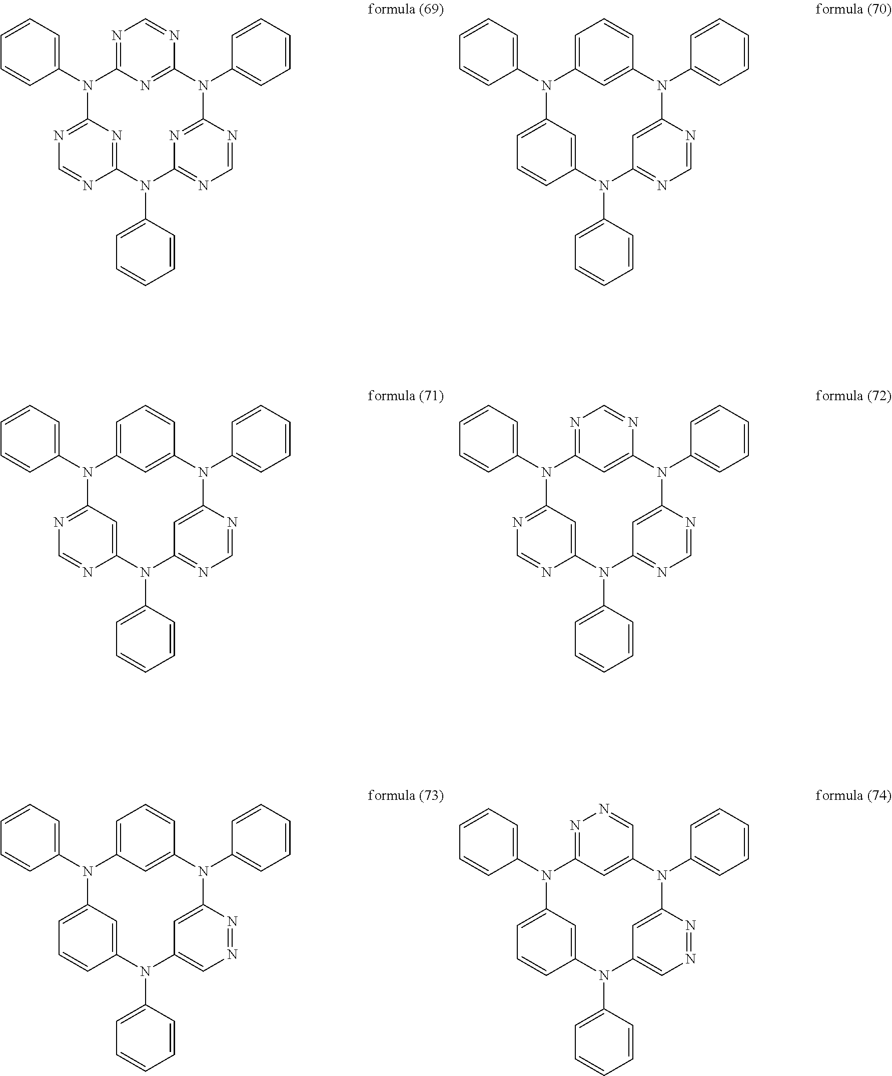 [SMILES: c1ccc(N2c3ncnc(n3)N(c3ccccc3)c3ncnc(n3)N(c3ccccc3)c3ncnc2n3)cc1 ; c1ccc(N2c3cccc(c3)N(c3ccccc3)c3cc(ncn3)N(c3ccccc3)c3cccc2c3)cc1 ; c1ccc(N2c3cccc(c3)N(c3ccccc3)c3cc(ncn3)N(c3ccccc3)c3cc2ncn3)cc1 ; c1ccc(N2c3cc(ncn3)N(c3ccccc3)c3cc(ncn3)N(c3ccccc3)c3cc2ncn3)cc1 ; c1ccc(N2c3cccc(c3)N(c3ccccc3)c3cnnc(c3)N(c3ccccc3)c3cccc2c3)cc1 ; c1ccc(N2c3cccc(c3)N(c3ccccc3)c3cc(cnn3)N(c3ccccc3)c3cc2cnn3)cc1]

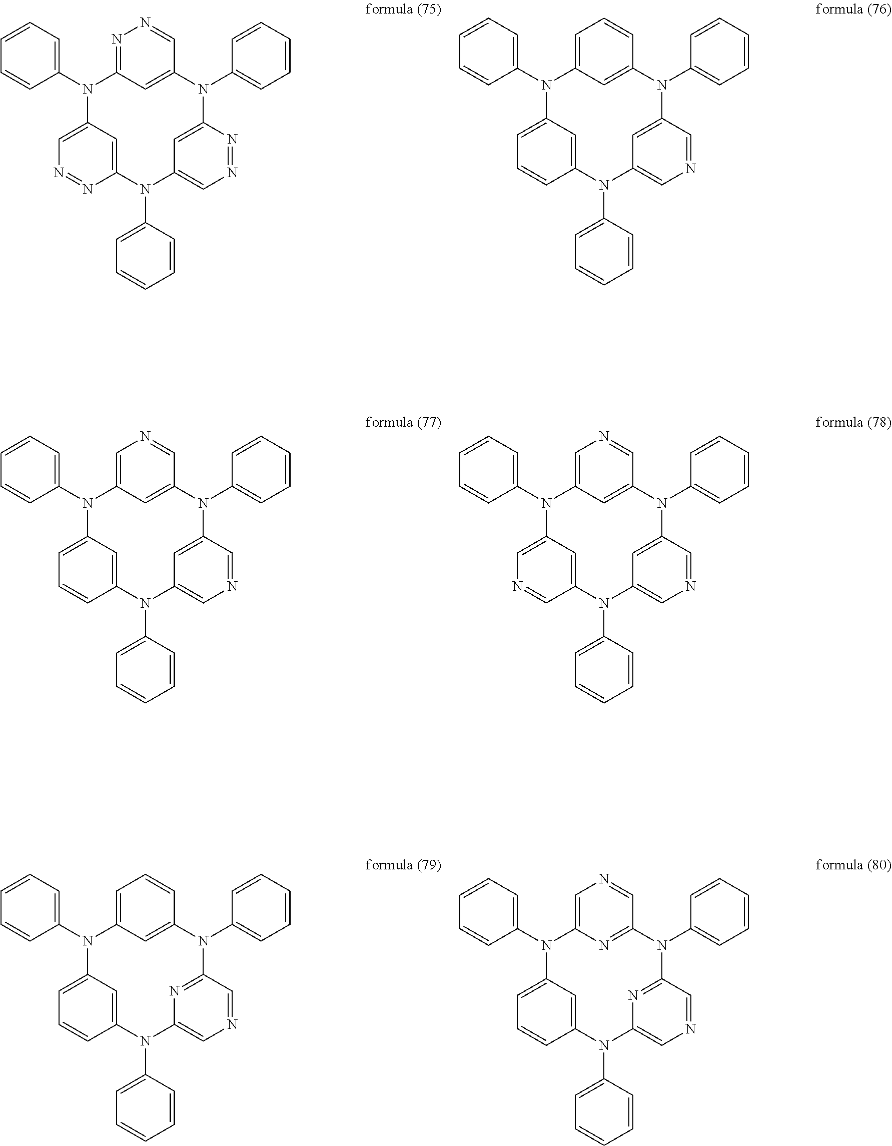 [SMILES: c1ccc(N2c3cnnc(c3)N(c3ccccc3)c3cnnc(c3)N(c3ccccc3)c3cnnc2c3)cc1 ; c1ccc(N2c3cccc(c3)N(c3ccccc3)c3cncc(c3)N(c3ccccc3)c3cccc2c3)cc1 ; c1ccc(N2c3cccc(c3)N(c3ccccc3)c3cncc(c3)N(c3ccccc3)c3cncc2c3)cc1 ; c1ccc(N2c3cncc(c3)N(c3ccccc3)c3cncc(c3)N(c3ccccc3)c3cncc2c3)cc1 ; c1ccc(N2c3cccc(c3)N(c3ccccc3)c3cncc(n3)N(c3ccccc3)c3cccc2c3)cc1 ; c1ccc(N2c3cccc(c3)N(c3ccccc3)c3cncc(n3)N(c3ccccc3)c3cncc2n3)cc1]

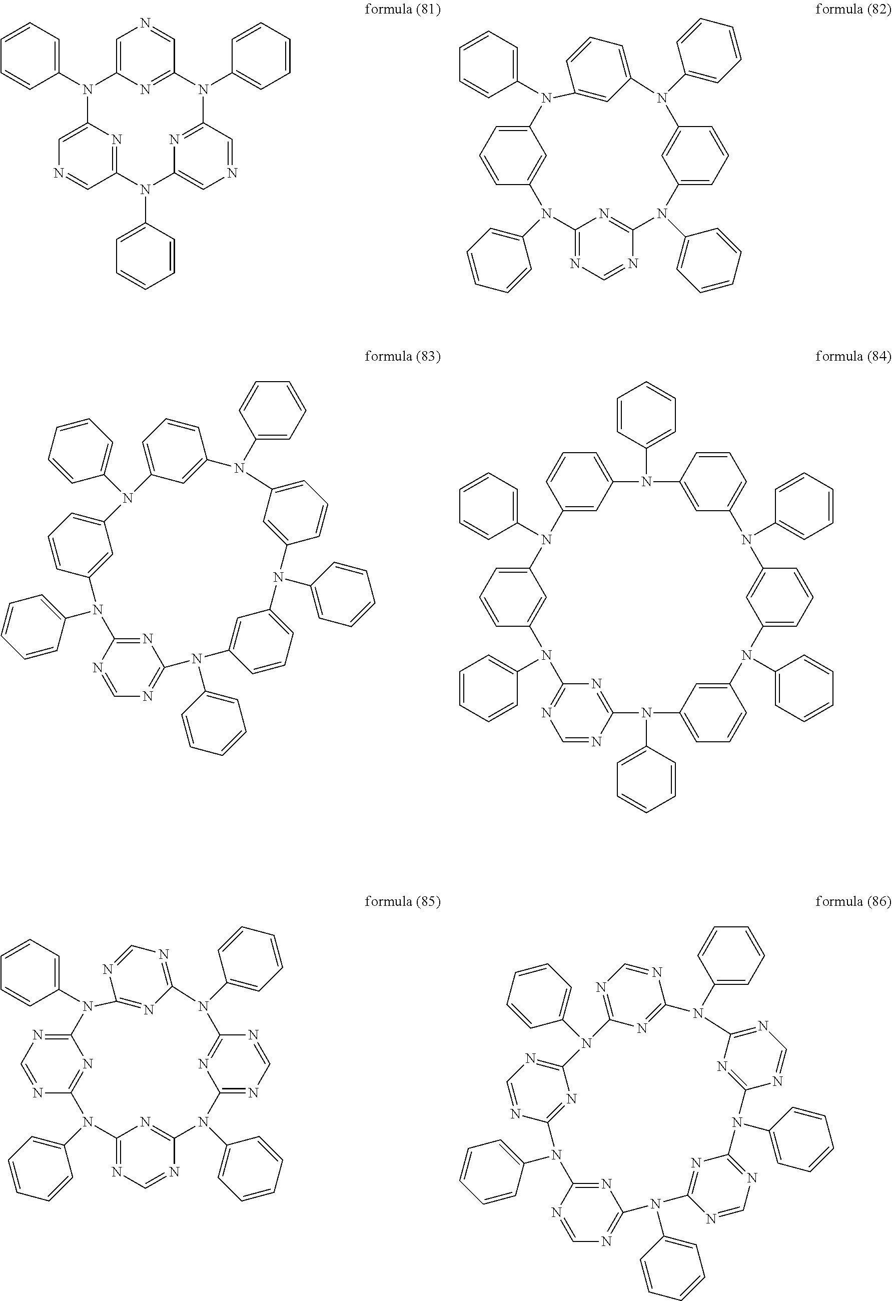

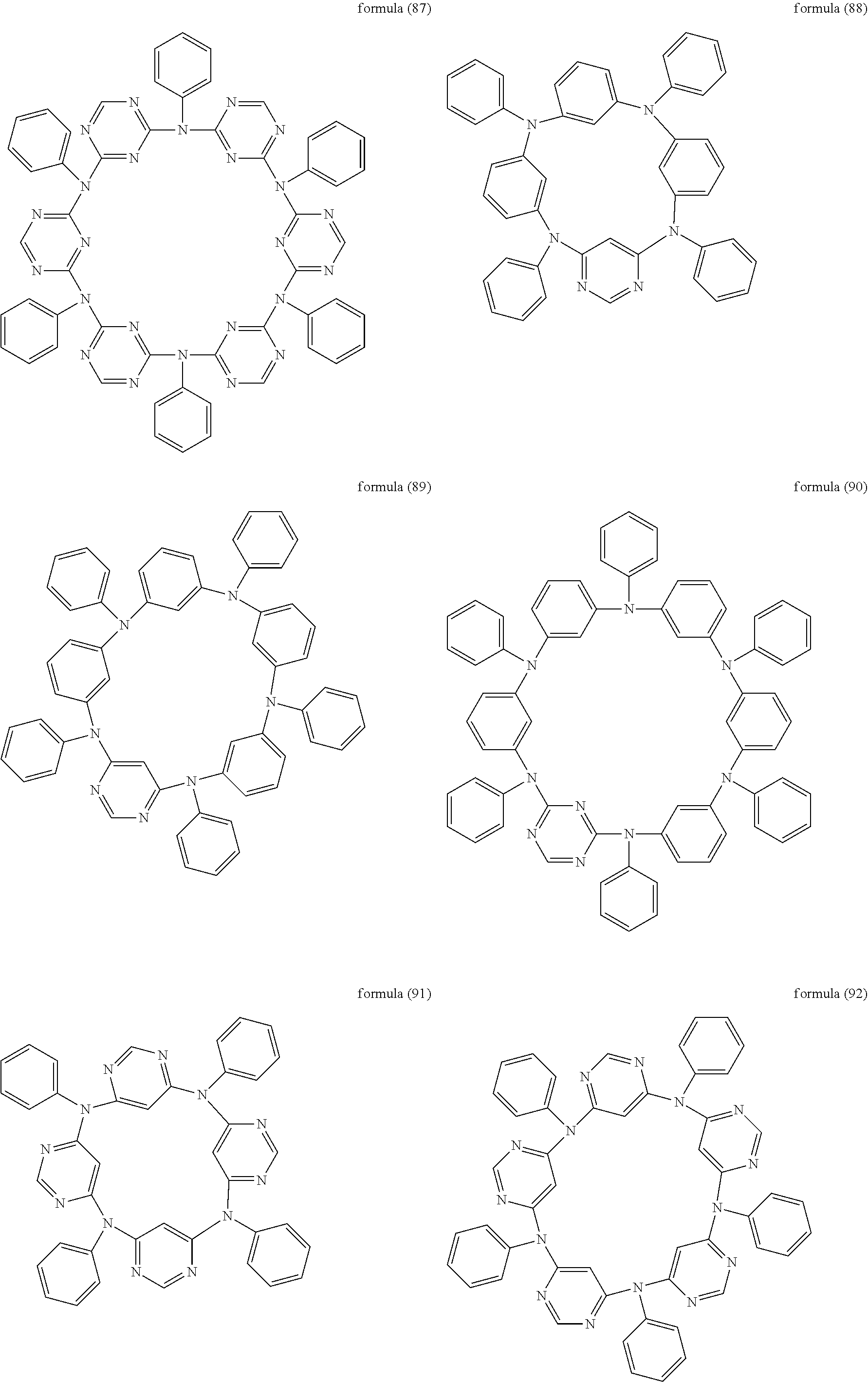

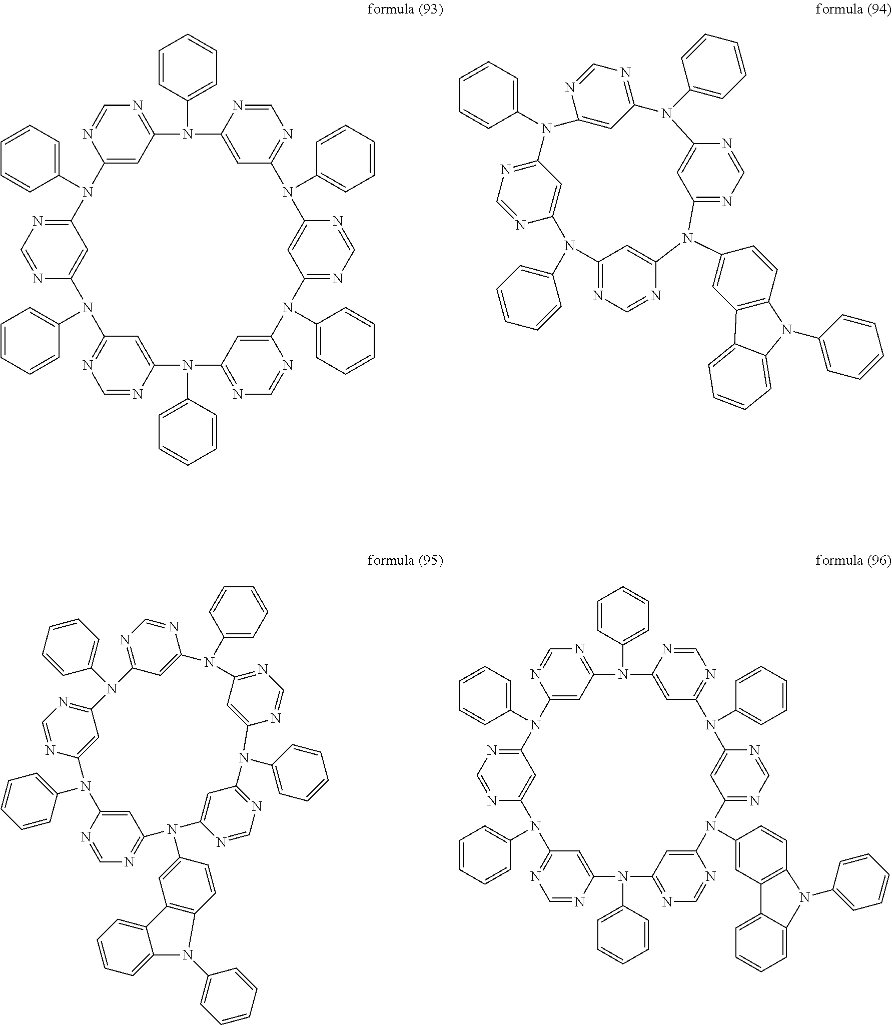

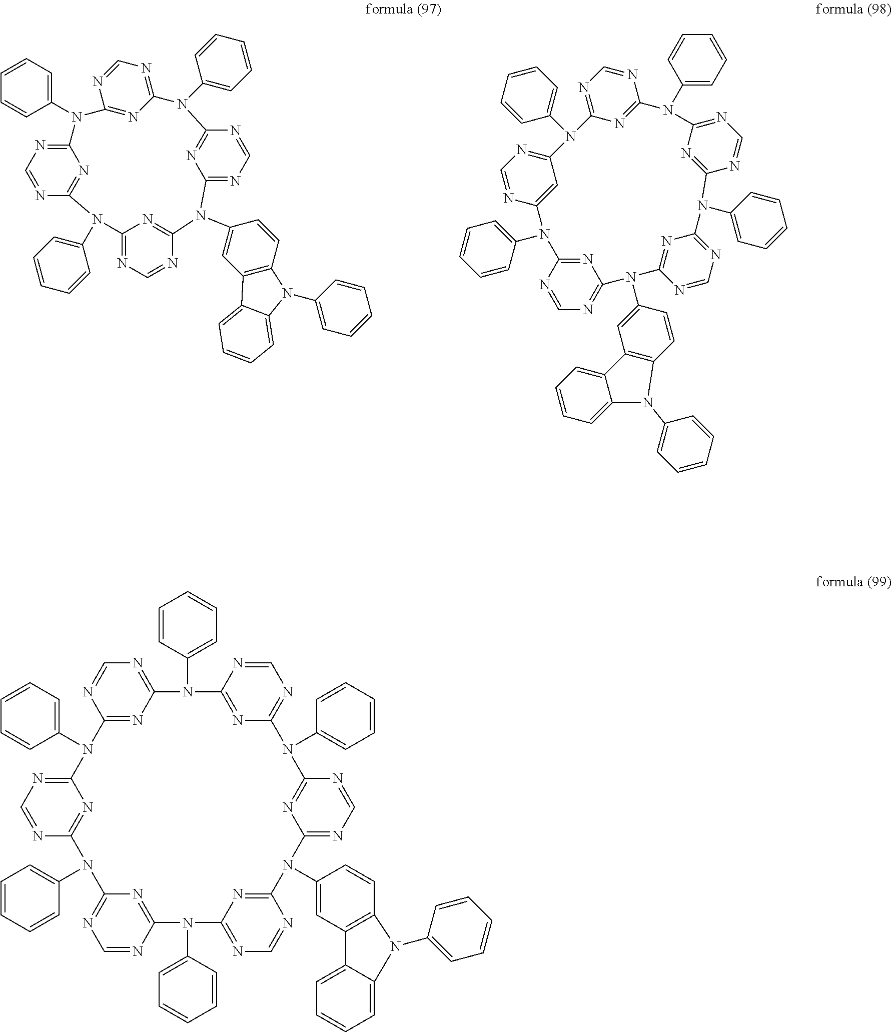 [SMILES: c1ccc(N2c3ncnc(n3)N(c3ccccc3)c3ncnc(n3)N(c3ccc4c(c3)c3ccccc3n4-c3ccccc3)c3ncnc(n3)N(c3ccccc3)c3ncnc2n3)cc1 ; c1ccc(N2c3cc(ncn3)N(c3ccccc3)c3ncnc(n3)N(c3ccc4c(c3)c3ccccc3n4-c3ccccc3)c3ncnc(n3)N(c3ccccc3)c3ncnc(n3)N(c3ccccc3)c3ncnc2n3)cc1 ; c1ccc(-n2c3ncnc(n3)n(-c3ccccc3)c3ncnc(n3)n(-c3ccccc3)c3ncnc(n3)n(-c3ccc4c(c3)c3ccccc3n4-c3ccccc3)c3ncnc(n3)n(-c3ccccc3)c3ncnc(n3)n(-c3ccccc3)c3ncnc2n3)cc1]

In a further embodiment of the present invention, at least one representative of the Ar¹ of the compound of the formula (1) is a divalent group of one of the following formulae (100) or (101):

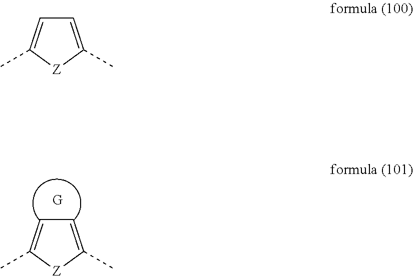

where Z is equal to O, S, SO₂ or NH, and G, together with the two carbon atoms of the 5-membered ring, is an aromatic or heteroaromatic mono- or polycyclic ring system, and the dashed lines on the 5-membered ring represent bonds to the ring nitrogen atoms of the compound of the formula (1).

Examples of compounds of the formulae (100) and (101) are the divalent groups of the following formulae (102) to (110):

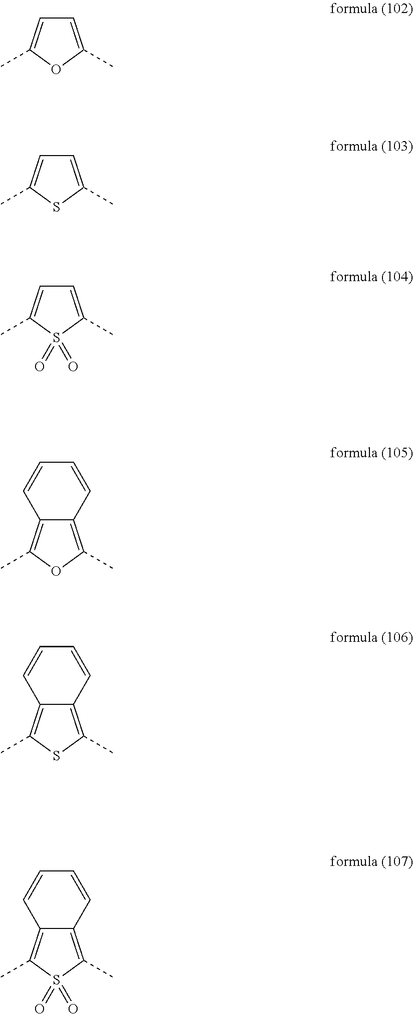

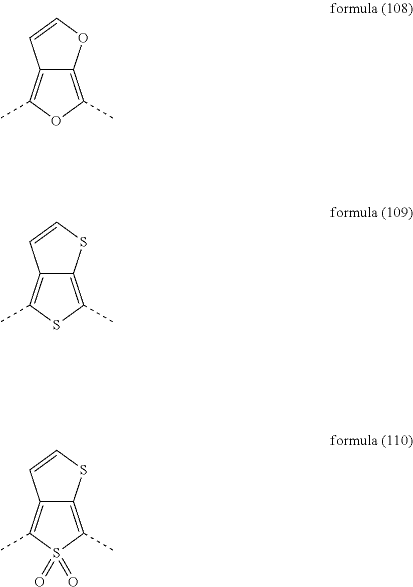

where here too the dashed lines represent bonds to the ring nitrogen atoms of the compound of the formula (1).

Examples of particularly preferred compounds of the formula (100) to (110) are the compounds of the formulae (111) to (143) shown below.

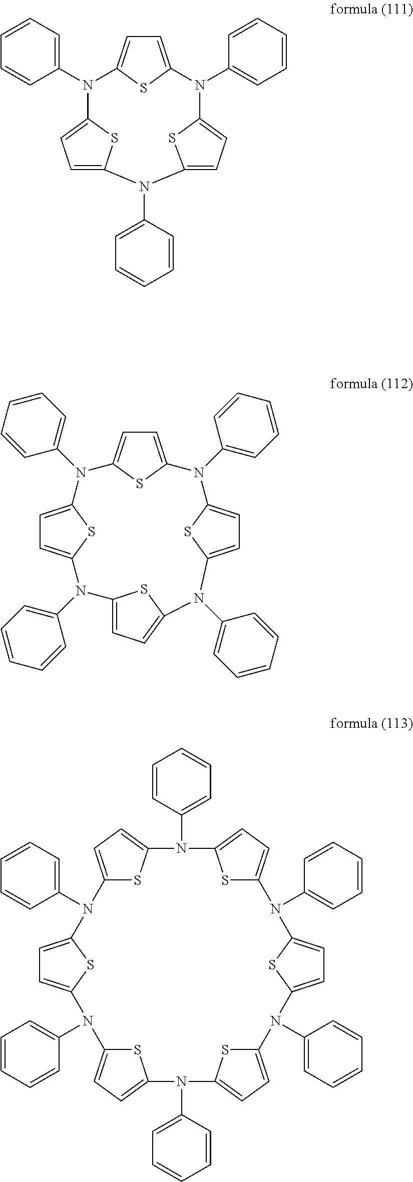 [SMILES: c1ccc(-n2c3ccc(s3)n(-c3ccccc3)c3ccc(s3)n(-c3ccccc3)c3ccc2s3)cc1 ; c1ccc(N2c3ccc(s3)N(c3ccccc3)c3ccc(s3)N(c3ccccc3)c3ccc(s3)N(c3ccccc3)c3ccc2s3)cc1 ; c1ccc(N2c3ccc(s3)N(c3ccccc3)c3ccc(s3)N(c3ccccc3)c3ccc(s3)N(c3ccccc3)c3ccc(s3)N(c3ccccc3)c3ccc(s3)N(c3ccccc3)c3ccc2s3)cc1]

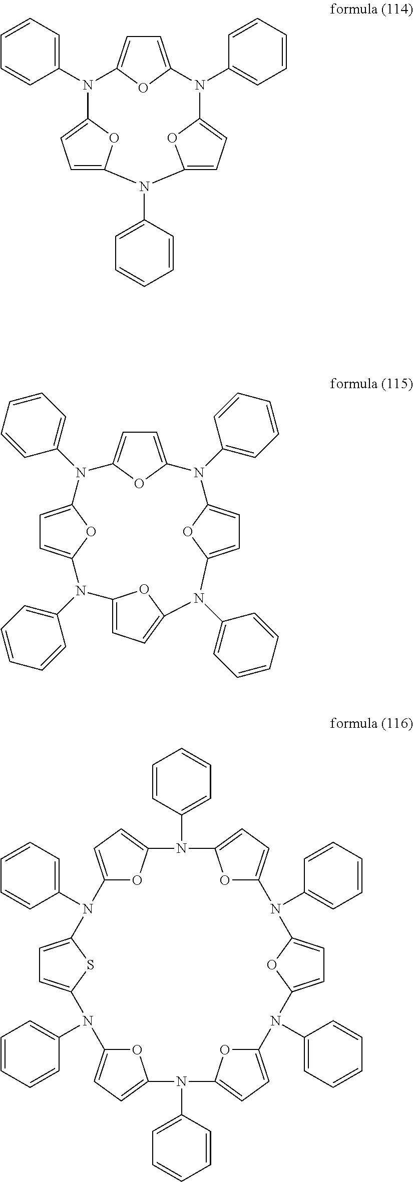 [SMILES: c1ccc(-n2c3ccc(o3)n(-c3ccccc3)c3ccc(o3)n(-c3ccccc3)c3ccc2o3)cc1 ; c1ccc(N2c3ccc(o3)N(c3ccccc3)c3ccc(o3)N(c3ccccc3)c3ccc(o3)N(c3ccccc3)c3ccc2o3)cc1 ; c1ccc(N2c3ccc(o3)N(c3ccccc3)c3ccc(o3)N(c3ccccc3)c3ccc(o3)N(c3ccccc3)c3ccc(s3)N(c3ccccc3)c3ccc(o3)N(c3ccccc3)c3ccc2o3)cc1]

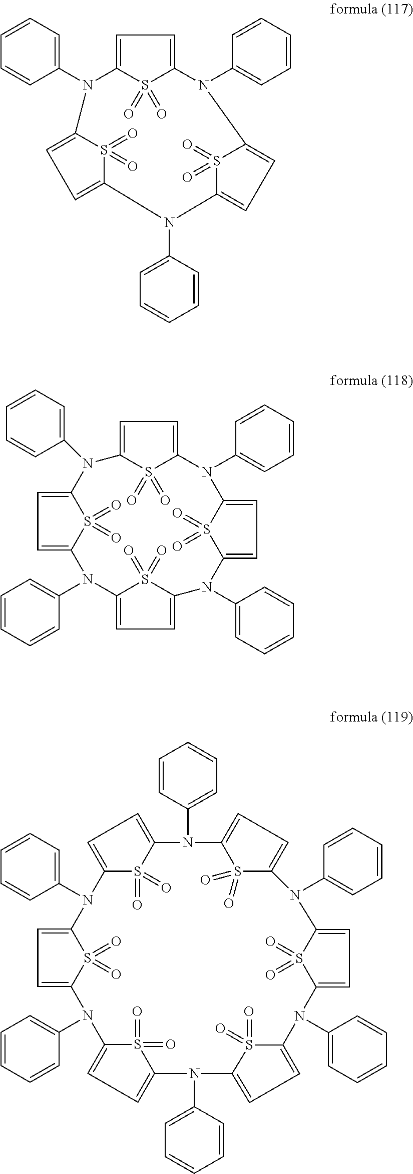 [SMILES: O=S1(=O)C2=CC=C1N(c1ccccc1)C1=CC=C(N(c3ccccc3)C3=CC=C(N2c2ccccc2)S3(=O)=O)S1(=O)=O ; O=S1(=O)C2=CC=C1N(c1ccccc1)C1=CC=C(N(c3ccccc3)C3=CC=C(N(c4ccccc4)C4=CC=C(N2c2ccccc2)S4(=O)=O)S3(=O)=O)S1(=O)=O ; O=S1(=O)C2=CC=C1N(c1ccccc1)C1=CC=C(N(c3ccccc3)C3=CC=C(N(c4ccccc4)C4=CC=C(N(c5ccccc5)C5=CC=C(N(c6ccccc6)C6=CC=C(N2c2ccccc2)S6(=O)=O)S5(=O)=O)S4(=O)=O)S3(=O)=O)S1(=O)=O]

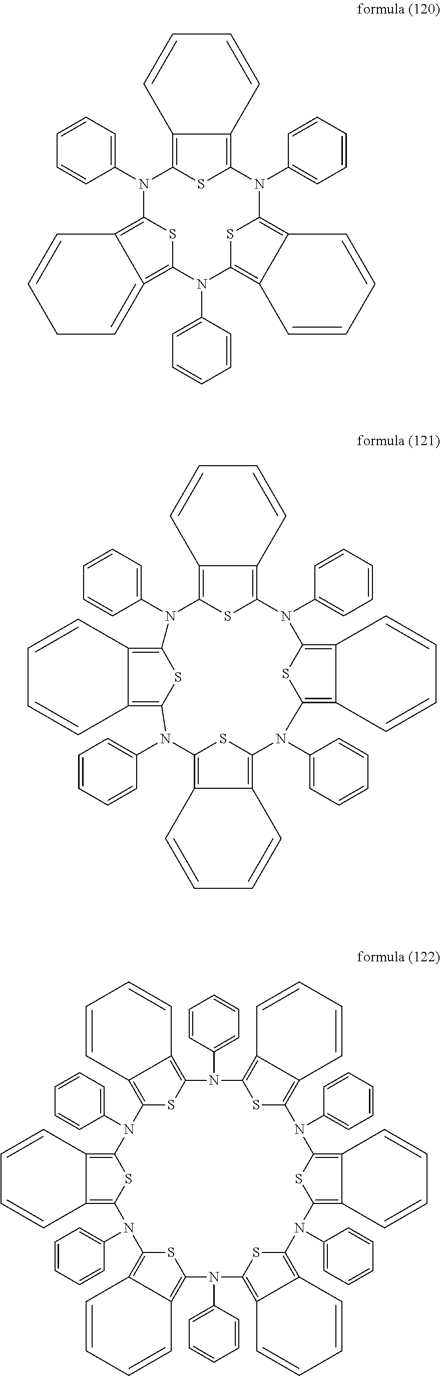

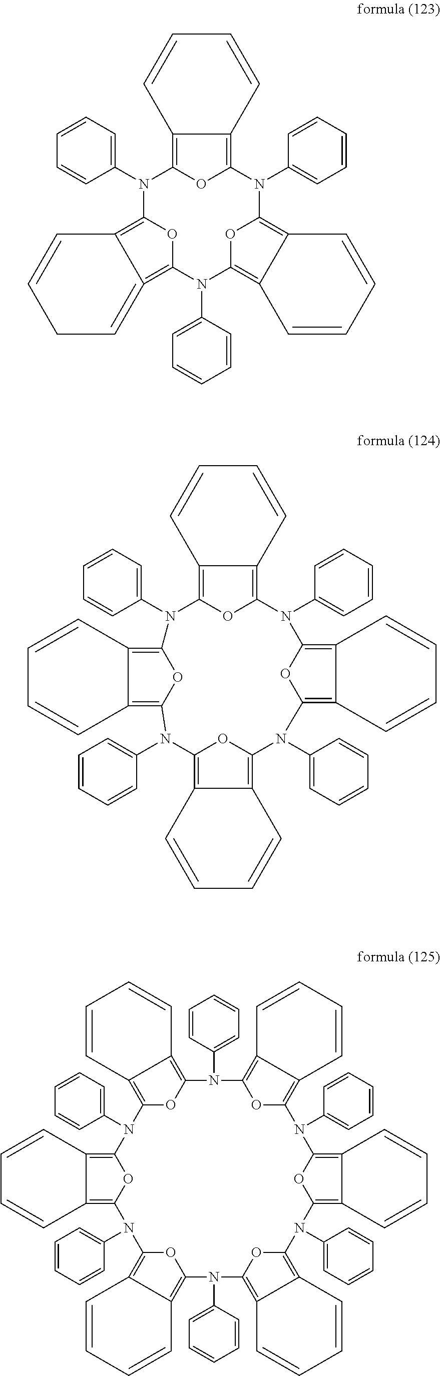

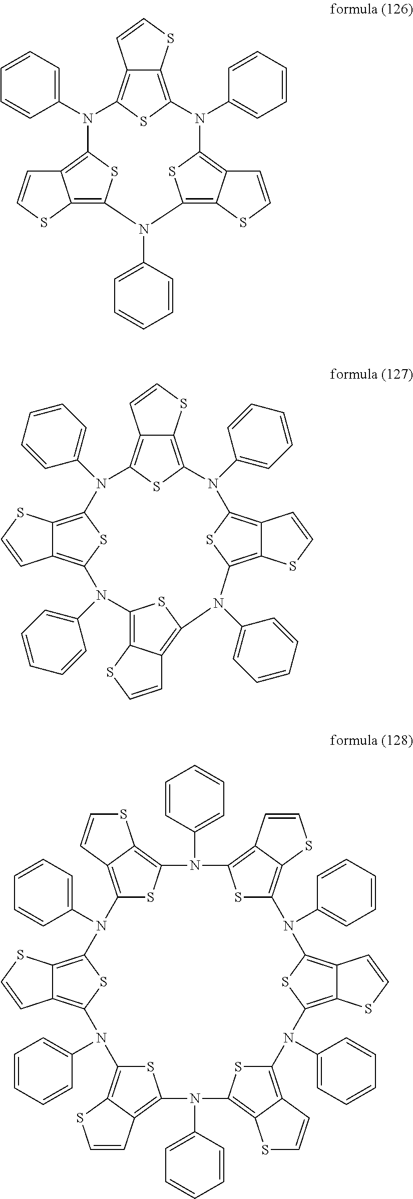 [SMILES: c1ccc(-n2c3sc(c4sccc43)n(-c3ccccc3)c3sc(c4sccc43)n(-c3ccccc3)c3sc2c2ccsc23)cc1 ; c1ccc(N2c3sc(c4sccc34)N(c3ccccc3)c3sc(c4sccc34)N(c3ccccc3)c3sc(c4sccc34)N(c3ccccc3)c3sc2c2sccc32)cc1 ; c1ccc(N2c3sc(c4sccc34)N(c3ccccc3)c3sc(c4sccc34)N(c3ccccc3)c3sc(c4sccc34)N(c3ccccc3)c3sc(c4sccc34)N(c3ccccc3)c3sc(c4sccc34)N(c3ccccc3)c3sc2c2sccc32)cc1]

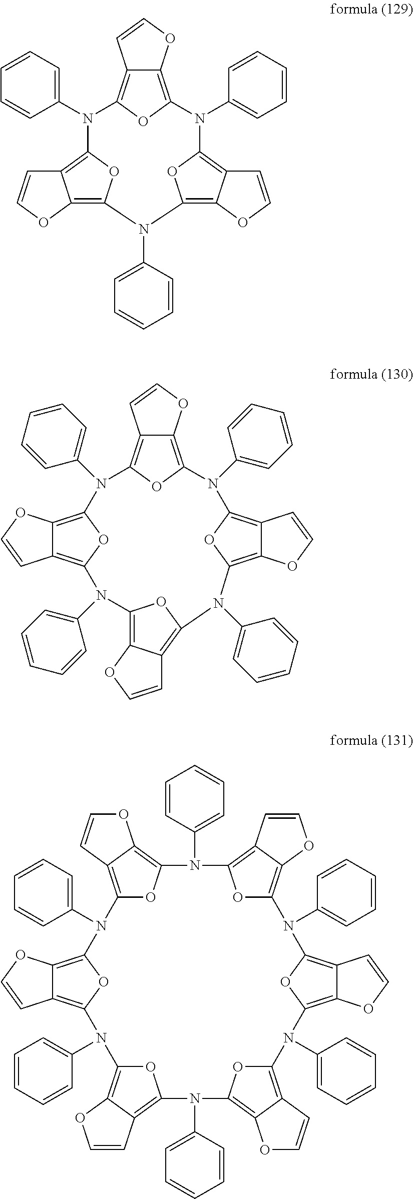 [SMILES: c1ccc(-n2c3oc(c4occc43)n(-c3ccccc3)c3oc(c4occc43)n(-c3ccccc3)c3oc2c2ccoc23)cc1 ; c1ccc(N2c3oc(c4occc34)N(c3ccccc3)c3oc(c4occc34)N(c3ccccc3)c3oc(c4occc34)N(c3ccccc3)c3oc2c2occc32)cc1 ; c1ccc(N2c3oc(c4occc34)N(c3ccccc3)c3oc(c4occc34)N(c3ccccc3)c3oc(c4occc34)N(c3ccccc3)c3oc(c4occc34)N(c3ccccc3)c3oc(c4occc34)N(c3ccccc3)c3oc2c2occc32)cc1]

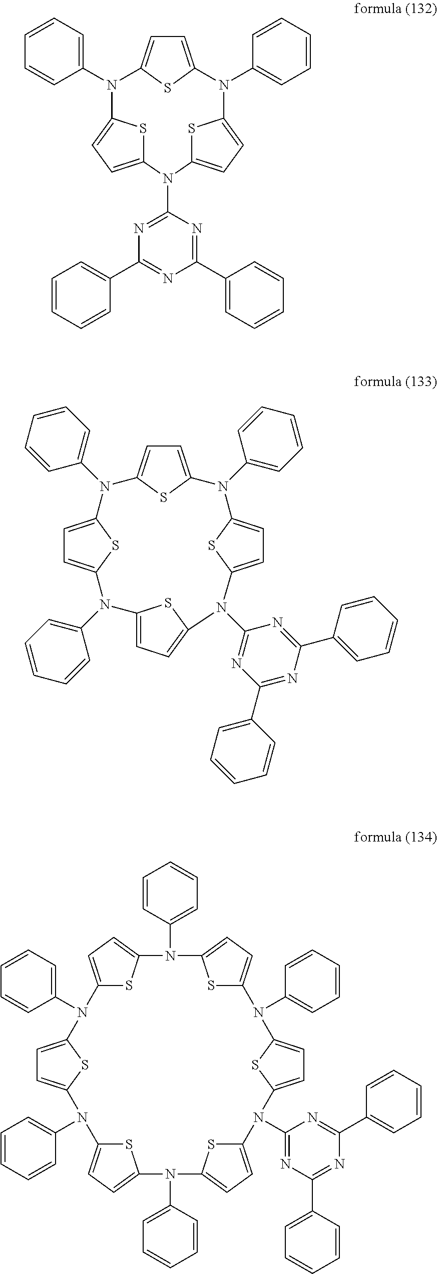 [SMILES: c1ccc(-c2nc(-c3ccccc3)nc(-n3c4ccc(s4)n(-c4ccccc4)c4ccc(s4)n(-c4ccccc4)c4ccc3s4)n2)cc1 ; c1ccc(-c2nc(-c3ccccc3)nc(N3c4ccc(s4)N(c4ccccc4)c4ccc(s4)N(c4ccccc4)c4ccc(s4)N(c4ccccc4)c4ccc3s4)n2)cc1 ; c1ccc(-c2nc(-c3ccccc3)nc(N3c4ccc(s4)N(c4ccccc4)c4ccc(s4)N(c4ccccc4)c4ccc(s4)N(c4ccccc4)c4ccc(s4)N(c4ccccc4)c4ccc(s4)N(c4ccccc4)c4ccc3s4)n2)cc1]

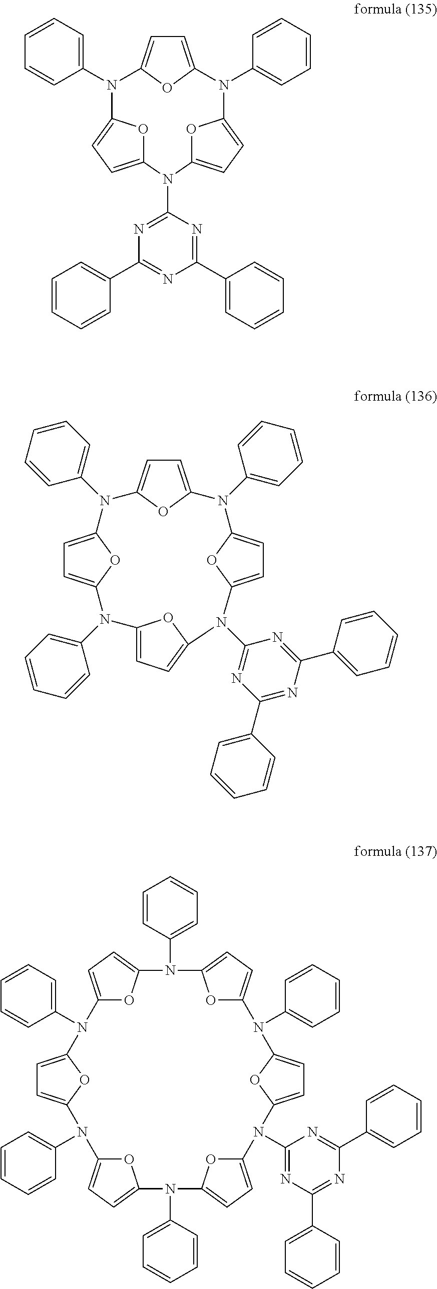 [SMILES: c1ccc(-c2nc(-c3ccccc3)nc(-n3c4ccc(o4)n(-c4ccccc4)c4ccc(o4)n(-c4ccccc4)c4ccc3o4)n2)cc1 ; c1ccc(-c2nc(-c3ccccc3)nc(N3c4ccc(o4)N(c4ccccc4)c4ccc(o4)N(c4ccccc4)c4ccc(o4)N(c4ccccc4)c4ccc3o4)n2)cc1 ; c1ccc(-c2nc(-c3ccccc3)nc(N3c4ccc(o4)N(c4ccccc4)c4ccc(o4)N(c4ccccc4)c4ccc(o4)N(c4ccccc4)c4ccc(o4)N(c4ccccc4)c4ccc(o4)N(c4ccccc4)c4ccc3o4)n2)cc1]

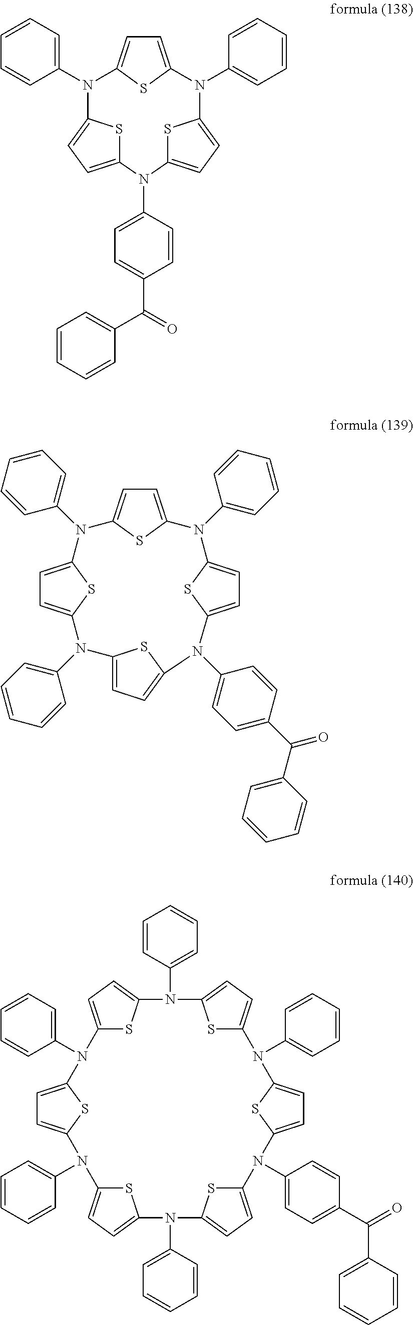 [SMILES: O=C(c1ccccc1)c1ccc(-n2c3ccc(s3)n(-c3ccccc3)c3ccc(s3)n(-c3ccccc3)c3ccc2s3)cc1 ; O=C(c1ccccc1)c1ccc(N2c3ccc(s3)N(c3ccccc3)c3ccc(s3)N(c3ccccc3)c3ccc(s3)N(c3ccccc3)c3ccc2s3)cc1 ; O=C(c1ccccc1)c1ccc(N2c3ccc(s3)N(c3ccccc3)c3ccc(s3)N(c3ccccc3)c3ccc(s3)N(c3ccccc3)c3ccc(s3)N(c3ccccc3)c3ccc(s3)N(c3ccccc3)c3ccc2s3)cc1]

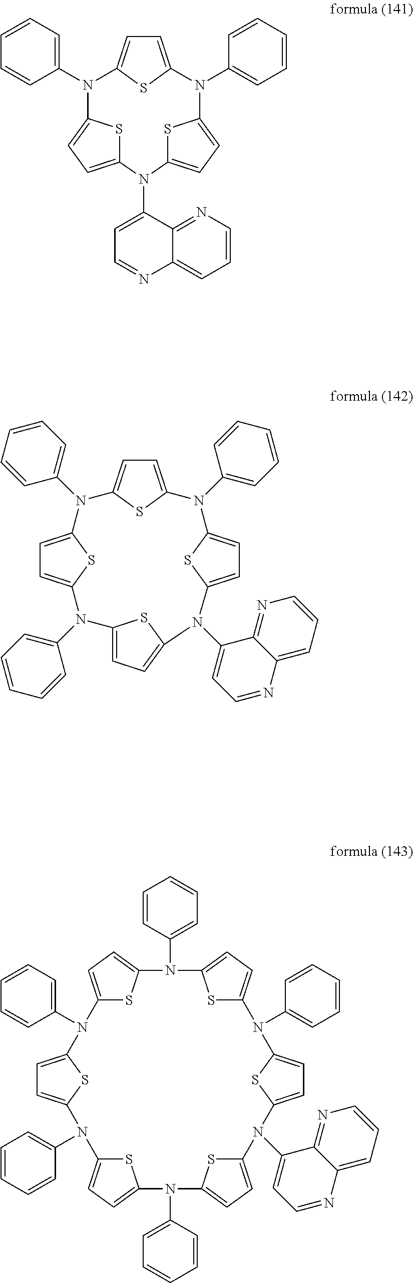 [SMILES: c1ccc(-n2c3ccc(s3)n(-c3ccccc3)c3ccc(s3)n(-c3ccnc4cccnc34)c3ccc2s3)cc1 ; c1ccc(N2c3ccc(s3)N(c3ccccc3)c3ccc(s3)N(c3ccnc4cccnc34)c3ccc(s3)N(c3ccccc3)c3ccc2s3)cc1 ; c1ccc(N2c3ccc(s3)N(c3ccccc3)c3ccc(s3)N(c3ccccc3)c3ccc(s3)N(c3ccnc4cccnc34)c3ccc(s3)N(c3ccccc3)c3ccc(s3)N(c3ccccc3)c3ccc2s3)cc1]

It is preferred in an organic electronic device in accordance with one of the embodiments of the present invention that at least one Ar² is a monovalent radical which is selected from the group which consists of the following formulae (144) to (156) and an aromatic or heteroaromatic ring system containing a keto group. This is the case, in particular, if all radicals Ar¹ are divalent aromatic units which contain no heteroatoms, and if the compound is employed as matrix material and/or as electron-transport material and/or as hole-blocking material and/or as exciton-blocking material, as described above and below.

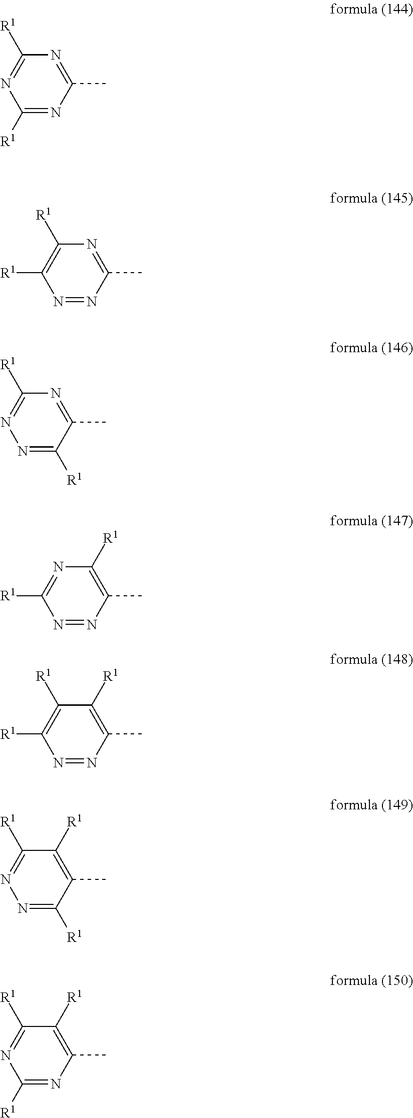

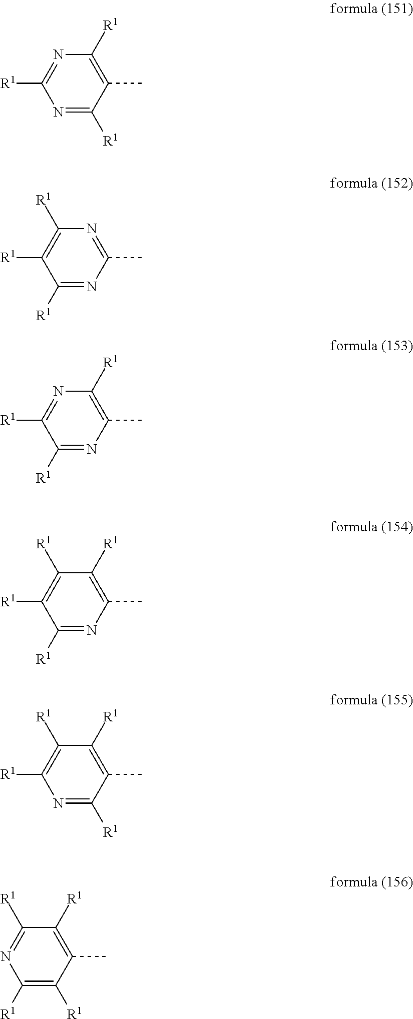

where the dashed line in each case represents a bond to the ring nitrogen atom of the compound of the formula (1); and R¹ is as defined above.

The compounds of the formula (1) preferably have a glass-transition temperature T_{G} of greater than 70° C., particularly preferably greater than 90° C., very particularly preferably greater than 110° C.

As described above, the compounds of the formula (1) are used as matrix materials for phosphorescent emitter compounds. The phosphorescent emitter compounds here are preferably employed in at least one layer of the organic electronic device according to the invention.

A phosphorescent emitter compound is generally taken to mean a compound which exhibits luminescence from an excited state having relatively high spin multiplicity, i.e. a spin state>1, such as, for example, from an excited triplet state (triplet emitter), from an MLCT mixed state or a quintet state (quintet emitter). Suitable phosphorescent emitter compounds are, in particular, compounds which emit light, preferably in the visible region, on suitable excitation and in addition contain at least one atom having atomic numbers>38 and <84, particularly preferably >56 and <80. Preferred phosphorescence emitters are compounds which contain copper, molybdenum, tungsten, rhenium, ruthenium, osmium, rhodium, iridium, palladium, platinum, silver, gold or europium, in particular compounds which contain iridium, platinum or copper. Examples of the emitters described above are revealed by the applications WO 00/7065, WO 01/41512, WO 02/02714, WO 02/15645, EP 1191613, EP 1191612, EP 1191614, WO 2005/033244. In general, suitable phosphorescent complexes are all those as are used in accordance with the prior art for phosphorescent OLEDs and as are known to the person skilled in the art in the area of organic electroluminescence.

Suitable phosphorescent emitter compounds are, in particular, compounds which emit light, preferably in the visible region, on suitable excitation and in addition contain at least one atom having an atomic number greater than 20, preferably greater than 38 and less than 84, particularly preferably greater than 56 and less than 80. The phosphorescence emitters used are preferably compounds which contain copper, molybdenum, tungsten, rhenium, ruthenium, osmium, rhodium, iridium, palladium, platinum, silver, gold or europium, in particular compounds which contain iridium or platinum.

Particularly preferred organic electronic devices comprise, as phosphorescent emitter compounds, at least one compound of the formulae (157) to (160),

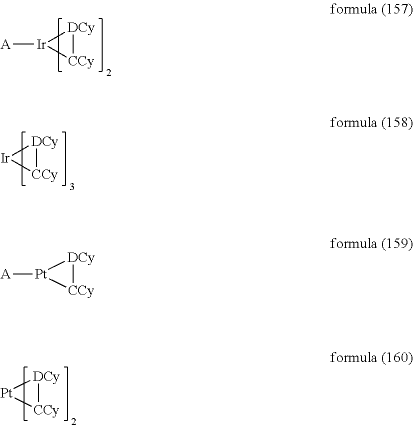

where:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are con-nected to one another via a covalent bond;
CCy is, identically or differently on each occurrence, a cyclic group which contains a carbon atom via which the cyclic group is bonded to the metal and may in turn carry one or more substituents R¹;
A is, identically or differently on each occurrence, a monoanionic, bidentate-chelating ligand, preferably a diketonate ligand.

A bridge may also be present between the groups DCy and CCy here through the formation of ring systems between a plurality of radicals R¹.

Examples of the emitters described above are revealed by the applications WO 00/70655, WO 01/41512, WO 02/02714, WO 02/15645, EP 1191613, EP 1191612, EP 1191614 and WO 2005/033244. In general, all phosphorescent complexes as are used in accordance with the prior art for phosphorescent OLEDs and as are known to the person skilled in the art in the area of organic electroluminescence are suitable, and the person skilled in the art will be able to use further phosphorescent complexes without inventive step. Examples of suitable phosphorescent compounds are shown in the following table.

| | |
|---|---|
| 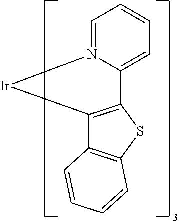 | formula (161) |
| 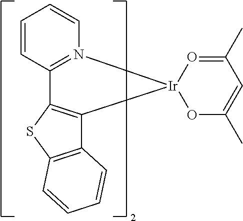 | formula (162) |
| 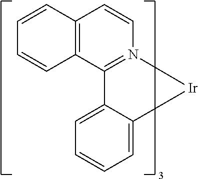 | formula (163) |
| 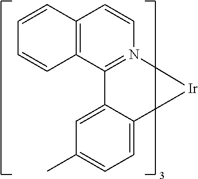 | formula (164) |
| 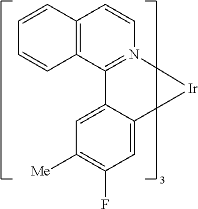 | formula (165) |
| 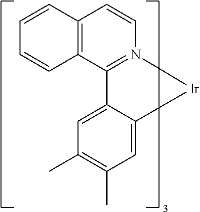 | formula (166) |
| 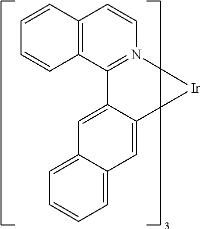 | formula (167) |
| 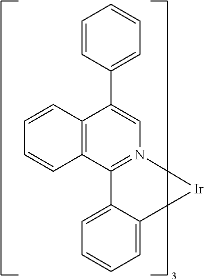 | formula (168) |
| 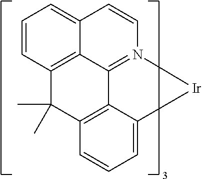 | formula (169) |
| 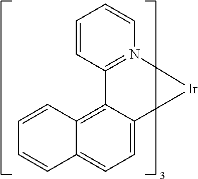 | formula (170) |
| 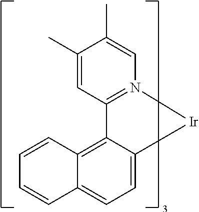 | formula (171) |
| 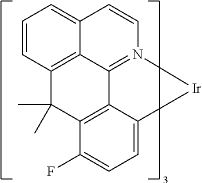 | formula (172) |
| 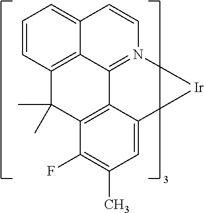 | formula (173) |
| 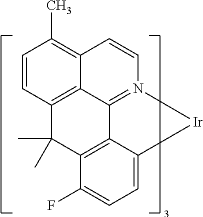 | formula (174) |
| 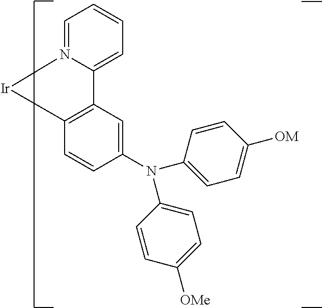 | formula (175) |
| 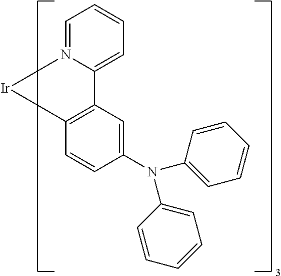 | formula (176) |
| 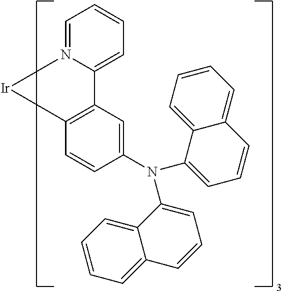 | formula (177) |
| 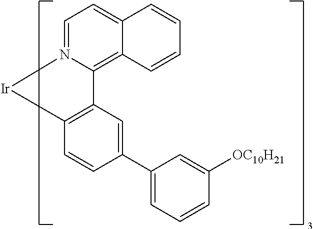 | formula (178) |
| 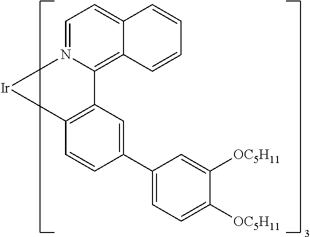 | formula (179) |
| 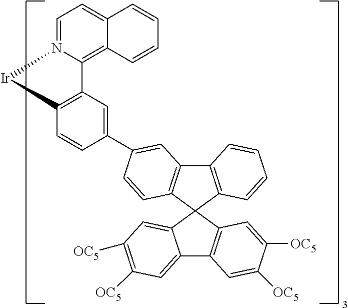 | formula (180) |
| 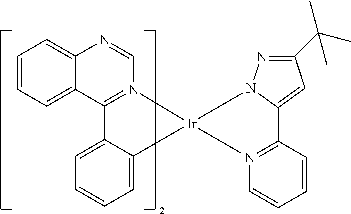 | formula (181) |
| 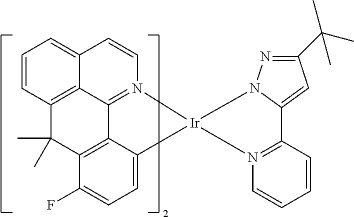 | formula (182) |
| 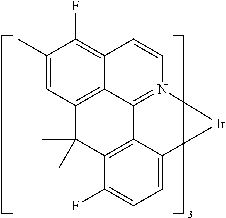 | formula (183) |
| 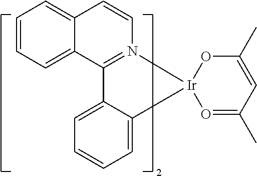 | formula (184) |
| 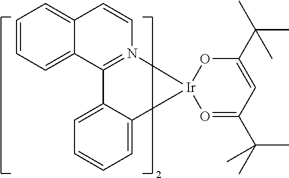 | formula (185) |
| 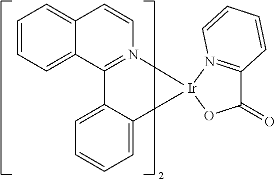 | formula (186) |
| 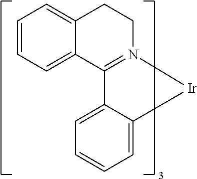 | formula (187) |
| 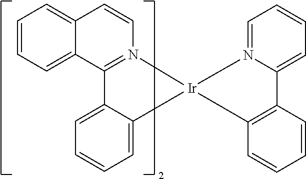 | formula (188) |
| 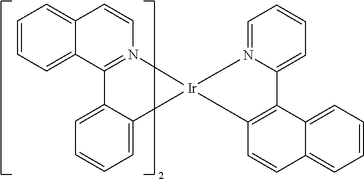 | formula (189) |
| 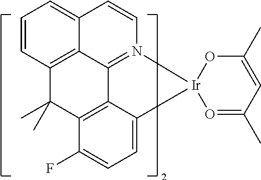 | formula (190) |
| 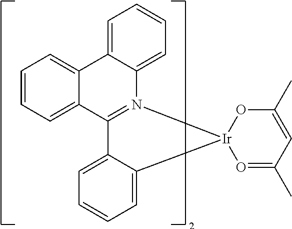 | formula (191) |
| 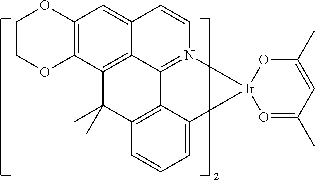 | formula (192) |
| 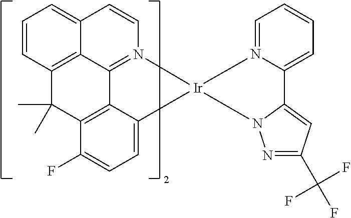 | formula (193) |
| 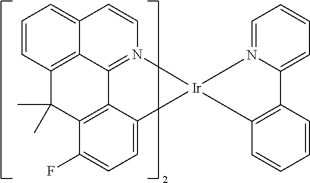 | formula (194) |
| 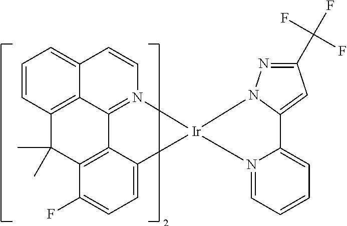 | formula (195) |
| 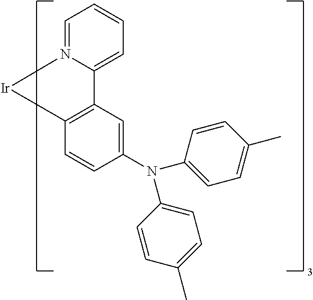 | formula (196) |
| 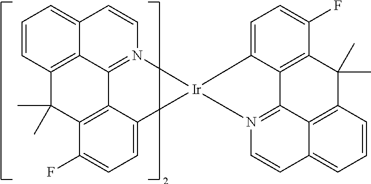 | formula (197) |
| 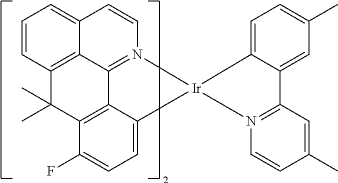 | formula (198) |
| 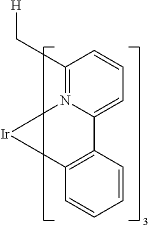 | formula (199) |
| 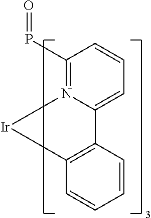 | formula (200) |
| 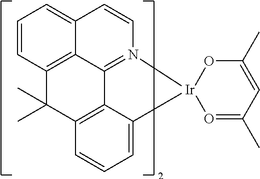 | formula (201) |
| 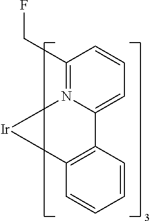 | formula (202) |
| 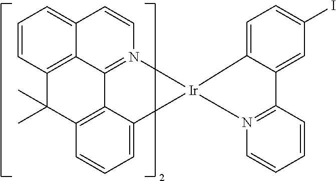 | formula (203) |
| 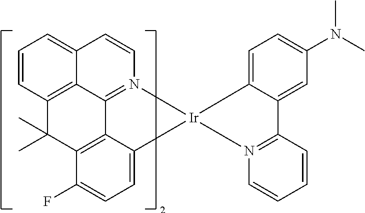 | formula (204) |
| 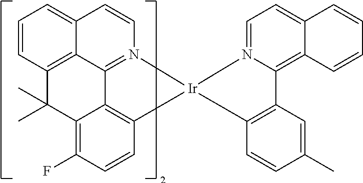 | formula (205) |
| 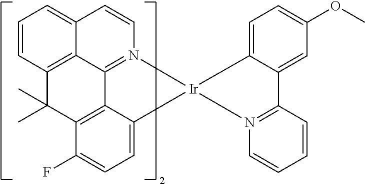 | formula (206) |
| 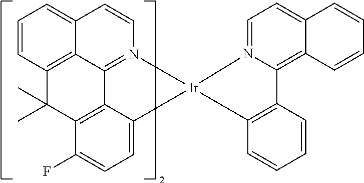 | formula (207) |
| 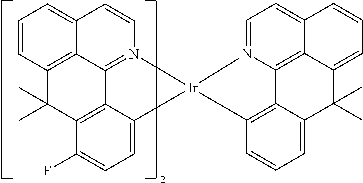 | formula (208) |
| 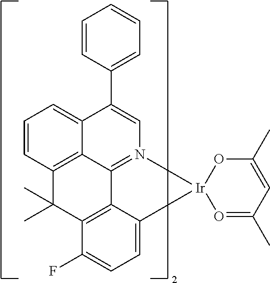 | formula (209) |
| 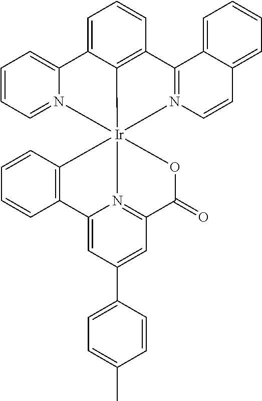 | formula (210) |
| 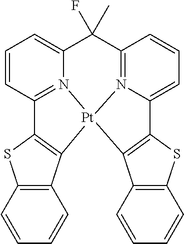 | formula (211) |
| 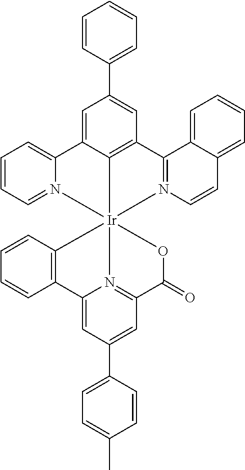 | formula (212) |
| 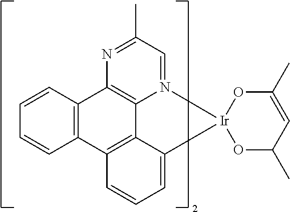 | formula (213) |
| 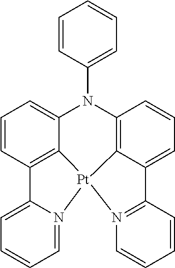 | formula (214) |
| 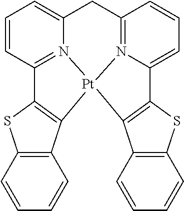 | formula (215) |
| 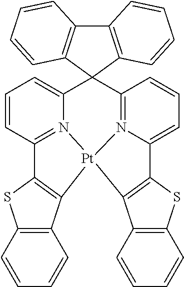 | formula (216) |
| 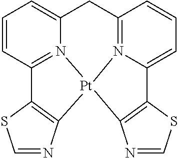 | formula (217) |
| 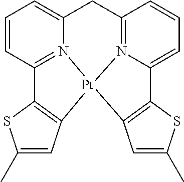 | formula (218) |
| 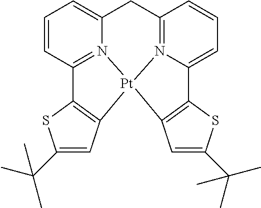 | formula (219) |
| 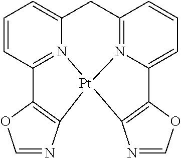 | formula (220) |
| 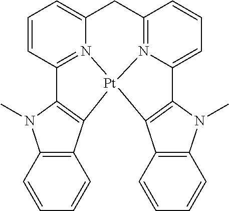 | formula (221) |
| 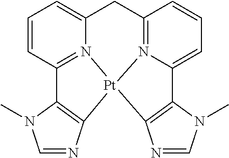 | formula (222) |
| 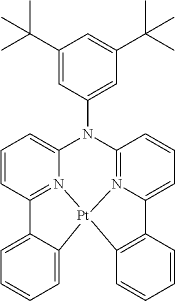 | formula (223) |
| 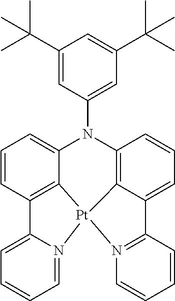 | formula (224) |
| 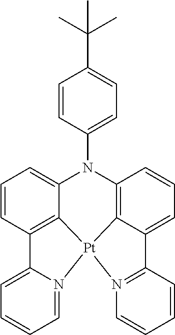 | formula (225) |
| 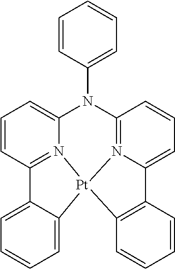 | formula (226) |
| 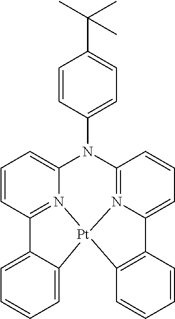 | formula (227) |
| 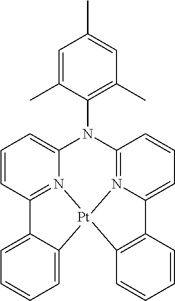 | formula (228) |
| 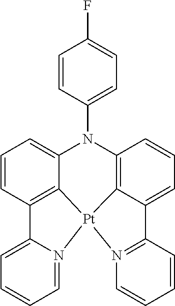 | formula (229) |
| 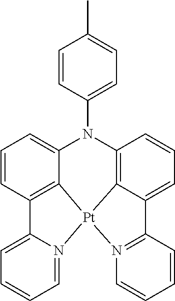 | formula (230) |
| 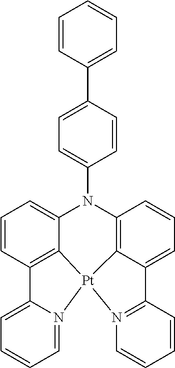 | formula (231) |
| 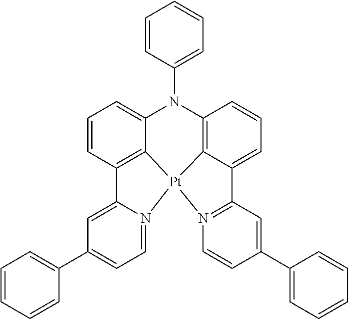 | formula (232) |
| 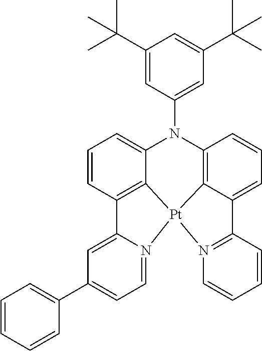 | formula (233) |
| 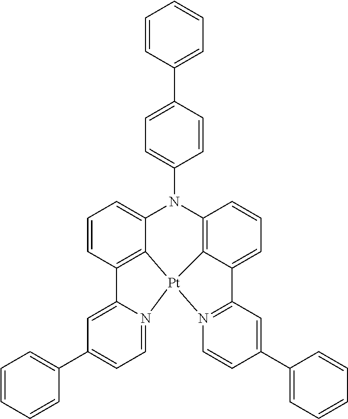 | formula (234) |
| 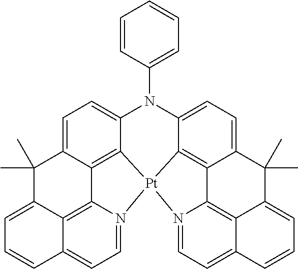 | formula (235) |
| 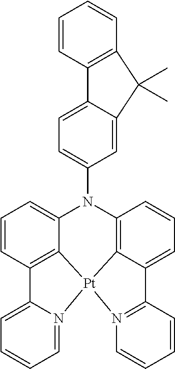 | formula (236) |
| 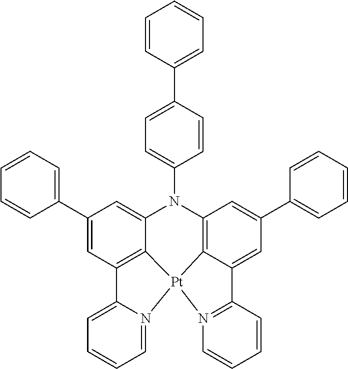 | formula (237) |
| 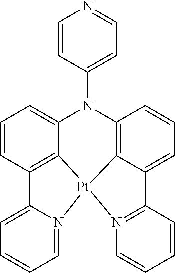 | formula (238) |
| 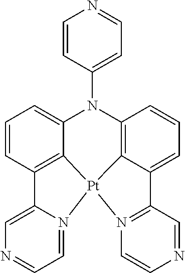 | formula (239) |
| 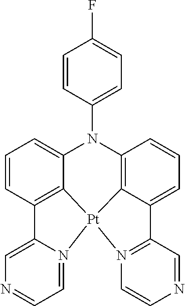 | formula (240) |
| 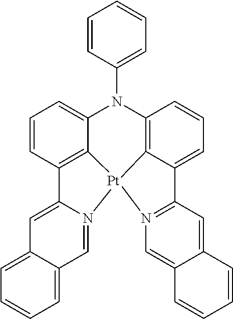 | formula (241) |
| 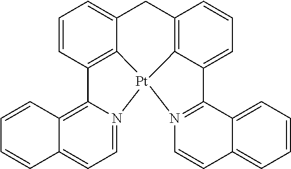 | formula (242) |
| 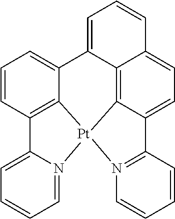 | formula (243) |
| 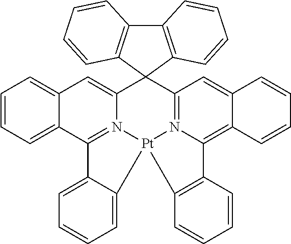 | formula (244) |
| 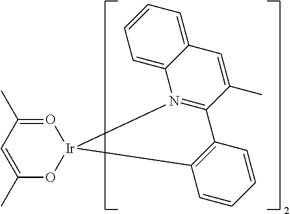 | formula (245) |
| 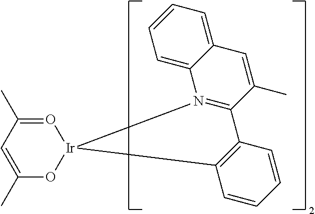 | formula (246) |
| 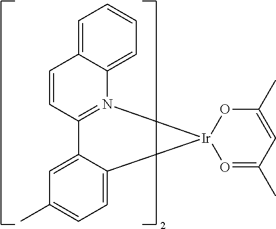 | formula (247) |
| 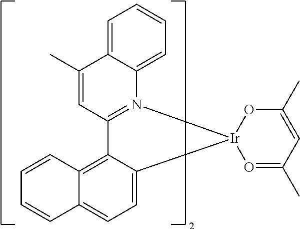 | formula (248) |
| 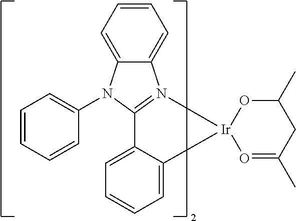 | formula (249) |
| 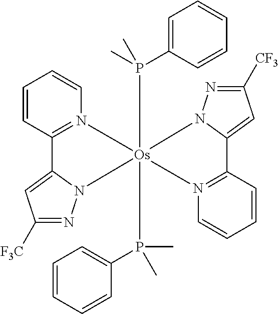 | formula (250) |
| 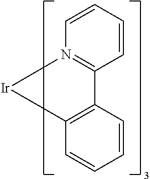 | formula (251) |
| 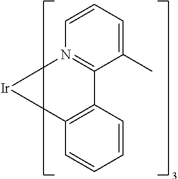 | formula (252) |
| 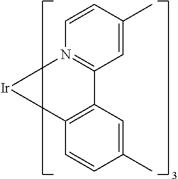 | formula (253) |
| 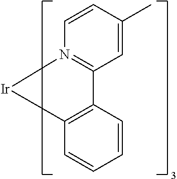 | formula (254) |
| 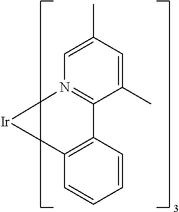 | formula (255) |
| 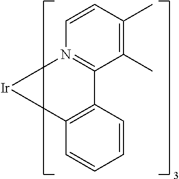 | formula (256) |
| 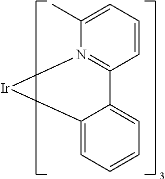 | formula (257) |
| 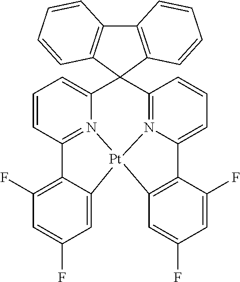 | formula (258) |
| 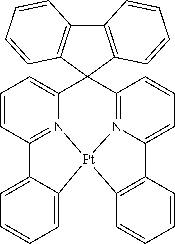 | formula (259) |
| 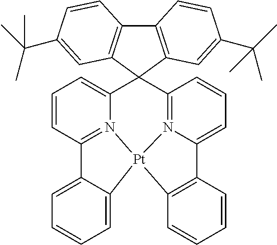 | formula (260) |
| 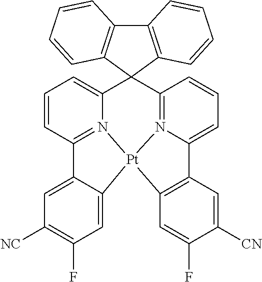 | formula (261) |
| 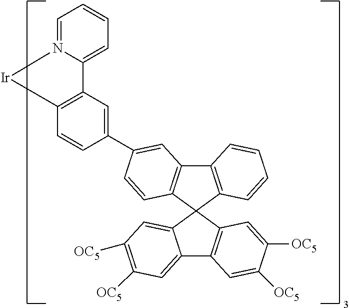 | formula (262) |
| 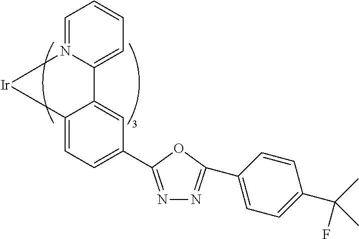 | formula (263) |
| 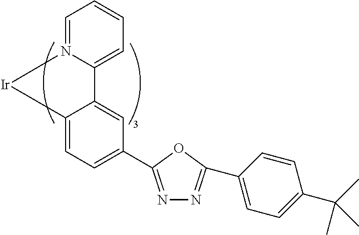 | formula (264) |
| 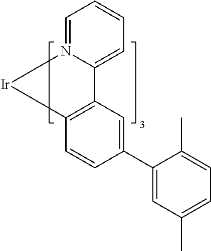 | formula (265) |
| 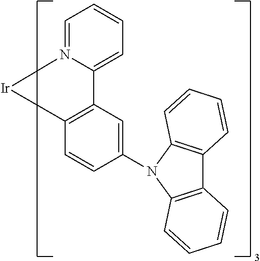 | formula (266) |
| 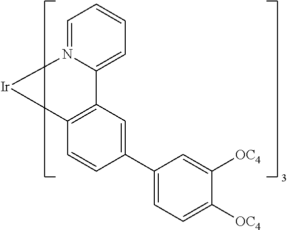 | formula (267) |
| 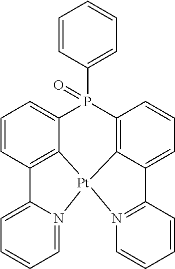 | formula (268) |
| 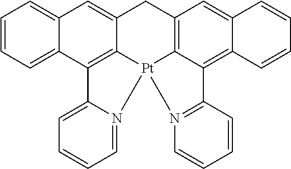 | formula (269) |
| 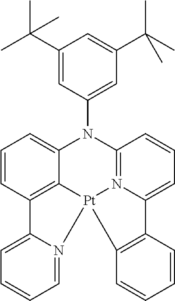 | formula (270) |
| 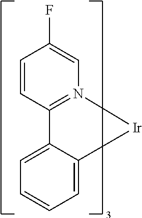 | formula (271) |
| 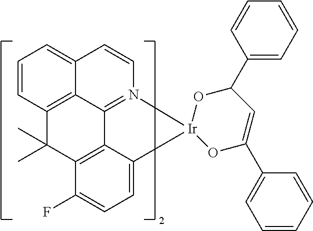 | formula (272) |
| 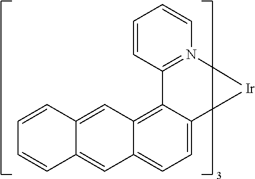 | formula (273) |
| 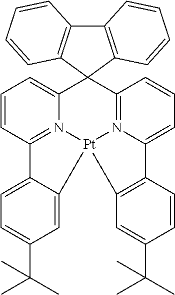 | formula (274) |
| 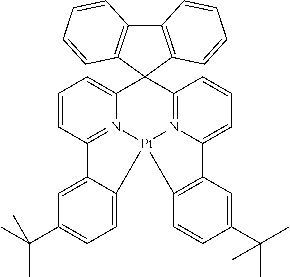 | formula (275) |
| 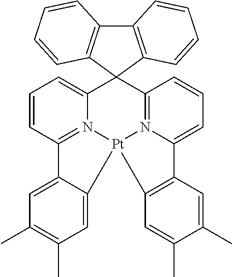 | formula (276) |
| 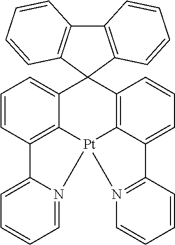 | formula (277) |
| 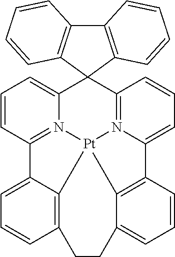 | formula (278) |
| 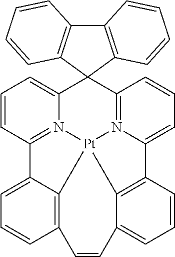 | formula (279) |
| 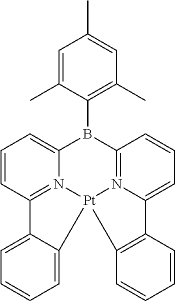 | formula (280) |
| 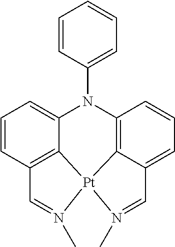 | formula (281) |
| 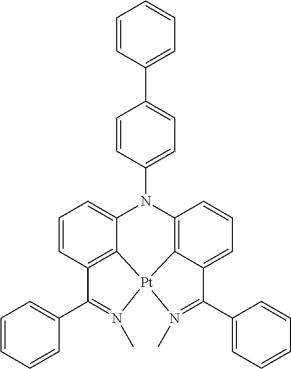 | formula (282) |
| 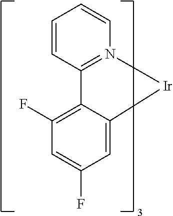 | formula (283) |
| 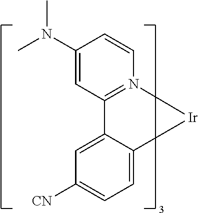 | formula (284) |
| 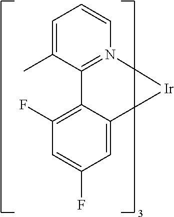 | formula (285) |
| 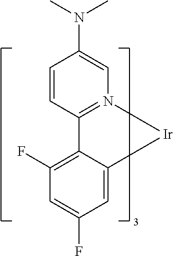 | formula (286) |
| 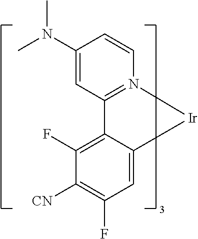 | formula (287) |
| 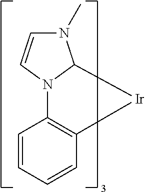 | formula (288) |
| 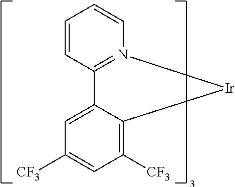 | formula (289) |
| 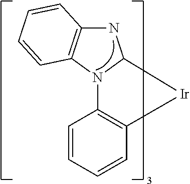 | formula (290) |
| 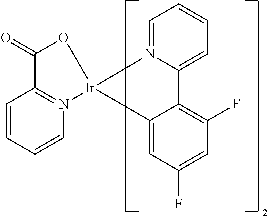 | formula (291) |
| 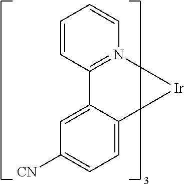 | formula (292) |
| 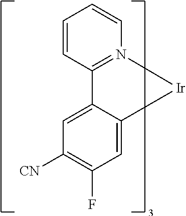 | formula (293) |
| 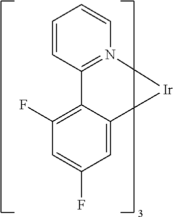 | formula (294) |
| 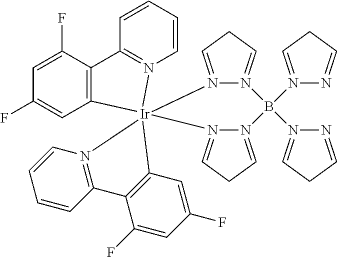 | formula (295) |
| 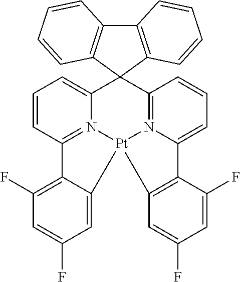 | formula (296) |
| 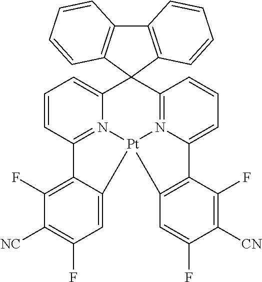 | formula (297) |
| 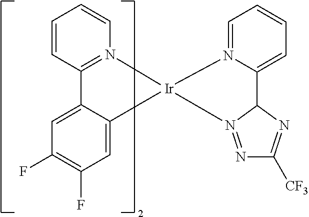 | formula (298) |
| 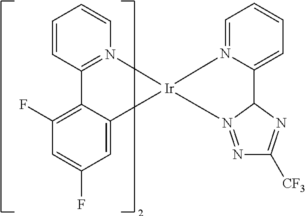 | formula (299) |
| 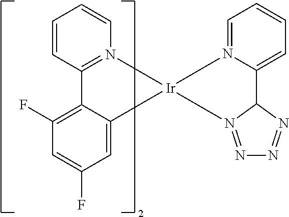 | formula (300) |
| 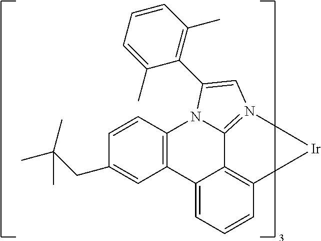 | formula (301) |
| 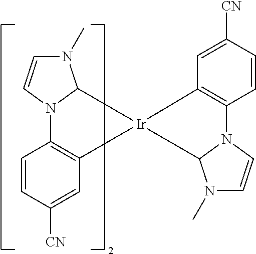 | formula (302) |
| 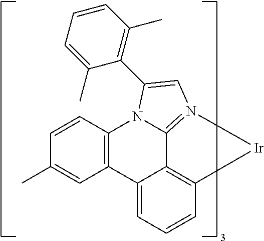 | formula (303) |

In a further particularly preferred embodiment of the invention, the organic electronic device according to the invention is one in which the compound of formula (1) is employed as electron-transport material in an electron-transport layer (ETL) or electron-injection layer (EIL) or hole-blocking layer (HBL) or as exciton-blocking material in an exciton-blocking layer (ExBL). The organic electronic device here may comprise one ETL or EIL or HBL or ExBL, or it may comprise a plurality of ETL or EIL or HBL or ExBL, where at least one layer of ETL or EIL or HBL or ExBL comprises at least one compound of the formula (1).

In a particularly preferred embodiment of the present invention, the compounds of the formula (1) are employed as described above as matrix materials.

In a further preferred embodiment of the invention, the organic electronic device according to the invention comprises at least one compound of the formula (1) in an electron-transport layer or electron-injection layer. The electron-transport layer or electron-injection layer particularly preferably also comprises at least one further electron-transport material. The groups Ar¹ and/or Ar² of the compound of the formula (1) which are preferred for this use are described in detail above.

In a preferred embodiment, the further electron-transport material is an organic alkali-metal compound.

The total proportion of the compound of the formula (1) in the mixture with the further electron-transport material is between 20.0 and 99.0 mol %, preferably between 30.0 and 90.0 mol %, particularly preferably between 30.0 and 70.0 mol %. Correspondingly, the proportion of the further electron-transport material is between 1.0 and 80.0 mol %, preferably between 10.0 and 70.0 mol %, particularly preferably between 30.0 and 70.0 mol %.

An organic alkali-metal compound in the sense of this invention is intended to be taken to mean a compound which contains at least one alkali metal, i.e. lithium, sodium, potassium, rubidium or caesium, and which furthermore contains at least one organic ligand.

Suitable organic alkali-metal compounds are, for example, the compounds disclosed in WO 2007/050301, WO 2007/050334 and EP 1144543.

Preferred organic alkali-metal compounds are the compounds of the following formula (304),

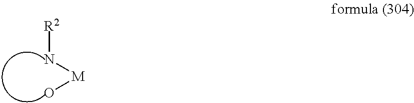

where R² has the same meaning as described above, the curved line represents two or three atoms and bonds which are necessary to make up a 5- or 6-membered ring with M, where these atoms may also be substituted by one or more radicals R² (as described above), and M represents an alkali metal selected from lithium, sodium, potassium, rubidium or caesium.

It is possible here for the complex of the formula (304) to be in monomeric form, as depicted above, or for it to be in the form of aggregates, for example comprising two alkali-metal ions and two ligands, four alkali-metal ions and four ligands, six alkali-metal ions and six ligands or in the form of other aggregates.

Preferred compounds of the formula (304) are the compounds of the following formulae (305) and (306),

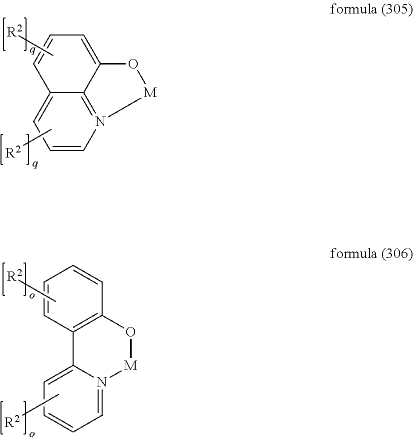

where the symbols used have the meanings given above and furthermore:

q is on each occurrence, identically or differently, 0, 1, 2 or 3;

o is on each occurrence, identically or differently, 0, 1, 2, 3 or 4.

Further preferred organic alkali-metal compounds are the compounds of the following formula (306),

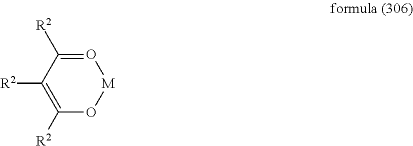

where the symbols used have the same meaning as described above.

The alkali metal is preferably selected from lithium, sodium and potassium, particularly preferably lithium and sodium, very particularly preferably lithium.

Particular preference is given to a compound of the formula (304), in particular where M=lithium. The indices q are furthermore very particularly preferably=0. The compound is very particularly preferably unsubstituted lithium quinolinate.

Examples of suitable organic alkali-metal compounds are the structures having the formulae (307) to (351) shown in the following table.

| | |
|---|---|
| 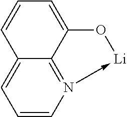 | formula (307) |
| 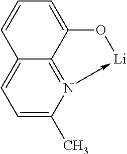 | formula (308) |
| 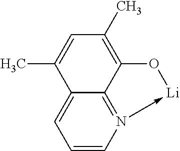 | formula (309) |
| 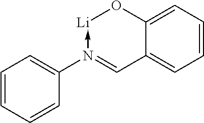 | formula (310) |
| 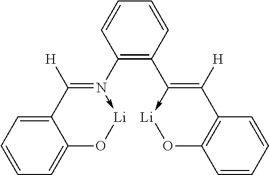 | formula (311) |
| 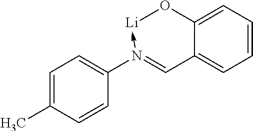 | formula (312) |
| 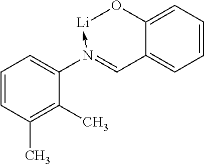 | formula (313) |
| 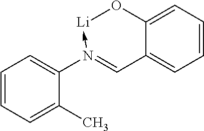 | formula (314) |
| 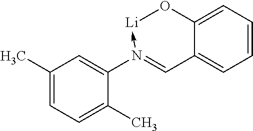 | formula (315) |
| 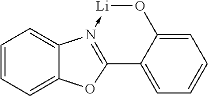 | formula (316) |
| 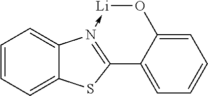 | formula (317) |
| 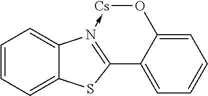 | formula (318) |
| 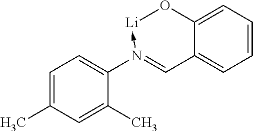 | formula (319) |
| 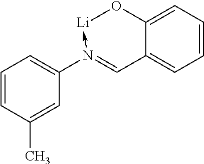 | formula (320) |
| 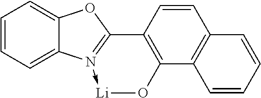 | formula (321) |
| 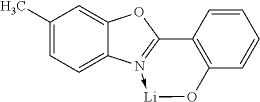 | formula (322) |
| 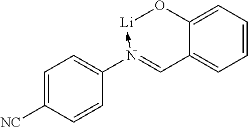 | formula (323) |
| 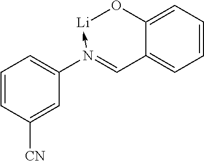 | formula (324) |
| 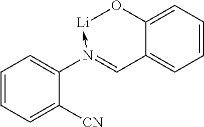 | formula (325) |
| 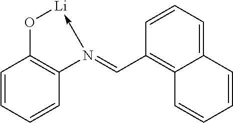 | formula (326) |
| 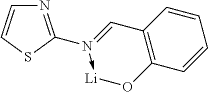 | formula (327) |
| 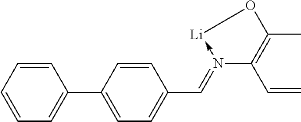 | formula (328) |
| 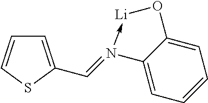 | formula (329) |
| 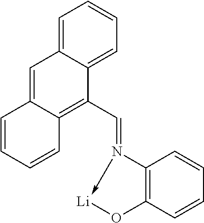 | formula (330) |
| 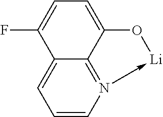 | formula (331) |
| 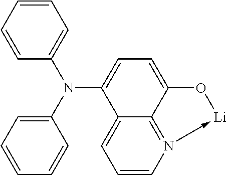 | formula (332) |
| 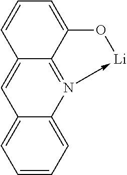 | formula (333) |
| 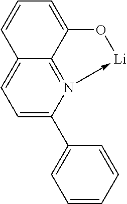 | formula (334) |
| 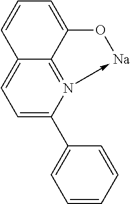 | formula (335) |
| 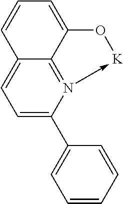 | formula (336) |
| 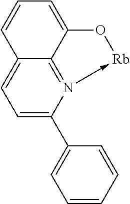 | formula (337) |
| 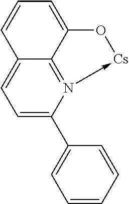 | formula (338) |
| 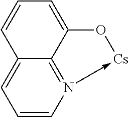 | formula (339) |
| 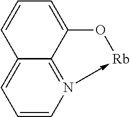 | formula (340) |
| 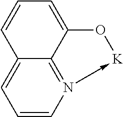 | formula (341) |
| 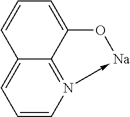 | formula (342) |
| 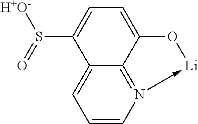 | formula (343) |
| 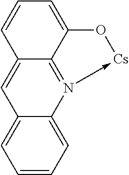 | formula (344) |
| 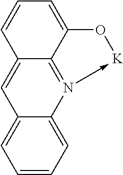 | formula (345) |
| 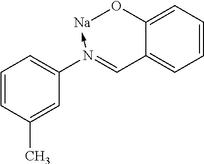 | formula (346) |
| 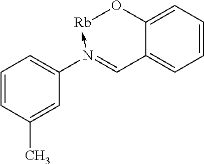 | formula (347) |
| 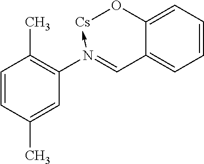 | formula (348) |
| 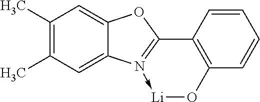 | formula (349) |
| 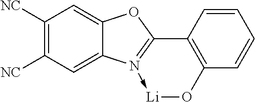 | formula (350) |
| 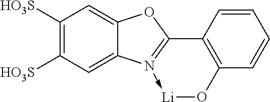 | formula (351) |

A further particularly preferred embodiment of the present invention is an organic electronic device in which the compound of the formula (1) is employed as hole-transport material in a hole-transport layer (HTL) or hole-injection layer (EIL) or electron-blocking layer (EBL). The organic electronic device here may comprise one HTL or HIL or EBL, or it may comprise a plurality of HTL or HIL or EBL, where at least one layer of HTL or HIL or EBL comprises at least one compound of the formula (1).

The compounds of the formula (1) which are suitable for HTL or HIL or EBL are preferably those in which at least one representative of the Ar¹ repre-sents a heteroaromatic ring system.

In a particularly preferred embodiment of the present invention, a compound of the formula (1) is employed in HTL or HIL or EBL, and is characterised in that at least one representative of the Ar₁ of the compound of the formula (1) is a divalent group of one of the formulae (100) to (110).

In a further particularly preferred embodiment of the present invention, a compound of the formula (1) is employed in HTL or HIL or EBL, and is characterised in that the compound of the formula (1) is a compound of the formula (9), where X and Y are equal to CR¹ or n and m is an integer from 1 to 6, with the proviso that at least one representative of the X or Y is equal to N.

Besides the at least one layer, the organic electronic device according to the invention may also comprise further layers. These are selected, for example, from in each case one or more hole-injection layers, hole-transport layers, hole-blocking layers, electron-transport layers, electron-injection layers, electron-blocking layers, exciton-blocking layers, charge-generation layers (IDMC 2003, Taiwan; Session 21 OLED (5), T. Matsumoto, T. Nakada, J. Endo, K. Mori, N. Kawamura, A. Yokoi, J. Kido, Multi-photon Organic EL Device Having Charge Generation Layer) and/or organic or inorganic p/n junctions. In addition, interlayers may be present which control the charge balance in the device. Furthermore, the layers, in particular the charge-transport layers, may also be doped. The doping of the layers may be advantageous for improved charge transport. However, it should be pointed out that each of these layers does not necessarily have to be present and the choice of layers is always dependent on the compounds used.

In a further preferred embodiment of the invention, the organic electronic device comprises a plurality of emitting layers, where at least one emitting layer comprises at least one compound of the formula (1) and at least one phosphorescent emitter compound. These emission layers particularly preferably have in total a plurality of emission maxima between 380 nm and 750 nm, resulting overall in white emission, i.e. various emitting compounds which are able to fluoresce or phosphoresce and which emit blue and yellow, orange or red light are used in the emitting layers. Particular preference is given to three-layer systems, i.e. systems having three emitting layers, where at least one of these layers comprises at least one compound of the formula (1) and at least one phosphorescent emitter compound and where the three layers exhibit blue, green and orange or red emission (for the basic structure see, for example, WO 2005/011013). The use of more than three emitting layers may also be preferred. Emitters which have broad-band emission bands and thus exhibit white emission are likewise suitable for white emission.

In a further embodiment of the present invention, it is preferred for the at least one layer to comprise one or more further compounds selected from the following: hole-injection compounds, hole-transport compounds, hole-blocking compounds, electron-transport compounds, electron-injection compounds, electron-blocking compounds, exciton-blocking compounds. In particular, the at least one layer comprises a hole-transport compound, preferably selected from triarylamines, carbazole derivatives, azacarba-zoles and bipolar matrix materials.

The present invention also relates to a composition comprising at least one compound of the formula (1) as defined above, and a least one phosphorescent emitter compounds, as defined above.

The composition according to the invention comprising the compound of the formula (1) and the phosphorescent emitter compound comprises between 99 and 50% by vol., preferably between 98 and 50% by vol., particularly preferably between 97 and 60% by vol., especially between 95 and 85% by vol., of the compound of the formula (1), based on the entire mixture comprising emitter compound and matrix material. Correspondingly, the mixture comprises between 1 and 15% by vol., preferably between 2 and 50% by vol., particularly preferably between 3 and 40% by vol., in particular between 5 and 15% by vol., of the phosphorescent emitter compound, based on the entire mixture comprising emitter and matrix material.

Preference is furthermore also given to the use of a plurality of matrix materials in the composition according to the invention, where one matrix material is selected from compounds of the formula (1). The compounds of the formula (1) have predominantly electron-transporting properties through the electron-deficient nitrogen heterocycles Ar¹ or Ar². If a mixture of two or more matrix materials is used, a further component of the mixture is therefore preferably a hole-transporting compound. Preferred hole-conducting matrix materials are triarylamines, carbazole derivatives, for example CBP (N,N-biscarbazolylbiphenyl) or the carbazole derivatives disclosed in WO 2005/039246, US 2005/0069729, JP 2004/288381, EP 1205527 or WO 08/086,851, for example in accordance with EP 1617710, EP 1617711, EP 1731584, JP 2005/347160, bipolar matrix materials, for example in accordance with WO 2007/137725, and 9,9-diarylfluorene derivatives, for example in accordance with the application DE 102008017591.9.

The composition comprising a plurality of matrix materials may also comprise more than two matrix materials. It is furthermore also possible to use the matrix material of the formula (1) as mixture with a further electron-transporting matrix material. Preferred further electron-transporting matrix materials are ketones, for example in accordance with WO 2004/093207, phosphine oxides, sulfoxides and sulfones, for example in accordance with WO 2005/003253, oligophenylenes, bipolar matrix materials, for example in accordance with WO 07/137,725, silanes, for example in accordance with WO 05/111172, 9,9-diarylfluorene derivatives (for example in accordance with the unpublished application DE 102008017591.9), azaboroles or boronic esters (for example in accordance with WO 06/117052).

Preference is furthermore given to an organic electronic device, characterised in that one or more layers are coated by means of a sublimation process, in which the materials are applied by vapour deposition in vacuum sublimation units at a pressure less than 10⁻⁵ mbar, preferably less than 10⁻⁶ mbar. However, it should be noted that the pressure may also be even lower, for example less than 10⁻⁷ mbar.

Preference is likewise given to an organic electronic device, characterised in that one or more layers are coated by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

Preference is furthermore given to an organic electronic device, characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose. High solubility can be achieved through suitable substitution of the compounds. Not only solutions comprising individual materials can be applied here, but also solutions which comprise a plurality of compounds, for example matrix materials and dopants.

The organic electronic device can also be produced as hybrid system by applying one or more layers from solution and applying one or more other layers by vapour deposition. Thus, for example, it is possible to apply an emitting layer comprising a compound of the formula (1) and the phosphorescent dopant from solution and to apply a hole-blocking layer and/or an electron-transport layer on top by vacuum vapour deposition. Likewise, the emitting layer comprising a compound of the formula (1) and a phosphorescent dopant can be applied by vacuum vapour deposition and one or more other layers can be applied from solution.

These processes are generally known to the person skilled in the art and can be applied by him without problems to organic electronic devices comprising compounds of the formula (1) or the preferred embodiments indicated above.

The present invention still furthermore relates to the use of compounds of the formula (1) as matrix material for phosphorescent emitter compounds in an organic electronic device, in particular an organic electroluminescent device.

The organic electronic device according to the invention preferably comprises a cathode and an anode, which are preferably installed on two oppo-site sides of the at least one layer of the device. The electrodes (cathode, anode) are for the purposes of this invention selected in such a way that their potential corresponds as well as possible to the potential of the adjacent organic layer in order to ensure the most efficient electron or hole injection possible.

The cathode preferably comprises metal complexes, metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides (for example LiF, Li₂O, BaF₂, MgO, NaF, etc.). The layer thickness of this layer is preferably between 1 and 10 nm, more preferably 2 to 8 nm.

The anode preferably comprises materials having a high work function. The anode preferably has a potential of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, AI/PtOₓ) may also be preferred. For some applications, at least one of the electrodes must be transparent in order to enable either irradiation of the organic material (O-SCs) or the coupling-out of light (OLEDs/PLEDs, O-lasers). A preferred structure uses a transparent anode. Preferred anode materials here are conductive mixed metal oxides. Particular preference is given to indium tin oxide (ITO) or indium zinc oxide (IZO). Preference is furthermore given to conductive doped organic materials, in particular conductive doped polymers.

The device is correspondingly structured in a manner known per se, depending on the application, provided with contacts and finally hermetically sealed, since the lifetime of devices of this type is drastically shortened in the presence of water and/or air.

The organic electronic devices according to the invention have the following surprising advantages over the prior art:
1. The organic electronic devices according to the invention have very high efficiency.
2. The organic electronic devices according to the invention at the same time have a reduced operating voltage.

The present invention also relates to an organic compound of the formula (1), in which the groups Ar¹ and Ar² are defined as in the above formula (9), with the proviso that at least one representative of the Y is equal to N and at least one representative of the X is equal to CR¹, where Y, X and R¹ otherwise have the same meanings as defined above. All above-mentioned preferred definitions also apply to this organic compound according to the invention.

In addition, the present invention also relates to an organic compound of the formula (1), with the proviso that at least one representative of the Ar₁ is a divalent group of the formula (100) or (101) as defined above. All above-mentioned preferred definitions also apply to this organic compound according to the invention.

The compounds according to the invention are suitable for use in an electronic device. An electronic device here is taken to mean a device which comprises at least one layer which comprises at least one organic compound. However, the component may also comprise inorganic materials or also layers built up entirely from inorganic materials.

The present invention therefore furthermore relates to the use of the above-mentioned compounds according to the invention in an organically electronic device, in particular in an organic electroluminescent device.

The present invention still furthermore relates to an electronic device comprising at least one of the above-mentioned compounds according to the invention. The above-mentioned preferences here likewise apply to the electronic devices.

The electronic device is preferably selected from the group consisting of organic electroluminescent devices (organic light-emitting diodes, OLEDs), organic integrated circuits (O-ICs), organic field-effect transistors (O-FETs), organic thin-film transistors (O-TFTs), organic light-emitting transistors (O-LETs), organic light-emitting electrochemical transistors, organic solar cells (O-SCs), dye-sensitised organic solar cells (ODSSCs), organic optical detectors, organic photoreceptors, organic field-quench devices (O-FQDs), organic light-emitting electrochemical cells (OLECs), organic laser diodes (O-lasers) and “organic plasmon emitting devices”” (D. M. Koller et al., Nature Photonics 2008, 1-4), but preferably organic electroluminescent devices (OLEDs), particularly preferably phosphorescent OLEDs, OLEC, O-LET and organic light-emitting electrochemical transistor.

The compounds described herein are suitable, as described above, for use in O-FETs, which is shown in detail below. Typically, conjugated polymers or oligomers, such as, for example, thiophene-containing polymer P3HT, or macromolecules, for example phtalocyanines and derivatives thereof, are employed in O-FETs. Thiophene polymers still exhibit problems in the case of processing from solutions and during purification. The phthalocyanine-based materials can only be applied by evaporation. The use of the small molecule compounds disclosed herein is advantageous compared with these, since they can be processed more easily from solution. Furthermore, their synthesis is comparatively simple and they can be obtained in higher purity, which has a positive influence on the performance of the electronic devices.

The organic electronic device according to the invention is furthermore preferably characterised in that one or more layers are coated by means of a sublimation process, in which the materials are applied by vapour deposition in vacuum sublimation units at an initial pressure of usually less than 10⁻⁵ mbar, preferably less than 10⁻⁶ mbar. However, it is also possible for the initial pressure to be even lower, for example less than 10⁻⁷ mbar.

The organic electronic device according to the invention is preferably characterised in that one or more layers are coated by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

Preference is furthermore given to an organic electronic device, characterised in that one or more layers are produced from solution, such as, for example, by spin coating, or by means of any desired printing process, such as, for example, LITI (light induced thermal imaging, thermal transfer printing), ink-jet printing, screen printing, flexographic printing, offset printing or nozzle printing. Soluble compounds, which can be obtained, for example, by suitable substitution, are necessary for this purpose. These processes are also suitable for oligomers, dendrimers and polymers. These processes are also suitable, in particular, for the compounds according to the invention, since these generally have very good solubility in organic solvents.

Furthermore, hybrid processes are possible in which, for example, one or layers are applied from solution and one or more further layers are applied by vapour deposition. Thus, for example, one layer in an organic electronic device can be applied to solution and the other layer can be applied by vapour deposition.

These processes are generally known to the person skilled in the art and can be applied by him without inventive step to the organic electronic devices described above comprising the compounds according to the invention.

For the processing of the compounds according to the invention from liquid phase, for example by spin coating or by printing processes, formulations of the compounds according to the invention or of the compounds of the formula (1) are necessary. These formulations can be, for example, solutions, dispersions or mini-emulsions. It may be preferred to use mixtures of two or more solvents for this purpose. Suitable and preferred solvents are, for example, toluene, anisole, o-, m- or p-xylene, methyl benzoate, dimethyl-anisole, mesitylene, tetralin, veratrol, THF, methyl-THF, THP, chlorobenzene, dioxane or mixtures of these solvents.

The present invention therefore furthermore relates to a formulation, in particular a solution, dispersion or mini-emulsion, comprising at least one compound according to the invention or a compound of the formula (1) and at least one solvent, in particular an organic solvent. The way in which solutions of this type can be prepared is known to the person skilled in the art and is described, for example, in WO 02/072714, WO 2003/019694 and the literature cited therein.

The present invention furthermore relates to mixtures comprising at least one compound according to the invention and at least one further compound. The further compound can be, for example, a fluorescent or phosphorescent dopant if the compound according to the invention is used as matrix material. Suitable phosphorescent dopants are indicated above in connection with the organic electronic devices according to the invention and are also preferred for the mixtures according to the invention.

Preferred organic compounds of the formula (1) according to the invention or compounds of the formula (1) employed in the organic electronic device according to the invention are the following:

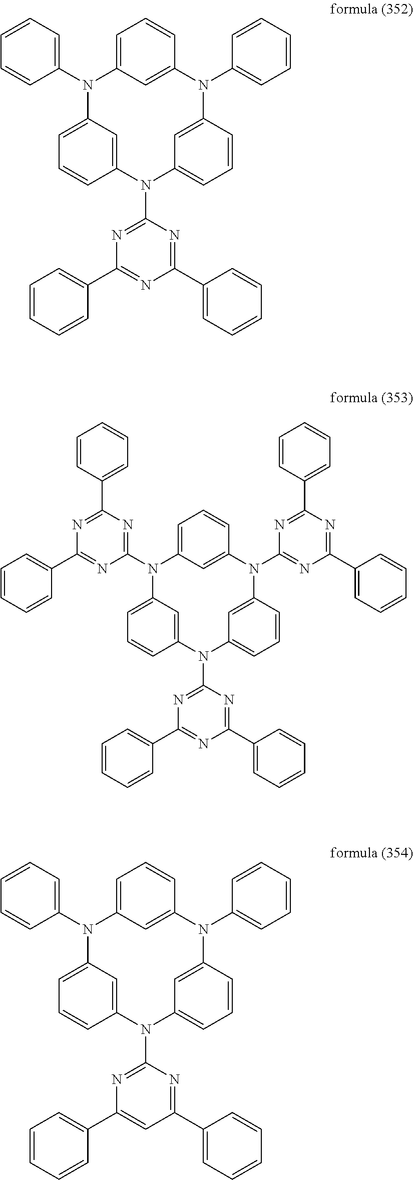 [SMILES: c1ccc(-c2nc(-c3ccccc3)nc(N3c4cccc(c4)N(c4ccccc4)c4cccc(c4)N(c4ccccc4)c4cccc3c4)n2)cc1 ; c1ccc(-c2nc(-c3ccccc3)nc(N3c4cccc(c4)N(c4nc(-c5ccccc5)nc(-c5ccccc5)n4)c4cccc(c4)N(c4nc(-c5ccccc5)nc(-c5ccccc5)n4)c4cccc3c4)n2)cc1 ; c1ccc(-c2cc(-c3ccccc3)nc(N3c4cccc(c4)N(c4ccccc4)c4cccc(c4)N(c4ccccc4)c4cccc3c4)n2)cc1]

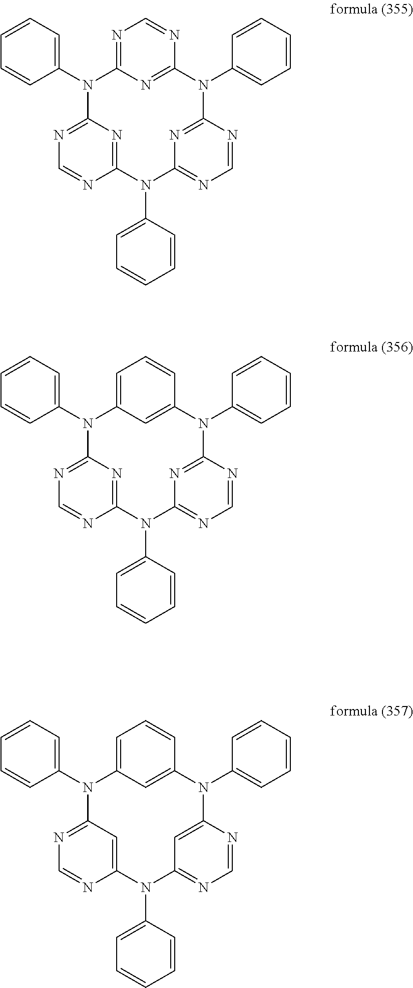 [SMILES: c1ccc(N2c3ncnc(n3)N(c3ccccc3)c3ncnc(n3)N(c3ccccc3)c3ncnc2n3)cc1 ; c1ccc(N2c3cccc(c3)N(c3ccccc3)c3ncnc(n3)N(c3ccccc3)c3ncnc2n3)cc1 ; c1ccc(N2c3cccc(c3)N(c3ccccc3)c3cc(ncn3)N(c3ccccc3)c3cc2ncn3)cc1]

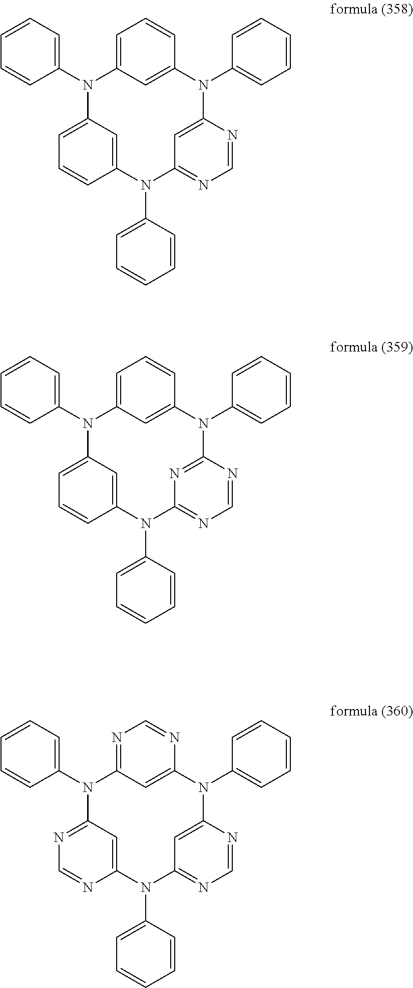 [SMILES: c1ccc(N2c3cccc(c3)N(c3ccccc3)c3cc(ncn3)N(c3ccccc3)c3cccc2c3)cc1 ; c1ccc(N2c3cccc(c3)N(c3ccccc3)c3ncnc(n3)N(c3ccccc3)c3cccc2c3)cc1 ; c1ccc(N2c3cc(ncn3)N(c3ccccc3)c3cc(ncn3)N(c3ccccc3)c3cc2ncn3)cc1]

The devices according to the invention comprising the compounds indicated above can be employed in electroluminescent devices. They are therefore also suitable for use in the areas of therapeutic and cosmetic phototherapy.

The present invention therefore furthermore relates to the use of the devices comprising the compounds of the formula (1) or (9) for the treatment, prophylaxis and diagnosis of diseases. The present invention still furthermore relates to the use, of the compounds according to the invention and devices comprising the compounds for the treatment and prophylaxis of cosmetic conditions.

The present invention furthermore relates to substances of the formula (1) or (9) for use for the treatment, prophylaxis and diagnosis of diseases.

The present invention furthermore relates to the devices according to the invention for the therapy, prophylaxis and/or diagnosis of therapeutic diseases.

The present invention still furthermore relates to substances of the formula (1) or (9) for use for application in cosmetics.

Phototherapy or light therapy is used in many medical and/or cosmetic areas. The devices according to the invention and compounds of the formula (1) or (9) can therefore be employed for the therapy and/or prophylaxis and/or diagnosis of all diseases and/or in cosmetic applications for which the person skilled in the art considers the use of phototherapy. Besides irradiation, the term phototherapy also includes photodynamic therapy (PDT) and disinfection and sterilisation in general. Phototherapy or light therapy can be used for the treatment of not only humans or animals, but also any other type of living or non-living materials. These include, for example, fungi, bacteria, microbes, viruses, eukaryotes, prokaryotes, foods, drinks, water and drinking water.

The term phototherapy also includes any type of combination of light therapy and other types of therapy, such as, for example, treatment with active compounds. Many light therapies have the aim of irradiating or treating exterior parts of an object, such as the skin of humans and animals, wounds, mucous membranes, the eye, hair, nails, the nail bed, gums and the tongue. However, the treatment or irradiation according to the invention can also be carried out inside an object in order, for example, to treat inter-nal organs (heart, lung, etc.) or blood vessels or the breast.

The therapeutic and/or cosmetic areas of application according to the invention are preferably selected from the group of skin diseases and skin-associated diseases or changes or conditions, such as, for example, psoriasis, skin ageing, skin wrinkling, skin rejuvenation, enlarged skin pores, cellulite, oily/greasy skin, folliculitis, actinic keratosis, precancerous actinic keratosis, skin lesions, sun-damaged and sun-stressed skin, crows' feet, skin ulcers, acne, acne rosacea, scars caused by acne, acne bacteria, photomodulation of greasy/oily sebaceous glands and their surrounding tissue, jaundice, jaundice of the newborn, vitiligo, skin cancer, skin tumours, Crigler-Najjar, dermatitis, atopic dermatitis, diabetic skin ulcers and desensitisation of the skin.

Particular preference is given for the purposes of the invention to the treatment and/or prophylaxis of psoriasis, acne, cellulite, skin wrinkling, skin ageing, jaundice and vitiligo.

Further areas of application according to the invention for the compositions and/or devices comprising the compositions according to the invention are selected from the group of inflammatory diseases, rheumatoid arthritis, pain therapy, treatment of wounds, neurological diseases and conditions, oedema, Paget's disease, primary and metastasising tumours, connective-tissue diseases or changes, changes in the collagen, fibroblasts and cell level originating from fibroblasts in tissues of mammals, irradiation of the retina, neovascular and hypertrophic diseases, allergic reactions, irradiation of the respiratory tract, sweating, ocular neovascular diseases, viral infections, particularly infections caused by herpes simplex or HPV (human papillomaviruses) for the treatment of warts and genital warts.

Particular preference is given for the purposes of the invention to the treatment and/or prophylaxis of rheumatoid arthritis, viral infections and pain.

Further areas of application according to the invention for the compounds and/or devices comprising the compounds are selected from winter depres-sion, sleeping sickness, irradiation for improving the mood, the reduction in pain particularly muscular pain caused by, for example, tension or joint pain, elimination of joint stiffness and the whitening of the teeth (bleaching).

Further areas of application according to the invention for the compounds and/or devices comprising the compounds are selected from the group of disinfections. The compounds and/or the devices according to the invention can be used for the treatment of any type of objects (non-living materials) or subjects (living materials such as, for example, humans and animals) for the purposes of disinfection. This includes, for example, the disinfection of wounds, the reduction in bacteria, the disinfection of surgical instruments or other articles, the disinfection of foods, of liquids, in particular water, drinking water and other drinks, the disinfection of mucous membranes and gums and teeth. Disinfection here is taken to mean the reduction in the living microbiological causative agents of undesired effects, such as bacteria and germs.

For the purposes of the above-mentioned phototherapy, the devices according to the invention preferably emit light having a wavelength between 250 and 1250 nm, particularly preferably between 300 and 1000 nm and especially preferably between 400 and 850 nm.

In a particularly preferred embodiment of the present invention, the compounds of the formulae (1) or (9) are employed in an organic light-emitting diode (OLED) or an organic light-emitting electrochemical cell (OLEC) for the purposes of phototherapy. Both the OLED and the OLEC can have a planar or fibre-like structure having any desired cross section (for example round, oval, polygonal, square) with a single- or multilayered structure. These OLECs and/or OLEDs can be installed in other devices which comprise further mechanical, adhesive and/or electronic elements (for example battery and/or control unit for adjustment of the irradiation times, intensities and wavelengths). These devices comprising the OLECs and/or OLEDs according to the invention are preferably selected from the group comprising plasters, pads, tapes, bandages, cuffs, blankets, caps, sleeping bags, textiles and stents.

The use of the said devices for the said therapeutic and/or cosmetic purpose is particularly advantageous compared with the prior art, since homo-geneous irradiation of lower irradiation intensity is possible at virtually any site and at any time of day with the aid of the devices according to the invention using the OLEDs and/or OLECs. The irradiation can be carried out as an inpatient, as an outpatient and/or by the patient themselves, i.e. without initiation by medical or cosmetic specialists. Thus, for example, plasters can be worn under clothing, so that irradiation is also possible during working hours, in leisure time or during sleep. Complex inpatient/outpatient treatments can in many cases be avoided or their frequency reduced. The devices according to the invention may be intended for re-use or be disposable articles, which can be disposed of after use once, twice or three times.

Further advantages over the prior art are, for example, lower evolution of heat and emotional aspects. Thus, newborn being treated owing to jaundice typically have to be irradiated blindfolded in an incubator without physical contact with the parents, which represents an emotional stress situation for parents and newborn. With the aid of a blanket according to the invention comprising the OLEDs and/or OLECs according to the invention, the emotional stress can be reduced significantly. In addition, better temperature control of the child is possible due to reduced heat production of the devices according to the invention compared with conventional irradiation equipment.

It should be pointed out that variations of the embodiments described in the present invention fall within the scope of this invention. Each feature disclosed in the present invention can, unless explicitly excluded, be replaced by alternative features which serve the same, an equivalent or a similar purpose. Thus, each feature disclosed in the present invention should, unless stated otherwise, be regarded as an example of a generic series or as an equivalent or similar feature.

All features of the present invention can be combined with one another in any way, unless certain features and/or steps are mutually exclusive. This applies, in particular, to preferred features of the present invention. Equally, features of non-essential combinations can be used separately (and not in combination).

It should furthermore be pointed out that many of the features, and in particular those of the preferred embodiments of the present invention, should be regarded as inventive themselves and not merely as part of the embodiments of the present invention. Independent protection may be granted for these features in addition or as an alternative to each invention claimed at present.

The teaching regarding technical action disclosed with the present invention can be abstracted and combined with other examples.

The invention is explained in greater detail by the following examples without wishing it to be restricted thereby.

### EXAMPLES

### Examples 1

### Quantum-Chemical Calculations for M1-M8, V1 and TEG1

Firstly, the following organic compounds are investigated by quantum chemistry simulation, where compounds M3 to M8 are the compounds according to the invention, M1 and M2 can be used in the organic electroluminescent devices according to the invention, V1 is a comparative matrix material, and TEG1 is a green triplet emitter.

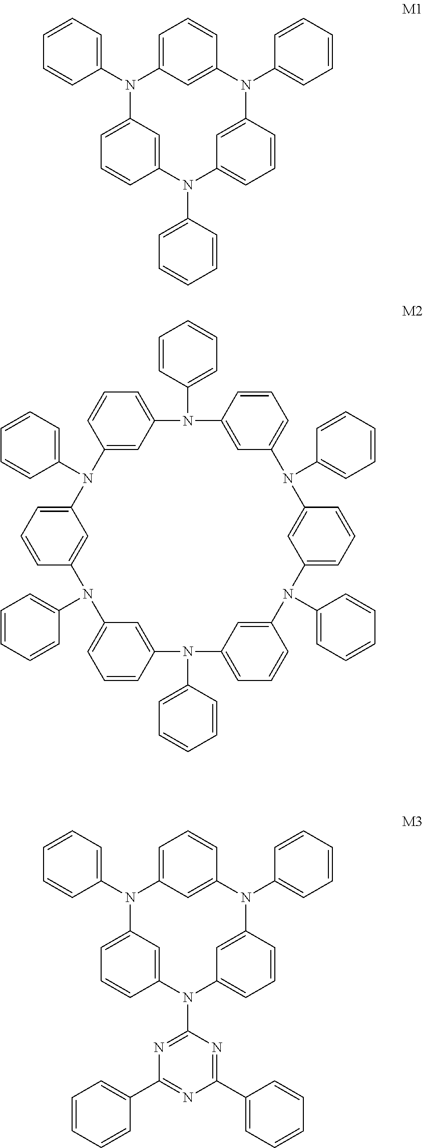

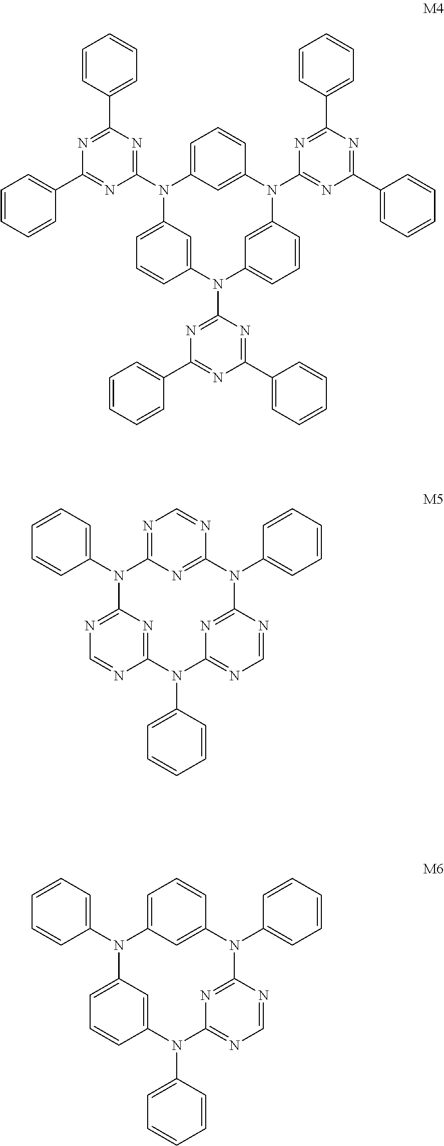 [SMILES: c1ccc(-c2nc(-c3ccccc3)nc(N3c4cccc(c4)N(c4nc(-c5ccccc5)nc(-c5ccccc5)n4)c4cccc(c4)N(c4nc(-c5ccccc5)nc(-c5ccccc5)n4)c4cccc3c4)n2)cc1 ; c1ccc(N2c3ncnc(n3)N(c3ccccc3)c3ncnc(n3)N(c3ccccc3)c3ncnc2n3)cc1 ; c1ccc(N2c3cccc(c3)N(c3ccccc3)c3ncnc(n3)N(c3ccccc3)c3cccc2c3)cc1]

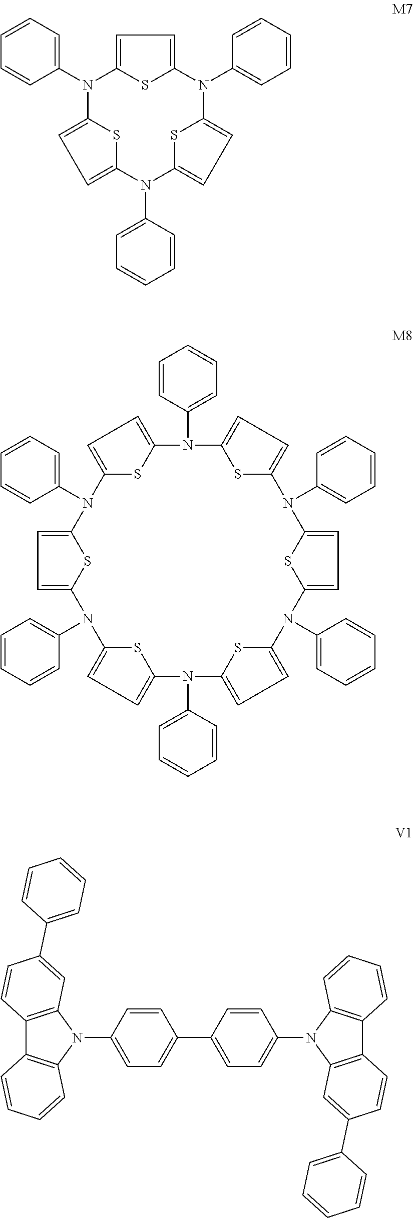 [SMILES: c1ccc(-n2c3ccc(s3)n(-c3ccccc3)c3ccc(s3)n(-c3ccccc3)c3ccc2s3)cc1 ; c1ccc(N2c3ccc(s3)N(c3ccccc3)c3ccc(s3)N(c3ccccc3)c3ccc(s3)N(c3ccccc3)c3ccc(s3)N(c3ccccc3)c3ccc(s3)N(c3ccccc3)c3ccc2s3)cc1 ; c1ccc(-c2ccc3c4ccccc4n(-c4ccc(-c5ccc(-n6c7ccccc7c7ccc(-c8ccccc8)cc76)cc5)cc4)c3c2)cc1]

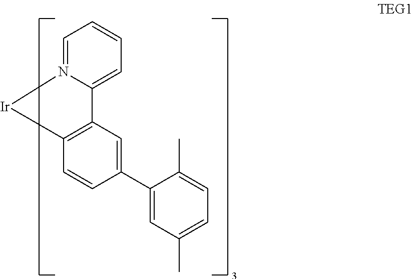

HOMO and LUMO positions and the triplet/singlet level of organic compounds can be determined by means of quantum-chemical calculations. To this end, use is made of the “Gaussian03W” (Gaussian Inc.) software. In order to calculate organic substances without metals, firstly a geometry optimisation is carried out using a semi-empirical “Ground State/Semi-empirical/Default Spin/AM1” method (Charge 0/Spin Singlet). An energy calculation is subsequently carried out on the basis of the optimised geometry. The “TD-SCF/DFT/Default Spin/B3PW91” method (TD-SCF/DFT-time dependent-self consisting field/density functional theory) with the “6-31G(d)” base set is used here (Charge 0/Spin Singlet). For organometallic compounds, the geometry is optimised via the “Ground State/Hartree-Fock/Default Spin/LanL2 MB” method (Charge 0/Spin Singlet). The energy calculation is carried out analogously to the organic substances as described above, with the difference that the “LanL2DZ” (pseudo=LanL2) base set is used for the metal atom and the “6-31G(d)” base set is used for the ligands. The most important results from such calculations are the HOMO/LUMO levels and the energies of excited triplet and singlet states. The first excited states (singlet and triplet) are the most important here. They are referred to as T1 (first excited triplet state) and S1 (first excited singlet state). The energy calculation gives the HOMO HEh and LUMO LEh in hartree units. The HOMO and LUMO values in electron volts are determined therefrom as follows, where these relationships arise from the cali-bration with reference to cyclic voltammetry measurements:

HOMO(eV)=((HEh*27.212)−0.9899)/1.1206

LUMO(eV)=((LEh*27.212)−2.0041)/1.385

For the purposes of this application, these values are to be regarded as the energetic position of the HOMO level or LUMO level respectively of the materials. As an example, an HOMO of −0.17968 hartrees and an LUMO of −0.02961 hartrees are obtained from the calculation for compound M1 (see also Table 1), which corresponds to a calibrated HOMO of −5.25 eV, a calibrated LUMO of −2.03 eV.

The calculated energy levels are summarised in Table 1. The T1 levels of M1 to M6 and M8 are higher than those of TEG1, which indicates that all these materials are suitable matrix materials for TEG1.

TABLE 1
Summary of the energy levels of M1 to M8, V1 and TEG1

| | TD-DFT | | | |
|---|---|---|---|---|
| | Homo corr. [eV] | Lumo corr. [eV] | T1 [eV] | S1 [eV] |
| M1 | −5.25 | −2.03 | 2.80 | 3.17 |
| M2 | −5.69 | −2.16 | 3.22 | 3.75 |
| M3 | −5.36 | −2.68 | 2.74 | 2.92 |
| M4 | −5.90 | −2.75 | 2.80 | 3.04 |
| M5 | −6.55 | −2.88 | 3.02 | 3.41 |
| M6 | −5.36 | −2.18 | 2.94 | 3.45 |
| M7 | −5.35 | −2.62 | 2.06 | 2.63 |
| M8 | −5.79 | −2.28 | 2.96 | 3.08 |
| V1 | −5.69 | −2.39 | 2.85 | 3.28 |
| TEG1 | −5.33 | −2.41 | 2.68 | 2.91 |

As can also be seen from Table 1, compounds M6 and M7 have a very high HOMO and are consequently very highly suitable as HTM. These compounds can be employed as HTM in HTL in OLED or in organic solar cells or in a p-transport channel in organic field effect transistor.

### Examples 2

### Synthesis of M1

Compound M1 is synthesised in accordance with the following scheme.

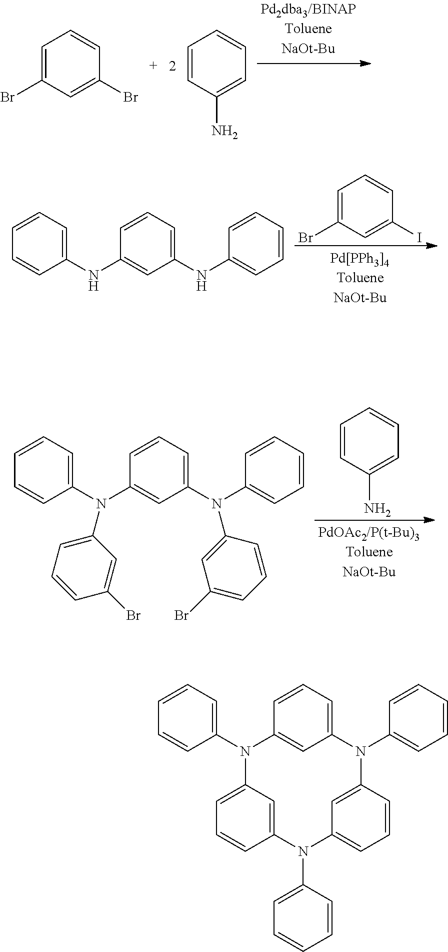

### a) Synthesis of N,N-diphenyl-1,3-diaminobenzene

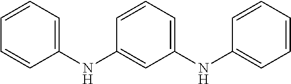 [SMILES: c1ccc(Nc2cccc(Nc3ccccc3)c2)cc1]

23.1 g (100 mmol) of 1.3 dibromobenzene [108-36-1], 23.3 g (250 mmol) of aniline [62-53-3] and 28.8 g (300 mmol) of Na tert-butoxide [865-45-5] are dissolved in 300 ml toluene. The reaction solution is carefully degassed, warmed to 80° C., and 183.2 mg (0.2 mmol) of Pd₂(dba)₃ and 373.6 mg (0.6 mmol) of rac-BINAP as catalyst are added. The progress of the reaction is monitored by means of TLC. The solution is cooled to room temperature 150 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from ethanol, giving 19.3 g (74 mmol) (74%) of a white solid in a of purity 99.2%.

### b) Synthesis of N,N-diphenyl-N,N-bis-3-bromophenyldiaminobenzene

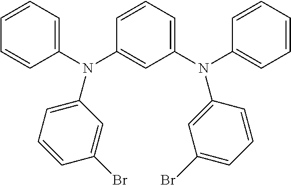 [SMILES: Brc1cccc(N(c2ccccc2)c2cccc(N(c3ccccc3)c3cccc(Br)c3)c2)c1]

18 g (69 mmol) of 1.3 diphenyldiaminobenzene, 14 g (139.4 mmol) of bromoiodobenzene [591-81-4] and 20.2 g (210 mmol) of Na tert-butoxide [865-45-5] are dissolved in 100 ml of toluene. The reaction solution is carefully degassed, warmed to 80° C., and 31 mg (0.14 mmol) of Pd(OAc)₂ and 127.8 mg of P(t-Bu)₃ as (0.42 mmol) catalyst are added. The progress of the reaction is monitored by means of TLC. The solution is cooled to room temperature 50 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from ethanol, giving 26.8 g (47 mmol) (68%) of a white solid in a of purity 99.3%.

### c) Synthesis of cyclophane M1

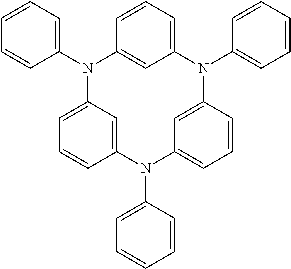 [SMILES: c1ccc(N2c3cccc(c3)N(c3ccccc3)c3cccc(c3)N(c3ccccc3)c3cccc2c3)cc1]

25 g (44 mmol) of dibromide, 4.08 g (44 mmol) of aniline [62-53-3] and 12.7 g (132 mmol) of Na tert-butoxide [865-45-5] are dissolved in 500 ml of toluene. The reaction solution is carefully degassed, warmed to 80° C., and 16 mg (0.07 mmol) of Pd(OAc)₂ and 64 mg P(t-Bu)₃ as (0.21 mmol) as catalyst are added. The progress of the reaction is monitored by means of TLC. The solution is cooled to room temperature 100 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised a number of times from buthanol, giving 9.3 g (18.5 mmol) (42%) of a white solid in a of purity 99.9%.

### Examples 3

### Synthesis of M3

Compound M3 is synthesised in accordance with the following scheme.

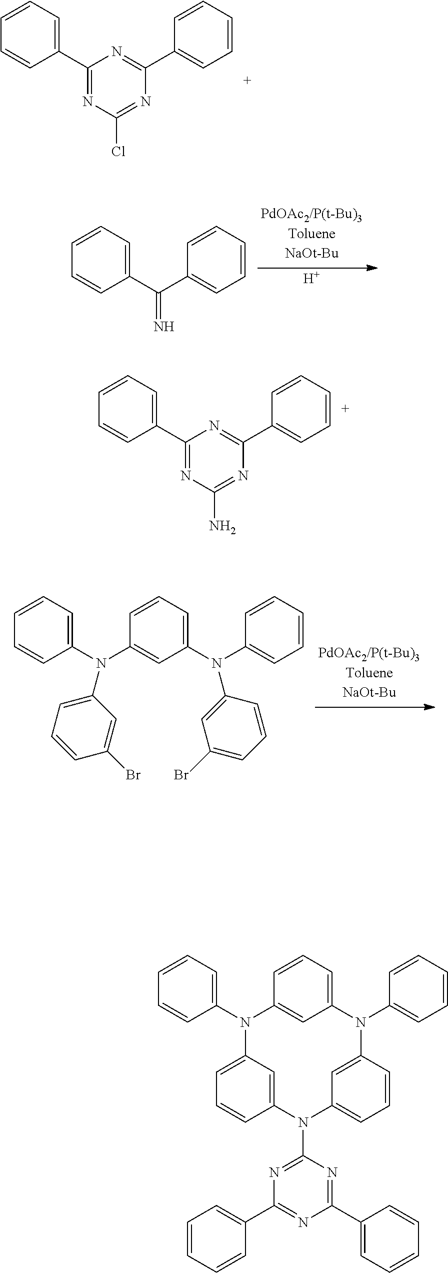

### a) Synthesis of 2-amino-4,6-diphenyl-1,3,5 triazine

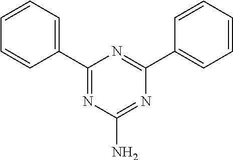 [SMILES: Nc1nc(-c2ccccc2)nc(-c2ccccc2)n1]

25 g (93.4 mmol) of diphenylchlorotriazine [3842-55-5], 18.1 g (100 mmol) of benzophenone imide [1013-88-3] and 14.4 g (150 mmol) of Na tert-butoxide [865-45-5] are dissolved in 200 ml of toluene. The reaction solution is carefully degassed, warmed to 80° C., and 16 mg (0.07 mmol) of Pd(OAc)₂ and 64 mg of P(t-Bu)₃ as (0.21 mmol) as catalyst are added The progress of the reaction is monitored by means of TLC. The solution is cooled to room temperature 100 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is taken up in ethyl acetate, and 10 ml of trifluoroacetic acid are added in order to hydrolyse the imide. The residue is recrystallised from toluene/ethanol 1:1, giving 18.8 g (75.6 mmol) (81%) of a white solid in a of purity 99.3%.

### b) Synthesis of cyclophane M3

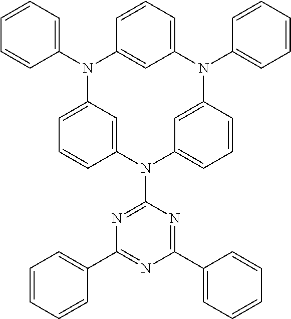 [SMILES: c1ccc(-c2nc(-c3ccccc3)nc(N3c4cccc(c4)N(c4ccccc4)c4cccc(c4)N(c4ccccc4)c4cccc3c4)n2)cc1]

10 g (17.5 mmol) of dibromide, 4.3 g (17.5 mmol) of aminotriazine and 2.88 g (30 mmol) of Na tert-butoxide [865-45-5] are dissolved in 300 ml of toluene. The reaction solution is carefully degassed, warmed to 80° C. 20 mg (0.09 mmol) of Pd(OAc)₂ and 82 mg of P(t-Bu)₃ as (0.27 mmol) as catalyst are added. The progress of the reaction is monitored by means of TLC. The solution is cooled to room temperature 100 ml of H₂O are added and the phases are separated. The aqueous phase is extracted three times with toluene, the combined organic phases are subsequently washed twice with water, dried over magnesium sulfate, filtered, and the solvent is stripped off in vacuo and recrystallised number of times from isopropanol, giving 4.4 g (6.65 mmol) (38%) of a white solid in a of purity 99.9%.

### Examples 4

### Synthesis of M6

Compound M6 is synthesised in accordance with the following scheme.

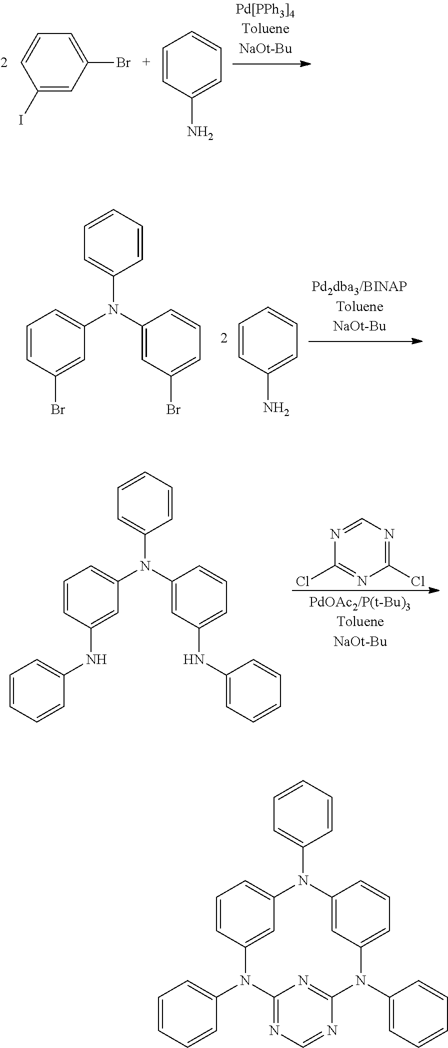

### a) Synthesis of 3,3′-dibromotriarylamine

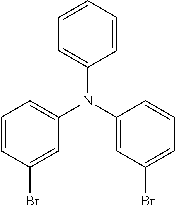 [SMILES: Brc1cccc(N(c2ccccc2)c2cccc(Br)c2)c1]

50 g (177 mmol) of bromoiodobenzene [591-81-4], 8.2 g (88 mmol) of aniline [62-53-3] and 28.8 g (300 mmol) of Na tert-butoxide [865-45-5] are dissolved in 300 ml toluene. The reaction solution is carefully degassed, warmed to 110° C., and 40 mg (0.18 mmol) of Pd(OAc)₂ and 164 mg of P(t-Bu)₃ as (0.54 mmol) as catalyst are added. The progress of the reaction is monitored by means of TLC. The solution is cooled to room temperature 50 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from hexane, giving 23.4 g (58 mmol) (66%) of a white solid in a of purity 99.7%.

### b) Synthesis of —N,N-diphenyl-3,3′-diaminotriarylamine

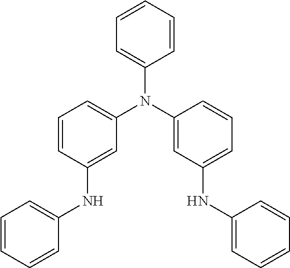 [SMILES: c1ccc(Nc2cccc(N(c3ccccc3)c3cccc(Nc4ccccc4)c3)c2)cc1]

15 g (37.2 mmol) of dibromotriarylamine, 6.9 g (74.4 mmol) of aniline [62-53-3] and 9.6 g (100 mmol) of Na tert-butoxide [865-45-5] are dissolved in 200 ml toluene. The reaction solution is carefully degassed, warmed to 100° C., and 92 mg (0.1 mmol) of Pd₂(dba)₃ and 187 mg (0.3 mmol) of rac-BINAP as catalyst are added. The progress of the reaction is monitored by means of TLC. The solution is cooled to room temperature 50 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from hexane, giving 8.2 g (19.3 mmol) (52%) of a white solid in a of purity 99.1%.

### c) Synthesis of cyclophane M6

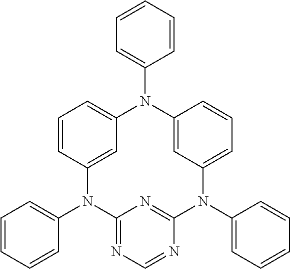 [SMILES: c1ccc(N2c3cccc(c3)N(c3ccccc3)c3ncnc(n3)N(c3ccccc3)c3cccc2c3)cc1]

7 g (16.4 mmol) of diamine, 2.5 g (16.4 mmol) of dichlorotriazine [2831-66-5] and 4.8 g (50 mmol) of Na tert-butoxide [865-45-5] are dissolved in 500 ml of toluene. The reaction solution is carefully degassed, warmed to

80° C., and 40 mg (0.18 mmol) of Pd(OAc)₂ and 164 mg (0.54 mmol) of P(t-Bu)₃ as catalyst are added. The progress of the reaction is monitored by means of TLC. The solution is cooled to room temperature 100 ml of H₂O are added and the phases are separated. The aqueous phase is extracted three times with toluene, the combined organic phases are subsequently washed twice with water, dried over magnesium sulfate, filtered, and the solvent is stripped off in vacuo and recrystallised a number of times from ethanol, giving 3.1 g (6.2 mmol) (38%) of a white solid in a of purity 99.9%.

### Examples 5

### Synthesis of M7

Compound M7 is synthesised in accordance with the following scheme.

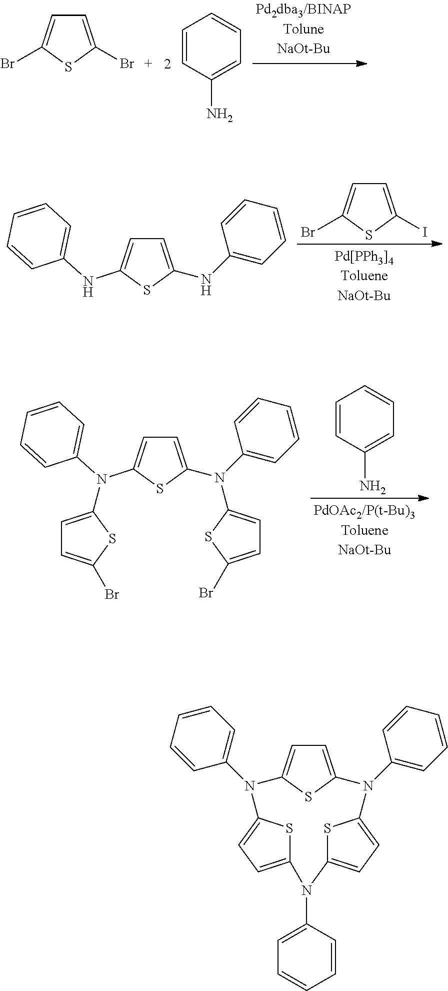

### a) Synthesis of N,N-diphenyl-1,3-diaminothiophene

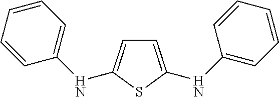 [SMILES: c1ccc(Nc2ccc(Nc3ccccc3)s2)cc1]

50 g (207 mmol) of 1.3 dibromothiophene [3141-27-4], 39.1 g (420 mmol) of aniline and 57.7 g (600 mmol) of Na tert-butoxide [865-45-5] are dissolved in 1000 ml of toluene. The reaction solution is carefully degassed, warmed to 90° C., and 276 mg (0.3 mmol) of Pd₂(dba)₃ and 561 mg (0.9 mmol) of rac-BINAP as catalyst are added. The progress of the reaction is monitored by means of TLC. The solution is cooled to room temperature 50 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from 1-propanol, giving 40.8 g (153 mmol) (74%) of a white solid in a of purity 99.8%.

### b) Synthesis of N,N-diphenyl-N,N-bis-3-bromothiophenediaminothio-phene

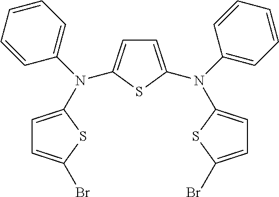 [SMILES: Brc1ccc(N(c2ccccc2)c2ccc(N(c3ccccc3)c3ccc(Br)s3)s2)s1]

30 g (112.6 mmol) of 1.3 diphenyldiaminothiophene, 65.1 g (225 mmol) of bromoiodothiophene [29054-81-2] and 28.8 g (300 mmol) of Na tert-butoxide [865-45-5] are dissolved in 500 ml of toluene. The reaction solution is carefully degassed, warmed to 90° C., and 80 mg (0.36 mmol) of Pd(OAc)₂ and 328 mg (0.108 mmol) of P(t-Bu)₃ as catalyst are added. The progress of the reaction is monitored by means of TLC. The solution is cooled to room temperature 50 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised from buthanol, giving 44.8 g (76.6 mmol) (68%) of a white solid in a of purity 99.4%.

### d) Synthesis of cyclophane M7

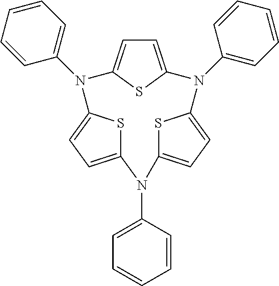 [SMILES: c1ccc(-n2c3ccc(s3)n(-c3ccccc3)c3ccc(s3)n(-c3ccccc3)c3ccc2s3)cc1]

30 g (51.2 mmol) of dibromide, 4.8 g (51.2 mmol) of aniline [62-53-3] and 14.4 g (150 mmol) of Na tert-butoxide [865-45-5] are dissolved in 300 ml of toluene. The reaction solution is carefully degassed, warmed to 80° C., and 40 mg (0.18 mmol) of Pd(OAc)₂ and 164 mg (0.54 mmol) of P(t-Bu)₃ as catalyst are added. The progress of the reaction is monitored by means of TLC. The solution is cooled to room temperature 100 ml of H₂O are added and the phases are separated. The aqueous phase is extracted three times with toluene, the combined organic phases are subsequently washed twice with water, dried over magnesium sulfate, filtered, and the solvent is stripped off in vacuo. The residue is recrystallised a number of times from buthanol, giving 7.4 g (14.3 mmol) (28%) of a white solid in a of purity 99.9%.

### Examples 6

### Materials Used in Organic Electronically Devices

The following materials are used in the present invention: V1 i is a reference matrix material in accordance with the prior art (WO 2008/086851). M1, M3 and M6 are matrix materials according to the invention, whose syntheses are described in Examples 2 to 4. And M6 and M7 can be used as HTM or HIM. TEG1 is a phosphorescent emitter, where TEG stands for Triplett Emitter Green. TEG1 was synthesised in accordance with WO 2004/026886. The synthesis of V1 is carried out in accordance with WO 2008/086851.

Matrix material TMM1 is synthesised in accordance with WO 2004/093207, and is used as co-matrix below.

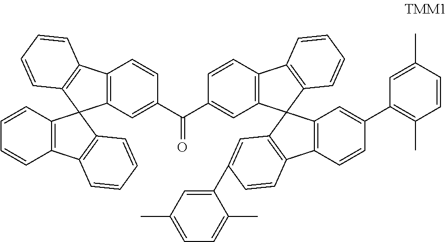 [SMILES: Cc1ccc(C)c(-c2ccc3c(c2)C2(c4ccccc4-c4ccc(C(=O)c5ccc6c(c5)C5(c7ccccc7-c7ccccc75)c5ccccc5-6)cc42)c2cc(-c4cc(C)ccc4C)ccc2-3)c1]

Polymer HIL-012 (Merck KGaA) is used as interlayer.

### Example 7

### Solutions and Compositions Comprising TMM1, V1, M1, M3, M6 and TEG1

Solutions as summarised in Table 2 are prepared as follows: firstly, 250 mg of the compositions are dissolved in 10 ml of chlorobenzene and stirred until the solution is clear. The solution is filtered using a filter (Millipore Millex LS, hydrophobic PTFE 5.0 μm).

TABLE 2
Composition of the solutions

| Solu- | | Ratio (based | | Concen- |
|---|---|---|---|---|
| tion | Composition | on weight) | Solvent | tration |
| 1 | TMM1 + M1 + TEG1 | 45:45:10 | Chlorobenzene | 25 mg/ml |
| 2 | TMM1 + M3 + TEG1 | 45:45:10 | Chlorobenzene | 25 mg/ml |
| 3 | M3 + TEG1 | 80:20 | Chlorobenzene | 25 mg/ml |
| 4 | TMM1 + M6 + TEG1 | 45:45:10 | Chlorobenzene | 25 mg/ml |
| 5 | TMM1 + V1 + TEG1 | 45:45:10 | Chlorobenzene | 25 mg/ml |
| 6 | M7 | 100% | Chlorobenzene | 20 mg/ml |

Solutions 1 to 5 are used to coat the emitting layer of OLEDs. The corresponding solid composition can be obtained by evaporating the solvent of the solutions. This can be used for the preparation of further formulations.

### Example 8

### Production of OLEDs

OLED1 to OLED5 having a structure in accordance with the prior art, anode(ITO)/PEDOT/interlayer/EML/cathode (EML=emission layer; ITO=indium tin oxide), are produced using the corresponding solutions 1 to 5, as summarised in Table 2, in accordance with the following procedure:
1. Coating of 80 nm of PEDOT (Baytron P Al 4083) onto an ITO-coated glass substrate by spin coating.
2. Coating of a 20 nm interlayer by spin coating of a toluene solution of HIL-012 (concentration 0.5% by weight) in a glovebox.
3. Drying of the interlayer by heating at 180° C. for 1 h in a glovebox.
4. Coating of a 80 nm emitting layer (EML) by spin coating of a solution in accordance with Table 2.
5. Drying of the device by heating at 120° C. for 20 min.
6. Vapour deposition of a Ba/Al cathode (3 nm+150 nm).
7. Encapsulation of the device.

### Example 8

### Measurements of the OLEDs and Comparison of the Results

The OLEDs obtained in this way are characterised by standard methods. The following properties are measured here: UIL characteristics, electroluminescence spectrum, colour coordinates, efficiency, operating voltage and lifetime. The results are summarised in Table 3, where OLED5 serves as comparison in accordance with the prior art. In Table 3, Uₒₙ stands for the use voltage, U(100) stands for the voltage at 100 cd/m² and U(1000) stands for the voltage at 1000 cd/m².

TABLE 3
Measurement results with OLED1 to OLED5

| | Max. eff. | Uₒₙ | U(100) | U(1000) | CIE @ |
|---|---|---|---|---|---|
| | [cd/A] | [V] | [V] | [V] | 100 cd/m² |
| OLED1 | 27.2 | 2.80 | 3.78 | 6.10 | 0.34/0.62 |
| OLED2 | 29.3 | 2.78 | 3.90 | 5.38 | 0.35/0.61 |
| OLED3 | 25.3 | 2.84 | 4.10 | 5.97 | 0.35/0.62 |
| OLED4 | 28.1 | 2.73 | 3.61 | 5.65 | 0.34/0.62 |
| OLED5 | 18.3 | 3.60 | 5.70 | 7.40 | 0.35/0.61 |
| (comparison) | | | | | |

As can be seen from Table 3, the organic electroluminescent devices according to the invention comprising M1, M3 and M6 as co-matrix material or matrix material exhibit significantly improved phosphorescent OLEDs with respect to operating voltage and efficiency. This may be due to the fact that M1, M3 and M6 all have a high T1 level, and also a favourable HOMO level, so that it may facilitate better hole transport. All OLEDs exhibit comparable colour coordinates.

On the basis of the present technical teaching according to the invention, further optimisations can be achieved by means of various possibilities without being inventive in the process. Thus, a further optimisation can be achieved, for example, through the use of other co-matrix or other emitters in the same or a different concentration.

### Example 9

### OFET Based on M7

Thin-film bottom-gate organic field-effect transistors (OFETs) are produced on highly doped silicon substrates in a dry nitrogen atmosphere glovebox, with thermally grown silicon oxide (SiO₂) insulation layer (thickness 230 nm), where the substrate served as common gate electrode. Transistor source/drain gold contacts are defined photolithographically on the SiO₂ layer. FET substrates are cleaned solvent and subsequently treated ozone for 10 min. in a specially made mercury low-pressure lamp setup. The devices are then treated firstly with octyltrichlorosilane by dipping the substrate into 10 mM solutions in toluene (heated at 60° C.) for 15 min., and then thorough washing with hexane, acetone and isopropanol. The thin semiconductor layers are subsequently by spin coating solution 6 at a rota-tional speed of about 3000 rpm. The devices are then dried and heated at 100° C. for 10 min. and measured with exclusion of light. Field-effect mobility μ^{sat} is calculated in the saturation regime (V_{d}>(V_{g}−Vo)) using equation (1):

$${( \frac{d {I}_{d}^{sat}}{d {V}_{g}} )}_{{V}_{d}} = \frac{{WC}_{i}}{L} {μ}^{sat} ( {V}_{g} - {V}_{0} ) \qquad Equation ( 1 )$$

where W is the channel width, L is the channel length, Ci is the capaci-tance of the insulation layer, V_{d} is the drain voltage, V_{g} is the gate voltage, V₀ is the switching voltage and I_{d} is the drain current.

The OFETs exhibit a mobility of 0.005 cm²/Vs, and an on/off ratio of 3×10⁵. The materials according to the invention are thus suitable for use in OFETs.

1-23. (canceled)

24. An organic electronic device which comprises, in at least one layer, a compound of the following formula (1): 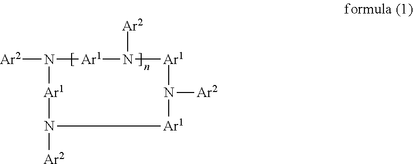
where the symbols and indices used have the following meanings:
n is an integer in the range from 0 to 8;
Ar¹ is on each occurrence, identically or differently, a substituted or unsubstituted divalent monocyclic or polycyclic aromatic or heteroaromatic ring system; and
Ar² is on each occurrence, identically or differently, a substituted or unsubstituted monovalent monocyclic or polycyclic aromatic or heteroaromatic ring system.

25. The organic electronic device according to claim 24, wherein the at least one layer is an electron-transport layer, electron-injection layer, hole-blocking layer, exciton-blocking layer or an emitting layer.

26. The organic electronic device according to claim 24, wherein at least one representative of the Ar¹ and/or Ar² in the compound of the formula (1) represents a heteroaromatic ring system and n is 0 or 1.

27. The organic electronic device according to claim 24, wherein at least one representative of the Ar¹ is a divalent group of one of the following formulae (2) to (8): 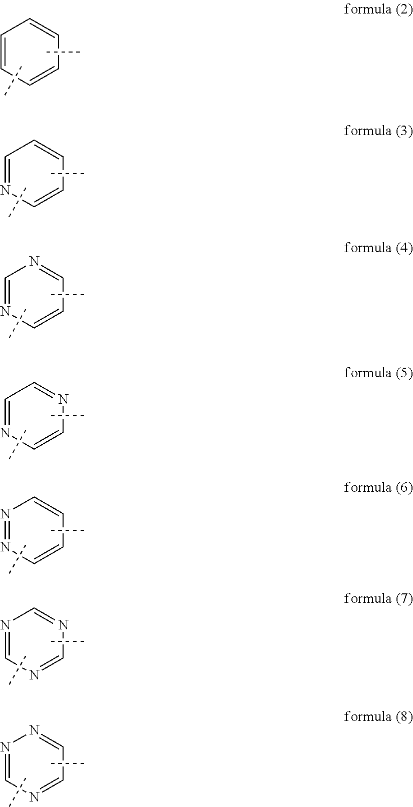
where the dashed lines represent the bonds to the ring nitrogen atoms in formula (1) and these bonds are linked via carbon atoms in positions 1 and 3 of the compounds of the formulae (2) to (8).

28. The organic electronic device according to claim 24, wherein the compound of the formula (1) is a compound of the following formula (9): 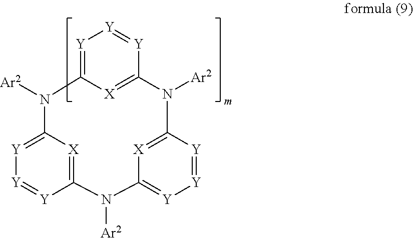
where X and Y are equal to CR¹ or N and m is an integer from 1 to 6, with the proviso that either
1.) at least one representative of the X or Y is equal to N, or
2.) one representative of the Ar² is a heteroaromatic ring system;
R¹ is selected on each occurrence, identically or differently, from the group consisting of the following: H, D, halogen, CHO, N(Ar)₂, C(═O)Ar, P(═O)(Ar)₂, S(═O)Ar, S(═O)₂Ar, CR²═CR²Ar, CN, NO₂, Si(R²)₃, B(OR²)₂, B(R²)₂, B(N(R²)₂)₂, OSO₂R², an alkyl, alkoxy or thioalkoxy group, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or a mono- or polycyclic aromatic or heteroaromatic ring system, which may in each case be substituted by one or more radicals R², or an aryloxy or heteroaryloxy group, which is optionally substituted by one or more radicals R², or a combination of these systems; two or more adjacent substituents R¹ here may also form a mono- or polycyclic, aliphatic or aromatic ring system with one another;
Ar is on each occurrence, identically or differently, an aromatic or heteroaromatic ring system, which is optionally substituted by one or more radicals R²; two radicals Ar here which are bonded to the same nitrogen, phosphorus or boron atom may also be linked to one another by a single bond or a bridge selected from B(R²), C(R²)₂, Si(R²)₂, C═O, C═NR², C═C(R²)₂, O, S, S═O, SO₂, N(R²), P(R²) and P(═O)R²;
R² is on each occurrence, identically or differently, H, D or an aliphatic, aromatic and/or heteroaromatic hydrocarbon radical, in which, in addition, H atoms is optionally replaced by F; two or more adjacent substituents R² here may also form a mono- or polycyclic, aliphatic or aromatic ring system with one another.

29. The organic electronic device according to claim 24, wherein at least one representative of the Ar¹ is a divalent group of one of the following formulae (100) or (101): 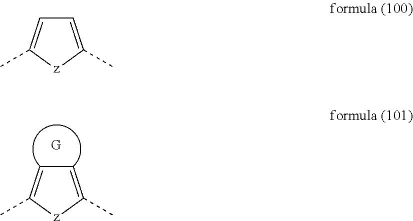
where Z is equal to O, S, SO₂ or NH and G, together with the two carbon atoms of the 5-membered ring, is an aromatic or heteroaromatic mono- or polycyclic ring system, and the dashed lines represent bonds to the ring nitrogen atoms of the compound of the formula (1).

30. The organic electronic device according to claim 24, wherein at least one representative of the Ar¹ is a divalent group of one of the following formulae (102) to (110): 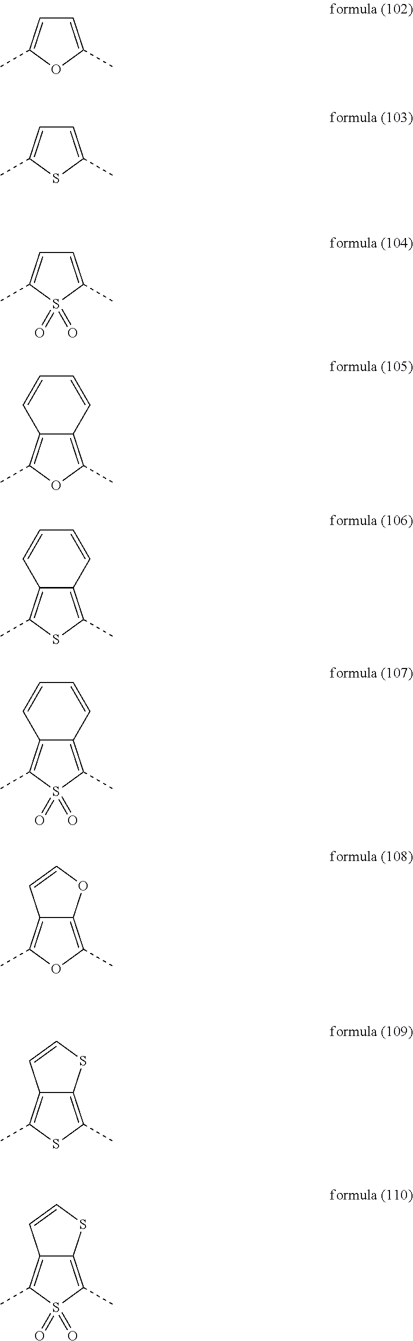
where the dashed lines represent bonds to the ring nitrogen atoms of the compound of the formula (1).

31. The organic electronic device according to claim 24, wherein the at least one layer is a hole-transport layer, hole-injection layer or electron-blocking layer, and in that at least one representative from Ar¹ is a compound of one of formulae (100) to (110) 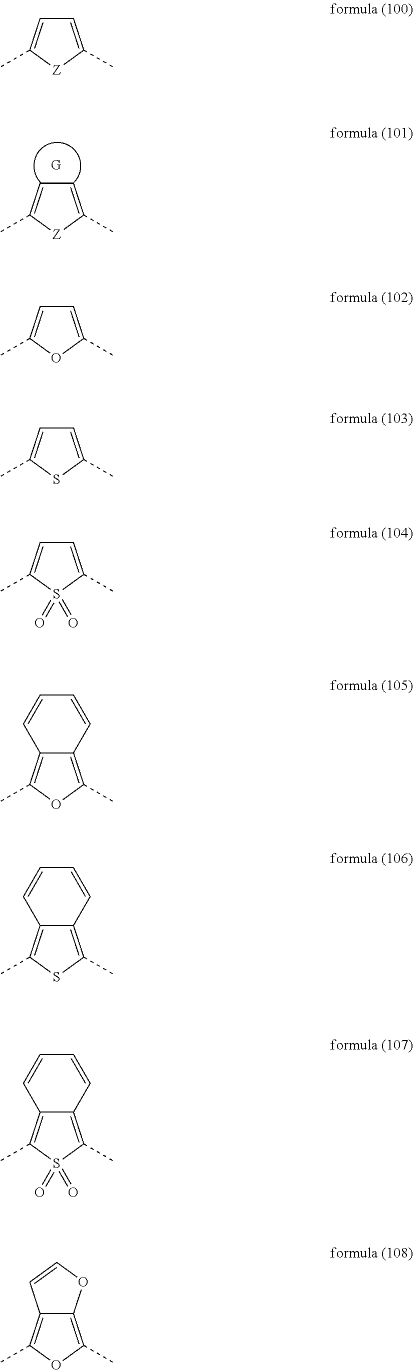 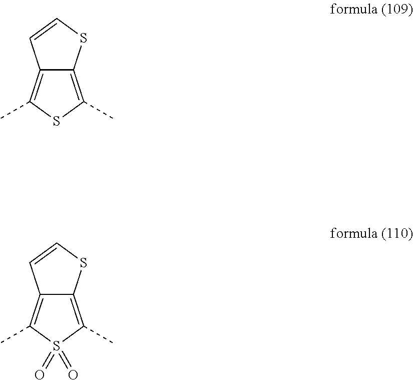
where Z is equal to O, S, SO₂ or NH and G, together with the two carbon atoms of the 5-membered ring, is an aromatic or heteroaromatic mono- or polycyclic ring system, and the dashed lines represent bonds to the ring nitrogen atoms of the compound of the formula (1) and the dashed lines represent bonds to the ring nitrogen atoms of the compound of the formula (1).

32. The organic electronic device according to claim 28, wherein the at least one layer is a hole-transport layer or hole-injection layer, and in that the compound of the formula (1) is a compound of the formula (9), where X and Y are equal to CR¹ or N and m is an integer from 1 to 6, with the proviso that at least one representative of the X or Y is equal to N

33. The organic electronic device according to claim 24, wherein at least one Ar² is a monovalent radical which is selected from the group which consists of the compounds of the following formulae (144) to (156) and an aromatic or heteroaromatic ring system containing a keto group: 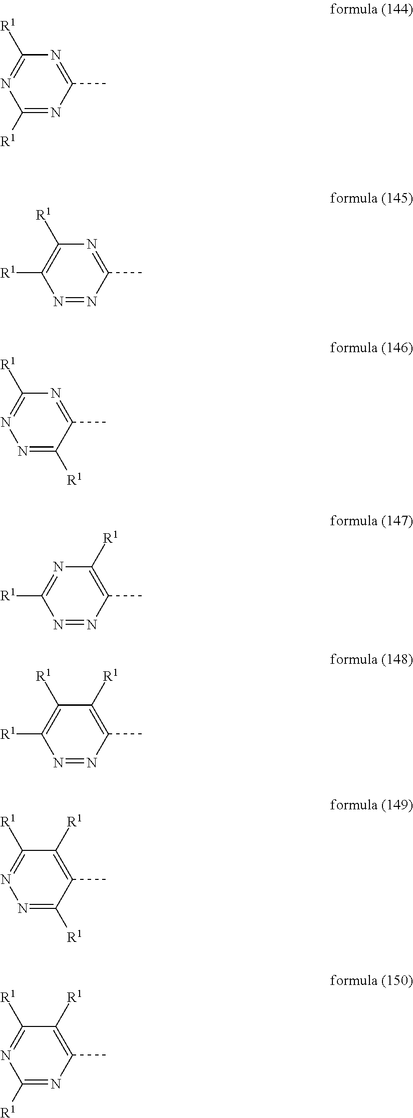 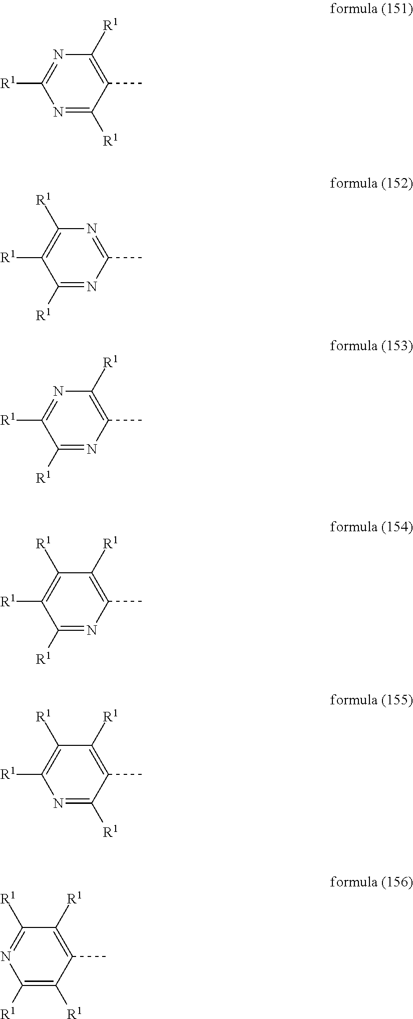
where
the dashed line in each case represents a bond to the ring nitrogen atom of the compound of the formula (1); and
R¹ is selected on each occurrence, identically or differently, from the group consisting of the following: H, D, halogen, CHO, N(Ar)₂, C(═O)Ar, P(═O)(Ar)₂, S(═O)Ar, S(═O)₂Ar, CR²═CR²Ar, CN, NO₂, Si(R²)₃, B(OR²)₂, B(R²)₂, B(N(R²)₂)₂, OSO₂R², an alkyl, alkoxy or thioalkoxy group, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by F, Cl, Br, I, CN or NO₂, or a mono- or polycyclic aromatic or heteroaromatic ring system, which may in each case be substituted by one or more radicals R², or an aryloxy or heteroaryloxy group, which is optionally substituted by one or more radicals R², or a combination of these systems; two or more adjacent substituents R¹ here may also form a mono- or polycyclic, aliphatic or aromatic ring system with one another.

34. The organic electronic device according to claim 24, wherein the at least one layer is an emitting layer which additionally comprises a phosphorescent emitter compound.

35. The organic electronic device according to claim 34, in which the phosphorescent emitter compound is a compound which contains copper, molybdenum, tungsten, rhenium, ruthenium, osmium, rhodium, iridium, palladium, platinum, silver, gold or europium.

36. The organic electronic device according to claim 24, wherein the at least one layer is an ETL or EIL which additionally comprises a phosphorescent emitter compound.

37. The organic electronic device according to claim 24, in which the device is an organic electroluminescent device.

38. The organic electronic device according to claim 37, which is an OLED, OLEC, an “organic light emitting field effect transistor” or an “organic light emitting electrochemical cell”.

39. A matrix material for phosphorescent emitter compounds or an electron-transport material in an organic electronic device which comprises the compound of the following formula (1): 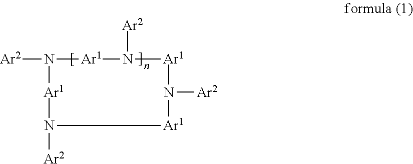
where the symbols and indices used have the following meanings:
n is an integer in the range from 0 to 8;
Ar¹ is on each occurrence, identically or differently, a substituted or unsubstituted divalent monocyclic or polycyclic aromatic or heteroaromatic ring system; and
Ar² is on each occurrence, identically or differently, a substituted or unsubstituted monovalent monocyclic or polycyclic aromatic or heteroaromatic ring system.

40. A composition comprising at least one compound of the a compound of the following formula (1): 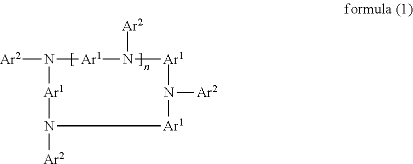
where the symbols and indices used have the following meanings:
n is an integer in the range from 0 to 8;
Ar¹ is on each occurrence, identically or differently, a substituted or unsubstituted divalent monocyclic or polycyclic aromatic or heteroaromatic ring system;
Ar² is on each occurrence, identically or differently, a substituted or unsubstituted monovalent monocyclic or polycyclic aromatic or heteroaromatic ring system;
and at least one phosphorescent emitter compound.

41. A compound of the formula (9) as defined in claim 28, with the proviso that at least one representative of the Y is equal to N and at least one representative of the X is equal to CR¹,
or
compound of the formula (1), 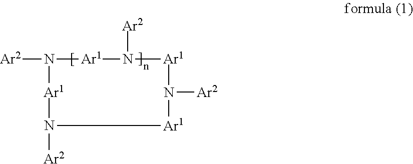
where the symbols and indices used have the following meanings:
n is an integer in the range from 0 to 8;
Ar¹ is on each occurrence, identically or differently, a substituted or unsubstituted divalent monocyclic or polycyclic aromatic or heteroaromatic ring system; and
Ar² is on each occurrence, identically or differently, a substituted or unsubstituted monovalent monocyclic or polycyclic aromatic or heteroaromatic ring system; with the proviso that at least one representative of the Ar¹ is a divalent group of one of the formulae (100) to (110) 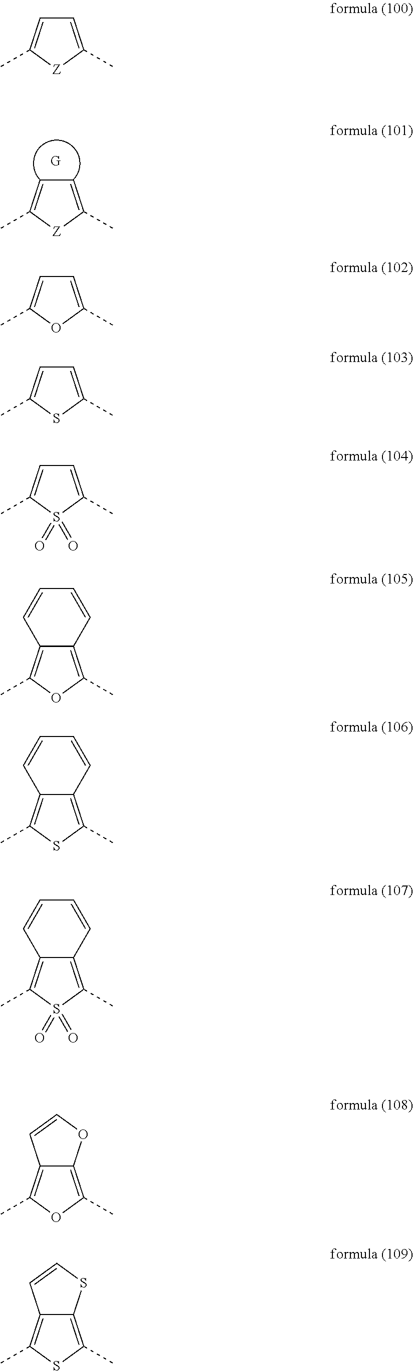 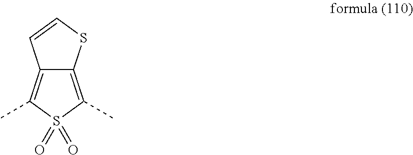
where Z is equal to O, S, SO₂ or NH and G, together with the two carbon atoms of the 5-membered ring, is an aromatic or heteroaromatic mono- or polycyclic ring system, and the dashed lines represent bonds to the ring nitrogen atoms of the compound of the formula (1) and the dashed lines represent bonds to the ring nitrogen atoms of the compound of the formula (1).

42. An organic electronic device which comprises the compound of claim 41.

43. The organic electronic device as claimed in claim 42, wherein the devices is selected from the group consisting of an organic electroluminescent device, an organic light-emitting transistor, an organic light-emitting electrochemical cell and organic light-emitting electrochemical transistor, an organic integrated circuit, an organic field-effect transistor, an organic thin-film transistor, an organic solar cell, a dye-sensitised organic solar cell, an organic optical detector, an organic photoreceptor, an organic field-quench device, an organic laser diode and an organic plasmon emitting device.

44. An organic electroluminescent device which comprises the compound according to claim 41 are used as matrix material for fluorescent or phosphorescent emitters and/or in a hole-blocking layer and/or in an electron-transport layer and/or in an electron-blocking or exciton-blocking layer and/or in a hole-transport layer.

45. A formulation, in particular a solution, dispersion or mini-emulsion, comprising at least one compound according to claim 41, and at least one solvent.

46. A mixture comprising at least one compound according to claim 41 and at least one further compound.
